(19) United States
(12) Patent Application Publication
(10) Pub. No.: US 2012/0288796 A1
(43) Pub. Date: Nov. 15, 2012

(54) RESIST COMPOSITION AND PATTERNING PROCESS

(76) Inventors: Kazuhiro KATAYAMA, Joetsu-shi (JP); Jun Hatakeyama, Joetsu-shi (JP); Youichi Ohsawa, Joetsu-shi (JP); Koji Hasegawa, Joetsu-shi (JP); Tomohiro Kobayashi, Joetsu-shi (JP)

(21) Appl. No.: 13/469,929

(22) Filed: May 11, 2012

(30) Foreign Application Priority Data
May 11, 2011 (JP) 2011-106011
Sep. 16, 2011 (JP) 2011-203162

(51) Int. Cl. G03F 7/20; G03F 7/027

(52) U.S. Cl. 430/285.1; 430/281.1; 430/325

(57) ABSTRACT

A resist composition is provided comprising a polymer comprising recurring units having a hydroxyl group substituted with an acid labile group, an onium salt PAG capable of generating a sulfonic acid, imide acid or methide acid, and an onium salt PAG capable of generating a carboxylic acid. A resist film of the composition is improved in dissolution contrast during organic solvent development, and from which a hole pattern having minimized nano-edge roughness can be formed via positive/negative reversal.

### CROSS-REFERENCE TO RELATED APPLICATION

This non-provisional application claims priority under 35 U.S.C. §119(a) on Patent Application Nos. 2011-106011 and 2011-203162 filed in Japan on May 11, 2011 and Sep. 16, 2011, respectively, the entire contents of which are hereby incorporated by reference.

### TECHNICAL FIELD

This invention generally relates to a resist composition and a pattern forming process using the composition. More particularly, it relates to a pattern forming process involving exposure of resist film, deprotection reaction with the aid of acid and heat, and development in an organic solvent to form a negative tone pattern in which the unexposed region of resist film is dissolved and the exposed region is not dissolved.

### BACKGROUND ART

In the recent drive for higher integration and operating speeds in LSI devices, the pattern rule is made drastically finer. The photolithography which is currently on widespread use in the art is approaching the essential limit of resolution determined by the wavelength of a light source. As the light source used in the lithography for resist pattern formation, g-line (436 nm) or i-line (365 nm) from a mercury lamp was widely used in 1980's. Reducing the wavelength of exposure light was believed effective as the means for further reducing the feature size. For the mass production process of 64 MB dynamic random access memories (DRAM, processing feature size 0.25 μm or less) in 1990's and later ones, the exposure light source of i-line (365 nm) was replaced by a KrF excimer laser having a shorter wavelength of 248 nm. However, for the fabrication of DRAM with a degree of integration of 256 MB and 1 GB or more requiring a finer patterning technology (processing feature size 0.2 μm or less), a shorter wavelength light source was required. Over a decade, photolithography using ArF excimer laser light (193 nm) has been under active investigation. It was expected at the initial that the ArF lithography would be applied to the fabrication of 180-nm node devices. However, the KrF excimer lithography survived to the mass-scale fabrication of 130-nm node devices. So, the full application of ArF lithography started from the 90-nm node. The ArF lithography combined with a lens having an increased numerical aperture (NA) of 0.9 is considered to comply with 65-nm node devices. For the next 45-nm node devices which required an advancement to reduce the wavelength of exposure light, the F₂ lithography of 157 nm wavelength became a candidate. However, for the reasons that the projection lens uses a large amount of expensive CaF₂ single crystal, the scanner thus becomes expensive, hard pellicles are introduced due to the extremely low durability of soft pellicles, the optical system must be accordingly altered, and the etch resistance of resist is low; the development of F₂ lithography was abandoned and instead, the ArF immersion lithography was introduced.

In the ArF immersion lithography, the space between the projection lens and the wafer is filled with water having a refractive index of 1.44. The partial fill system is compliant with high-speed scanning and when combined with a lens having a NA of 1.3, enables mass production of 45-nm node devices.

One candidate for the 32-nm node lithography is lithography using extreme ultraviolet (EUV) radiation with wavelength 13.5 nm. The EUV lithography has many accumulative problems to be overcome, including increased laser output, increased sensitivity, increased resolution and minimized line edge or width roughness (LER, LWR) of resist film, defect-free MoSi laminate mask, reduced aberration of reflection mirror, and the like.

Another candidate for the 32-nm node lithography is high refractive index liquid immersion lithography. The development of this technology was abandoned because LUAG, a high refractive index lens candidate had a low transmittance and the refractive index of liquid did not reach the goal of 1.8.

The process that now draws attention under the above-discussed circumstances is a double patterning process involving a first set of exposure and development to form a first pattern and a second set of exposure and development to form a pattern between the first pattern features. A number of double patterning processes are proposed. One exemplary process involves a first set of exposure and development to form a photoresist pattern having lines and spaces at intervals of 1:3, processing the underlying layer of hard mask by dry etching, applying another layer of hard mask thereon, a second set of exposure and development of a photoresist film to form a line pattern in the spaces of the first exposure, and processing the hard mask by dry etching, thereby forming a line-and-space pattern at a half pitch of the first pattern. An alternative process involves a first set of exposure and development to form a photoresist pattern having spaces and lines at intervals of 1:3, processing the underlying layer of hard mask by dry etching, applying a photoresist layer thereon, a second set of exposure and development to form a second space pattern on the remaining hard mask portion, and processing the hard mask by dry etching. In either process, the hard mask is processed by two dry etchings.

As compared with the line pattern, the hole pattern is difficult to reduce the feature size. In order for the prior art method to form fine holes, an attempt is made to form fine holes by under-exposure of a positive resist film combined with a hole pattern mask. This, however, results in the exposure margin being extremely narrowed. It is then proposed to form holes of greater size, followed by thermal flow or RELACS® method to shrink the holes as developed. However, there is a problem that control accuracy becomes lower as the pattern size after development and the size after shrinkage differ greater and the quantity of shrinkage is greater. With the hole shrinking method, the hole size can be shrunk, but the pitch cannot be narrowed.

It is then proposed in Non-Patent Document 1 that a pattern of X-direction lines is formed in a positive resist film using dipole illumination, the resist pattern is cured, another resist material is coated thereon, and a pattern of Y-direction lines is formed in the other resist film using dipole illumination, leaving a lattice-like line pattern, interstices of which provide a hole pattern. Although a hole pattern can be formed at a wide margin by combining X and Y lines and using dipole illumination featuring a high contrast, it is difficult to etch vertically staged line patterns at a high dimensional accuracy. It is proposed in Non-Patent Document 2 to form a hole pattern by exposure of a negative resist film through a Levenson phase shift mask of X-direction lines combined with a Levenson phase shift mask of Y-direction lines. However, the crosslinking negative resist film has the drawback that the resolving power is low as compared with the positive resist film, because the maximum resolution of ultrafine holes is determined by the bridge margin.

A hole pattern resulting from a combination of two exposures of X- and Y-direction lines and subsequent image reversal into a negative pattern can be formed using a high-contrast line pattern of light. Thus holes having a narrow pitch and fine size can be opened as compared with the prior art.

Non-Patent Document 3 reports three methods for forming hole patterns via image reversal. The three methods are: method (1) involving subjecting a positive resist material to two double-dipole exposures of X and Y lines to form a dot pattern, depositing a SiO₂ film thereon by LPCVD, and effecting O₂-RIE for reversal of dots into holes; method (2) involving forming a dot pattern by the same steps as in (1), but using a resist material designed to turn alkali-soluble and solvent-insoluble upon heating, coating a phenol-base overcoat film thereon, effecting alkaline development for image reversal to form a hole pattern; and method (3) involving double dipole exposure of a positive resist material and organic solvent development for image reversal to form holes.

The formation of negative pattern through organic solvent development is a traditional technique. A resist material comprising cyclized rubber is developed using an alkene such as xylene as the developer. An early chemically amplified resist material comprising poly(t-butoxycarbonyloxystyrene) is developed in anisole as the developer to form a negative pattern.

Recently a highlight is put on the organic solvent development again. It would be desirable if a very fine hole pattern, which is not achievable with the positive tone, is resolvable through negative tone exposure. To this end, a positive resist material featuring a high resolution is subjected to organic solvent development to form a negative pattern. An attempt to double a resolution by combining two developments, alkali development and organic solvent development is under study.

As the ArF resist material for negative tone development with organic solvent, positive ArF resist compositions of the prior art design may be used. Pattern forming processes are described in Patent Documents 1 to 6. These patent documents disclose resist materials for organic solvent development comprising a copolymer of hydroxyadamantane methacrylate, a copolymer of norbornane lactone methacrylate, and a copolymer of methacrylate having acidic groups including carboxyl, sulfo, phenol, thiol and other groups substituted with two or more acid labile groups, and pattern forming processes using the same.

Further, Patent Document 7 discloses a process for forming a pattern through organic solvent development in which a protective film is applied onto a resist film. Patent Document 8 discloses a topcoatless process for forming a pattern through organic solvent development in which an additive is added to a resist material so that the additive may segregate at the resist film surface after spin coating to provide the surface with improved water repellency.

### CITATION LIST

Patent Document 1: JP-A 2008-281974
Patent Document 2: JP-A 2008-281975
Patent Document 3: JP-A 2008-281980
Patent Document 4: JP-A 2009-053657
Patent Document 5: JP-A 2009-025707
Patent Document 6: JP-A 2009-025723
Patent Document 7: JP-A 2008-309878
Patent Document 8: JP-A 2008-309879
Patent Document 9: JP-A 2004-531749 (US 20030027061)
Patent Document 10: JP-A 2004-002252
Patent Document 11: JP-A 2005-352466
Patent Document 12: JP-A 2006-257078
Non-Patent Document 1: Proc. SPIE Vol. 5377, p. 255 (2004)
Non-Patent Document 2: IEEE IEDM Tech. Digest 61 (1996)
Non-Patent Document 3: Proc. SPIE Vol. 7274, p. 72740N (2009)

### DISCLOSURE OF INVENTION

As compared with the positive resist system which becomes dissolvable in alkaline developer as a result of acidic carboxyl or analogous groups generating through deprotection reaction, the organic solvent development provides a low dissolution contrast. The alkaline developer provides an alkaline dissolution rate that differs by a factor of 1,000 or more between the unexposed and exposed regions whereas the organic solvent development provides a dissolution rate difference of only about 10 times. While Patent Documents 1 to 6 describe conventional photoresist materials of the alkaline aqueous solution development type, there is a demand for a novel material which can offer a significant dissolution contrast upon organic solvent development.

When holes are formed by negative development, regions surrounding the holes receive light so that excess acid is generated therein. It is then important to control acid diffusion because the holes are not opened if the acid diffuses inside the holes.

The structure of photoacid generator (PAG) is critical for the control of acid diffusion. The object is achieved to some extent by having a stable PAG capable of generating an acid with sufficient acidity and bulkiness. However, as the advanced lithography reaches a pattern feature size which is approximate to the diffusion length of acid, it is desired to further enhance the acid diffusion control capability.

It is effective for further control of acid diffusion to add a quencher component capable of trapping the acid generated upon light exposure. Basic nitrogen-containing organic compounds, typically primary, secondary and tertiary amines are often used as the quencher. However, the nitrogen-containing organic compounds give rise to a dimensional difference between dark area (area including wide light-shielded region) and bright area (area including wide exposed region) due to localization in the resist film or volatilization (or chemical flare) from the resist film surface layer. They also cause a profile failure such as surface insolubilization.

Other typical quenchers are quenchers of onium salt type. For example, JP 3912767 proposes a resist material comprising, in combination, a compound capable of generating an alkane sulfonic acid having fluorine substituted at alpha-position and a non-fluorinated alkane sulfonic acid onium salt, the material being minimized in proximity bias, especially proximity bias of a line-and-space pattern. Although the mechanism is not discussed in detail, it is presumed that the fluorinated sulfonic acid generated upon exposure reacts with the non-fluorinated alkane sulfonic acid onium salt to induce a salt exchange into a non-fluorinated alkane sulfonic acid and a fluorinated sulfonic acid onium salt. The mechanism depends on a salt exchange from the strong acid (fluorinated sulfonic acid) to the weak acid (non-fluorinated alkane sulfonic acid). It is thus believed that the onium salt of non-fluorinated alkane sulfonic acid functions as a quencher or acid deactivator to the strong acid generated upon exposure. A similar concept is found in JP-A 2009-244859, describing that an alkane sulfonic acid onium salt of specific structure is effective for improving pattern profile or the like.

Also, since these weak acid onium salt quenchers are generally nonvolatile, they eliminate any concern about chemical flare and are expected to be effective for improving pattern rectangularity. When a resin comprising recurring units having a hydroxyl group protected with an acetal protective group as defined herein is used in combination with such a weak acid onium salt quencher, rectangularity is improved while maintaining nano edge roughness. The combination improves lithography performance in a complementary way.

An object of the invention is to provide a resist composition which displays a high dissolution contrast during organic solvent development as well as improved nano edge roughness and pattern rectangularity, and a pattern forming process involving exposure through a mask having a lattice-like pattern and forming a hole pattern via positive/negative reversal.

The inventors have found that when a resist film of a resist composition comprising a polymer comprising recurring units having a hydroxyl group substituted with an acid labile group, a compound capable of generating a sulfonic acid, imide acid or methide acid upon exposure to high-energy radiation, and a compound capable of generating a carboxylic acid upon exposure to high-energy radiation is exposed and developed in organic solvent, the dissolution contrast during organic solvent development is improved, and a hole pattern having minimized nano edge roughness can be formed via positive/negative reversal.

The invention provides a resist composition and a pattern forming process as defined below.

[1] A resist composition comprising

(A) a polymer comprising recurring units (a) having a hydroxyl group substituted with an acid labile group, represented by the general formula (1),

(B) at least one photoacid generator selected from an onium salt type photoacid generator capable of generating a sulfonic acid of the general formula (2), an onium salt type photoacid generator capable of generating an imide acid of the general formula (3), and an onium salt type photoacid generator capable of generating a methide acid of the general formula (4), and

(C) an onium salt type photoacid generator capable of generating a carboxylic acid of the general formula (5),

wherein the cations of the onium salts of (B) and (C) each are a sulfonium cation having the general formula (6) or an iodonium cation having the general formula (7).

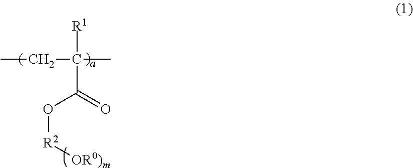

Herein R¹ is hydrogen or methyl, R² is a C₁-C₁₆ straight, branched or cyclic aliphatic hydrocarbon group having a valence of 2 to 5 which may contain an ether or ester radical, R⁰ is an acid labile group, “a” is a number in the range: 0<a≦1.0, and m is an integer of 1 to 4.

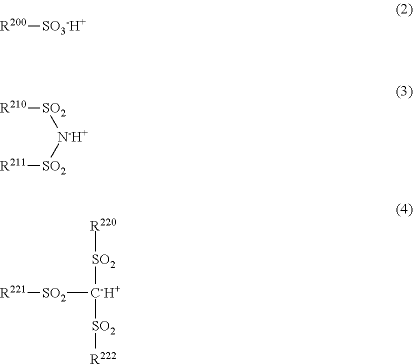

Herein R²⁰⁰ is a C₁-C₂₈ straight, branched or cyclic alkyl group, C₆-C₂₈ aryl group or C₇-C₂₈ aralkyl group, in which a methylene moiety may be substituted by an ether, ester, carbonyl, amide, carbonate or carbamate radical, and in which some or all hydrogen atoms may be substituted by at least one radical selected from the group consisting of halogen, hydroxyl, carboxyl, amino, cyano, nitro, and sulfonic acid ester; R²¹⁰ and R²¹¹ each are an optionally substituted C₁-C₈ straight or branched fluoroalkyl group, or R²¹⁰ and R²¹¹ may bond together to form a ring, wherein R²¹⁰ and R²¹¹ each are a C₁-C₈ fluoroalkylene group; R²²⁰, R²²¹ and R²²² each are an optionally substituted C₁-C₈ straight or branched fluoroalkyl group, or R²²⁰ and R²²¹ may bond together to form a ring, wherein R²¹⁰ and R²²¹ each are a C₁-C₈ fluoroalkylene group.

R³⁰⁰—COO⁻H⁺ (5)

Herein R³⁰⁰ is a C₁-C₂₅ straight, branched or cyclic alkyl group, C₂-C₂₅ alkenyl group, C₆-C₂₅ aryl group or C₇-C₂₅ aralkyl group, in which a methylene moiety may be substituted by an ether, ester or carbonyl radical, and in which some or all hydrogen atoms may be substituted by at least one radical selected from the group consisting of halogen, hydroxyl, carboxyl, amino, cyano, nitro, and sulfonic acid ester.

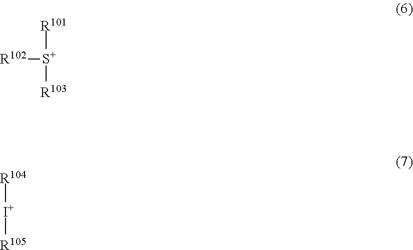

Herein R¹⁰¹, R¹⁰² and R¹⁰³ are each independently a C₁-C₂₀ straight or cyclic alkyl group, C₂-C₂₀ alkenyl group, C₆-C₂₀ aryl group or C₇-C₂₀ aralkyl group, in which a methylene moiety may be substituted by an ether, ester or carbonyl radical, and in which some or all hydrogen atoms may be substituted by at least one radical selected from the group consisting of halogen, hydroxyl, carboxyl, amino, and cyano, or two of R¹⁰¹, R¹⁰² and R¹⁰³ may bond together to form a ring with the sulfur atom; R¹⁰⁴ and R¹⁰⁵ are each independently a C₁-C₂₀ straight or cyclic alkyl group, C₂-C₂₀ alkenyl group, C₆-C₂₀ aryl group or C₁-C₂₀ aralkyl group, in which a methylene moiety may be substituted by an ether, ester or carbonyl radical, and in which some or all hydrogen atoms may be substituted by at least one radical selected from the group consisting of halogen, hydroxyl, carboxyl, amino, and cyano.
[2] The resist composition of [1] wherein (A) the polymer comprising recurring units (a) having a hydroxyl group substituted with an acid labile group comprises recurring units (a1) or (a2) having a hydroxyl group protected with an acetal protective group, represented by the general formula (1-1) or (1-2).

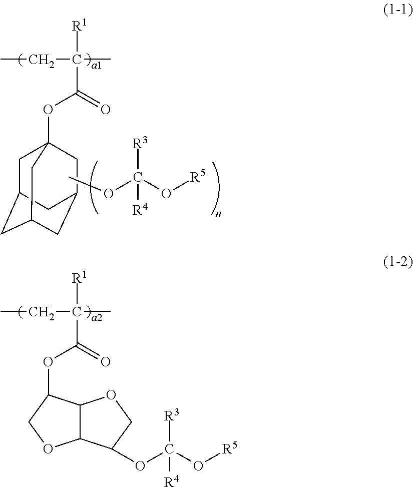

Herein R¹ is hydrogen or methyl, R³ and R⁴ are each independently hydrogen or a C₁-C₁₀ straight, branched or cyclic monovalent hydrocarbon group, R⁵ is a C₁-C₁₆ straight, branched or cyclic monovalent hydrocarbon group which may contain a heteroatom, a1 and a2 are numbers in the range: 0<a1≦1.0, 0<a2≦1.0, and 0<a1+a2≦1.0, and n is an integer of 1 to 3.
[3] The resist composition of [1] or [2] wherein the photoacid generator (B) generates a sulfonic acid of the general formula (8):

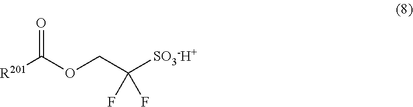

wherein R²⁰¹ is a C₁-C₂₃ straight, branched or cyclic alkyl group, C₆-C₂₃ aryl group or C₇-C₂₃ aralkyl group, in which a is methylene moiety may be substituted by an ether, ester or carbonyl radical, and in which some or all hydrogen atoms may be substituted by at least one radical selected from the group consisting of halogen, hydroxyl, carboxyl, amino, cyano, nitro, and sulfonic acid ester, with the proviso that R²⁰¹ is not perfluoroalkyl.
[4] The resist composition of [1] or [2] wherein the photoacid generator (B) generates a sulfonic acid of the general formula (9):

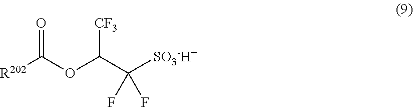

wherein R²⁰² is a C₁-C₂₃ straight, branched or cyclic alkyl group, C₆-C₂₃ aryl group or C₇-C₂₃ aralkyl group, in which a methylene moiety may be substituted by an ether, ester or carbonyl radical, and in which some or all hydrogen atoms may be substituted by at least one radical selected from the group consisting of halogen, hydroxyl, carboxyl, amino, and cyano, with the proviso that R²⁰² is not perfluoroalkyl.
[5] The resist composition of [1] or [2] wherein the photoacid generator (B) generates a sulfonic acid of the general formula (10):

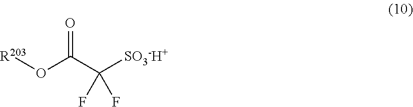

wherein R²⁰³ is an optionally substituted C₁-C₂₀ straight, branched or cyclic alkyl group or optionally substituted C₆-C₁₄ aryl group, with the proviso that R²⁰³ is not perfluoroalkyl.
[6] The resist composition of [1] or [2] wherein the photoacid generator (B) generates a sulfonic acid of the general formula (11):

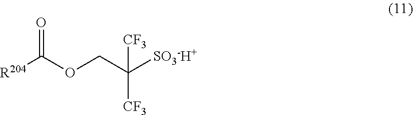

wherein R²⁰⁴ is a C₁-C₂₃ straight, branched or cyclic alkyl group, C₆-C₂₃ aryl group or C₇-C₂₃ aralkyl group, in which a methylene moiety may be substituted by an ether, ester or carbonyl radical, and in which some or all hydrogen atoms may be substituted by at least one radical selected from the group consisting of halogen, hydroxyl, carboxyl, amino, and cyano, with the proviso that R²⁰⁴ is not perfluoroalkyl.
[7] The resist composition of [1] or [2] wherein the photoacid generator (B) generates a sulfonic acid of the general formula (12):

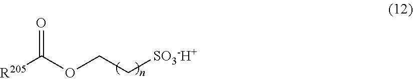

wherein R²⁰⁵ is an optionally substituted C₁-C₂₀ straight, branched or cyclic alkyl group or optionally substituted C₆-C₁₄ aryl group, and n is an integer of 1 to 3, with the proviso that R²⁰⁵ is not perfluoroalkyl.
[8] The resist composition of any one of [1] to [7] wherein the polymer (A) further comprises recurring units (b) having a carboxyl group substituted with an acid labile group, represented by the general formula (14) and/or recurring units (c) having an adhesive group selected from the group consisting of hydroxyl, cyano, carbonyl, ester, ether, lactone ring, carboxyl, and carboxylic anhydride.

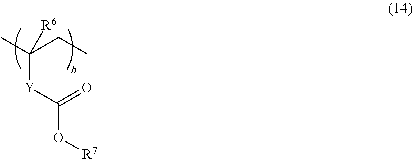

Herein R⁶ is hydrogen or methyl, R⁷ is an acid labile group, Y is a single bond or —C(═O)—O—R⁸—, R⁸ is a C₁-C₁₀ straight, branched or cyclic alkylene group which may contain an ether or ester radical, or a naphthylene group, and b is a number in the range: 0<b<1.0.
[9] The resist composition of any one of [1] to [8] herein the polymer (A) comprising recurring units (a) having a hydroxyl group substituted with an acid labile group, represented by the general formula (1) further comprises recurring units of at least one type selected from units of sulfonium salt having the general formulae (d1) to (d3), and the onium salt type photoacid generator (C) capable of generating a carboxylic acid of the general formula (5) is present.

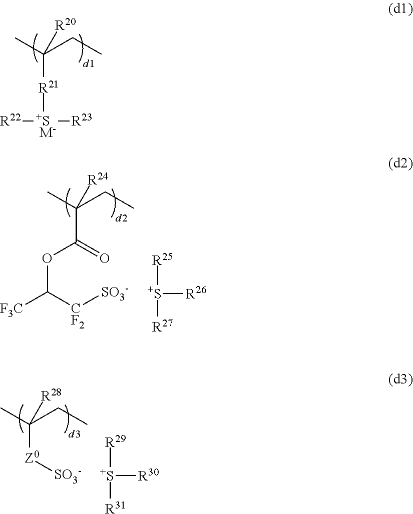

Herein R²⁰, R²⁴, and R²⁸ each are hydrogen or methyl, R²¹ is a single bond, phenylene, —O—R³³—, or —C(═O)—Y—R³³—, Y is oxygen or NH, R³³ is a straight, branched or cyclic C₁-C₆ alkylene group, alkenylene or phenylene group, which may contain a carbonyl (—CO—), ester (—COO—), ether (—O—) or hydroxyl radical, R²², R²³, R²⁵, R²⁶, R²⁷, R²⁹, R³⁰, and R³¹ are each independently a straight, branched or cyclic C₁-C₁₂ alkyl group which may contain a carbonyl, ester or ether radical, or a C₆-C₁₂ aryl, C₇-C₂₀ aralkyl, or thiophenyl group, Z⁰ is a single bond, methylene, ethylene, phenylene, fluorophenylene, —O—R³²—, or —C(═O)—Z¹—R³²—, Z¹ is oxygen or NH, R³² is a straight, branched or cyclic C₁-C₆ alkylene group, alkenylene or phenylene group, which may contain a carbonyl, ester, ether or hydroxyl radical, M⁻ is a non-nucleophilic counter ion, d1, d2 and d3 are numbers in the range: 0≦d1≦0.3, 0≦d2≦0.3, 0≦d3≦0.3, and 0<d1+d2+d3≦0.3.
[10] A pattern forming process comprising the steps of applying the resist composition of any one of [1] to [9] onto a substrate to form a resist film, exposing the resist film to high-energy radiation, baking, and developing the exposed film in an organic solvent-based developer to form a negative pattern wherein the unexposed region of film is dissolved away and the exposed region of film is not dissolved.
[11] The process of [10] wherein the developer comprises at least one organic solvent selected from the group consisting of 2-octanone, 2-nonanone, 2-heptanone, 3-heptanone, 4-heptanone, 2-hexanone, 3-hexanone, diisobutyl ketone, 2-methylcyclohexanone, 3-methylcyclohexanone, 4-methylcyclohexanone, acetophenone, 2′-methylacetophenone, 4′-methylacetophenone, propyl acetate, butyl acetate, isobutyl acetate, amyl acetate, isoamyl acetate, butenyl acetate, phenyl acetate, propyl formate, butyl formate, isobutyl formate, amyl formate, isoamyl formate, methyl valerate, methyl pentenoate, methyl crotonate, ethyl crotonate, methyl lactate, ethyl lactate, propyl lactate, butyl lactate, isobutyl lactate, amyl lactate, isoamyl lactate, methyl 2-hydroxyisobutyrate, ethyl 2-hydroxyisobutyrate, methyl benzoate, ethyl benzoate, benzyl acetate, methyl phenylacetate, benzyl formate, phenylethyl formate, methyl 3-phenylpropionate, benzyl propionate, ethyl phenylacetate, and 2-phenylethyl acetate.
[12] The process of [10] or [11] wherein the step of exposing the resist film to high-energy radiation includes ArF excimer laser immersion lithography of 193 nm wavelength, EUV lithography of 13.5 nm wavelength or EB lithography.
[13] The process of any one of [10] to [12] wherein the ArF immersion lithography of 193 nm wavelength uses a halftone phase shift mask bearing a dot pattern, whereby a pattern of holes is formed at the dots after development.
[14] The process of any one of [10] to [12] wherein the exposing step includes two exposures through a halftone phase shift mask having intersecting lines, whereby a pattern of holes is formed at the intersections of lines after development.
[15] The process of any one of [10] to [12] wherein the exposing step uses a halftone phase shift mask bearing lattice-like shifter gratings, whereby a pattern of holes is formed at the intersections of gratings after development.
[16] The process of [13], [14] or [15] wherein the halftone phase shift mask has a transmittance of 3 to 15%.
[17] The process of [15] or [16] wherein the phase shift mask used is a phase shift mask including a lattice-like first shifter having a line width equal to or less than a half pitch and a second shifter arrayed on the first shifter and consisting of lines whose on-wafer size is 2 to 30 nm thicker than the line width of the first shifter, whereby a pattern of holes is formed only where the thick shifter is arrayed.
[18] The process of [13] to [16] wherein the phase shift mask used is a phase shift mask including a lattice-like first shifter having a line width equal to or less than a half pitch and a second shifter arrayed on the first shifter and consisting of dots whose on-wafer size is 2 to 100 nm thicker than the line width of the first shifter, whereby a pattern of holes is formed only where the thick shifter is arrayed.
[19] A pattern forming process comprising the steps of applying the resist composition of any one of [1] to [9] onto a substrate to form a resist film, forming a protective film thereon, exposing the resist film to high-energy radiation, baking, and applying an organic solvent-based developer to dissolve the protective film and the unexposed region of resist film and form a negative pattern wherein the exposed region of resist film is not dissolved.
[20] The process of [19] wherein the protective film is formed of a composition comprising a polymer comprising recurring units having a 1,1,1,3,3,3-hexafluoro-2-propanol residue and an amine compound or amine salt, or a composition comprising a polymer comprising recurring units having a 1,1,1,3,3,3-hexafluoro-2-propanol residue and recurring units having an amino group or amine salt copolymerized, the composition further comprising an alcohol solvent of at least 4 carbon atoms, an ether solvent of 8 to 12 carbon atoms, or a mixture thereof.

### ADVANTAGEOUS EFFECTS OF INVENTION

When an image is formed via positive/negative reversal by forming a resist film from a resist composition, exposing and developing in an organic solvent, the resist composition comprising a polymer comprising recurring units having a hydroxyl group substituted with an acid labile group, at least one compound capable of generating a sulfonic acid, imide acid or methide acid upon exposure to high-energy radiation, and a compound capable of generating a carboxylic acid upon exposure to high-energy radiation offers the advantages of a high dissolution contrast during organic solvent development in that the unexposed region is highly dissolvable and the exposed region is least dissolvable, and minimized nano edge roughness. This ensures that a fine hole pattern is formed at a high sensitivity and a high precision of dimensional control.

### BRIEF DESCRIPTION OF DRAWINGS

FIG. 1 schematically illustrates in cross-sectional views the pattern forming process of the invention, FIG. 1A shows a resist film formed on a substrate, FIG. 1B shows the resist film being exposed, and FIG. 1C shows the resist film being developed in organic solvent.

FIG. 2 is an optical image of X-direction lines having a pitch of 90 nm and a line size of 45 nm printed under conditions: ArF excimer laser of wavelength 193 nm, NA 1.3 lens, dipole illumination, 6% halftone phase shift mask, and s-polarization.

FIG. 3 is an optical image of Y-direction lines like FIG. 2.

FIG. 4 shows a contrast image obtained by overlaying the optical image of X-direction lines in FIG. 2 with the optical image of Y-direction lines in FIG. 3.

FIG. 5 illustrates a mask bearing a lattice-like pattern.

FIG. 6 is an optical image of a lattice-like line pattern having a pitch of 90 nm and a line width of 30 nm printed under conditions: NA 1.3 lens, cross-pole illumination, 6% halftone phase shift mask, and azimuthally polarized illumination.

FIG. 7 illustrates a mask bearing a dot pattern of square dots having a pitch of 90 nm and a side width of 60 nm.

FIG. 8 is an optical image resulting from the mask of FIG. 7, printed under conditions: NA 1.3 lens, cross-pole illumination, 6% halftone phase shift mask, and azimuthally polarized illumination, showing its contrast.

FIG. 9 illustrates a mask bearing a lattice-like pattern having a pitch of 90 nm and a line width of 20 nm on which thick crisscross or intersecting line segments are disposed where dots are to be formed.

FIG. 10 is an optical image resulting from the mask of FIG. 9, showing its contrast.

FIG. 11 illustrates a mask bearing a lattice-like pattern having a pitch of 90 nm and a line width of 15 nm on which thick dots are disposed where dots are to be formed.

FIG. 12 is an optical image resulting from the mask of FIG. 11, showing its contrast.

FIG. 13 illustrates a mask without a lattice-like pattern.

FIG. 14 is an optical image resulting from the mask of FIG. 13, showing its contrast.

FIG. 15 is a diagram showing film thickness versus exposure dose in Example 1-1.

FIG. 16 is a diagram showing film thickness versus exposure dose in Comparative Example 1-1.

FIG. 17 is a diagram showing film thickness versus exposure dose in Comparative Example 1-2.

FIG. 18 illustrates a lattice-like mask used in ArF lithography patterning test 2.

FIG. 19 illustrates a lattice-like mask with dots disposed at intersections, used in ArF lithography patterning test 3.

FIG. 20 illustrates a mask bearing a lattice-like pattern with thick gratings disposed thereon, used in ArF lithography patterning test 4.

### DESCRIPTION OF EMBODIMENTS

In the disclosure, the singular forms “a,” “an” and “the” include plural referents unless the context clearly dictates otherwise. The notation (Cn-Cm) means a group containing from n to m carbon atoms per group.

The abbreviations and acronyms have the following meaning.

Mw: weight average molecular weight

Mn: number average molecular weight

Mw/Mn: molecular weight distribution or dispersity

GPC: gel permeation chromatography

PEB: post-exposure baking

UV: ultraviolet

DUV: deep ultraviolet

EUV: extreme ultraviolet

EB: electron beam

PAG: photoacid generator

### Resist Composition

One embodiment of the invention is a resist composition comprising (A) a polymer comprising recurring units (a) having a hydroxyl group substituted with an acid labile group, represented by the general formula (1).

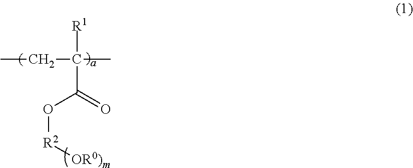

Herein R¹ is hydrogen or methyl, R² is a C₁-C₁₆ straight, branched or cyclic aliphatic hydrocarbon group having a valence of 2 to 5 which may contain an ether or ester radical, R⁰ is an acid labile group, “a” is a number in the range: 0<a≦1.0, and m is an integer of 1 to 4. It is noted that recurring units may be of one or more types that fall within the confine of the relevant formula.

In a preferred embodiment, the polymer (A) comprises recurring units of at least one type having a hydroxyl group protected with an acetal protective group which is acid labile, specifically recurring units (a1) having the general formula (1-1) or recurring units (a2) having the general formula (1-2).

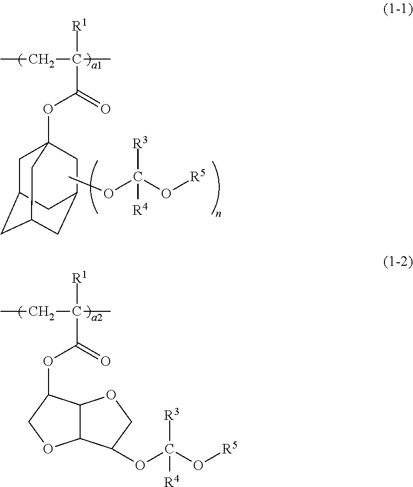

Herein R¹ is hydrogen or methyl, R³ and R⁴ are each independently hydrogen or a C₁-C₁₀ straight, branched or cyclic monovalent hydrocarbon group, R⁵ is a C₁-C₁₆ straight, branched or cyclic monovalent hydrocarbon group which may contain a heteroatom, a1 and a2 are numbers in the range: 0<a1≦1.0, 0<a2≦1.0, and 0<a1+a2≦1.0, and n is an integer of 1 to 3.

Suitable C₁-C₁₀ straight, branched or cyclic monovalent hydrocarbon groups represented by R³ and R⁴ include alkyl groups such as methyl, ethyl, n-propyl, isopropyl, n-butyl, isobutyl, tert-butyl, tert-amyl, n-pentyl, n-hexyl, 2-ethylhexyl, n-octyl, cyclopropyl, cyclopentyl, cyclopentylmethyl, and cyclohexylethyl.

Suitable C₁-C₁₆ straight, branched or cyclic monovalent hydrocarbon groups represented by R⁵ include alkyl groups such as methyl, ethyl, n-propyl, isopropyl, n-butyl, sec-butyl, tert-butyl, tert-amyl, n-pentyl, n-hexyl, n-octyl, n-nonyl, n-decyl, cyclopentyl, cyclohexyl, 2-ethylhexyl, cyclopentylmethyl, cyclopentylethyl, cyclopentylbutyl, cyclohexylmethyl, cyclohexylethyl, cyclohexylbutyl, norbornyl, oxanorbornyl, tricyclo[5.2.1.0^{2,6}]decanyl, and adamantyl. R⁵ may contain heteroatoms including oxygen, nitrogen, sulfur and fluorine atoms.

The subscript n is an integer of 1 to 3, preferably 1 or 2, and most preferably 2. In the case of n=3, the relevant compound itself may have a higher molecular weight and sometimes become difficult to purify by distillation.

Examples of recurring units (a1) having formula (1-1) are given below, but not limited thereto. Herein, R¹ is as defined above, and Me stands for methyl.

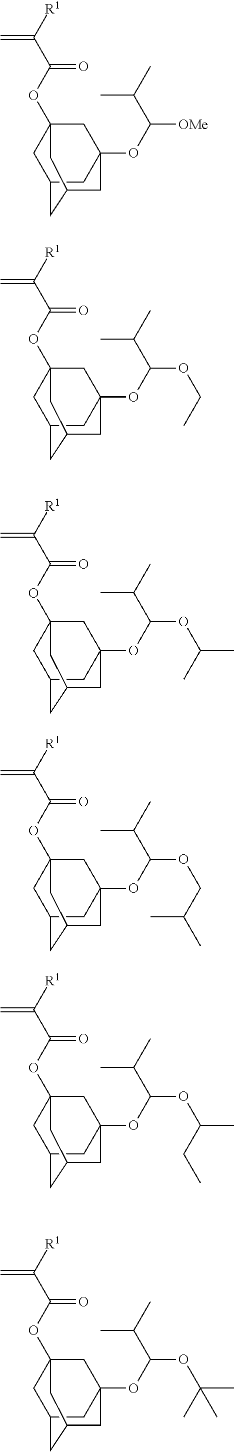

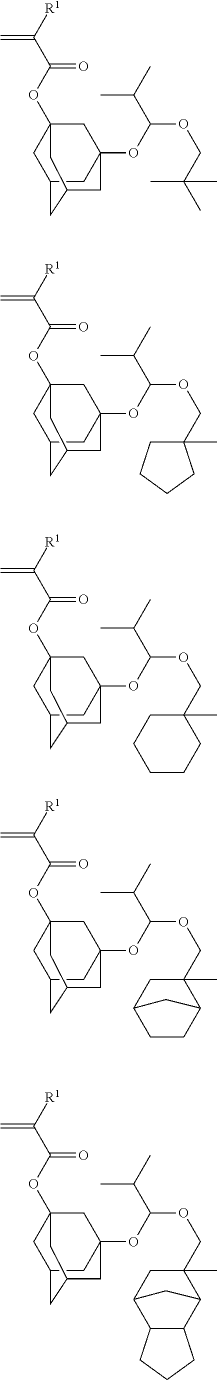

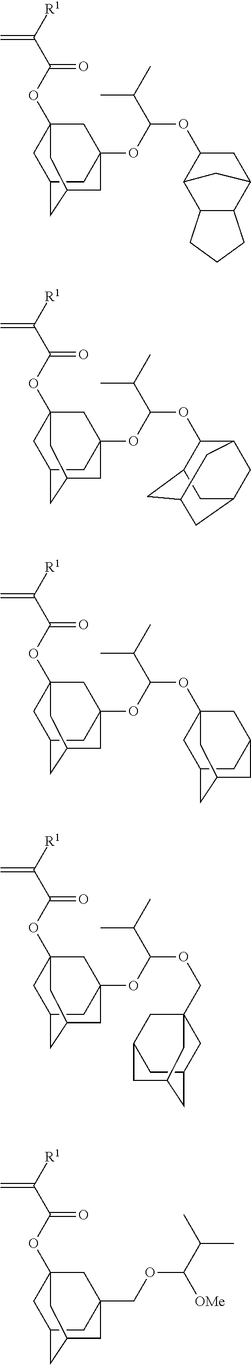

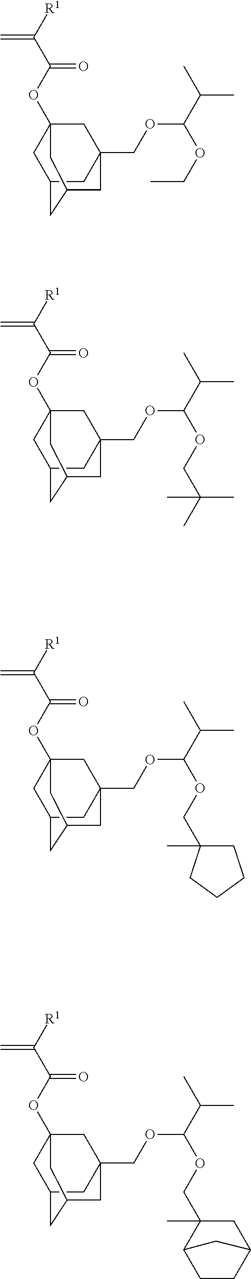

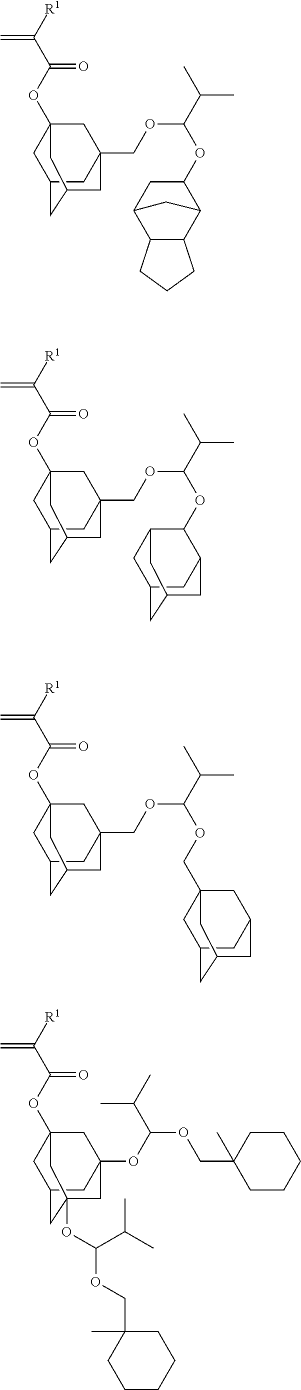

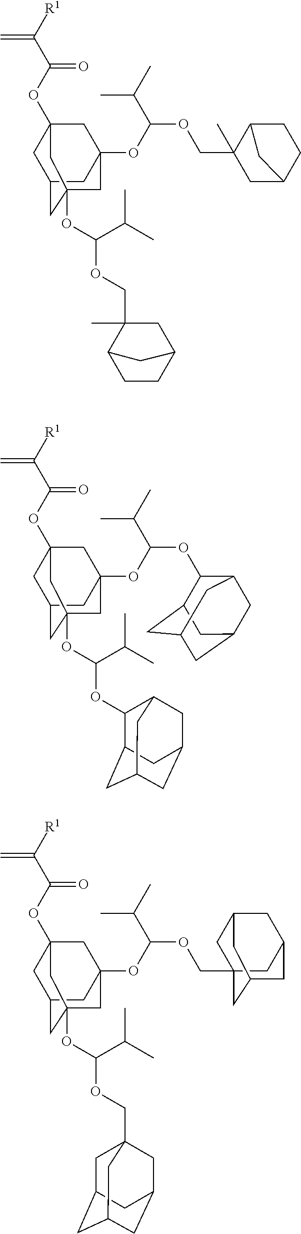

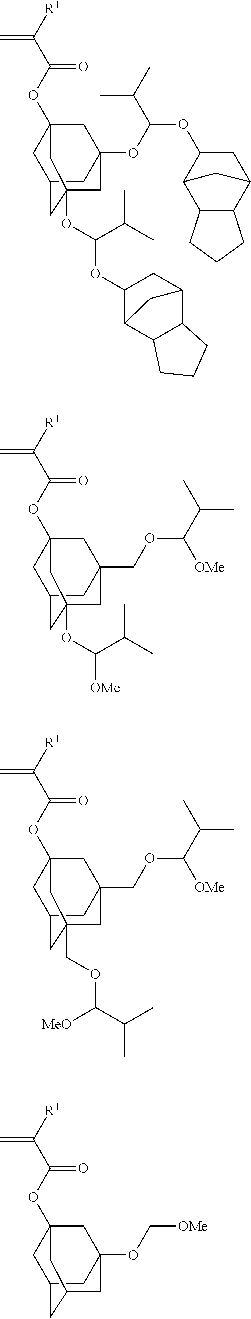

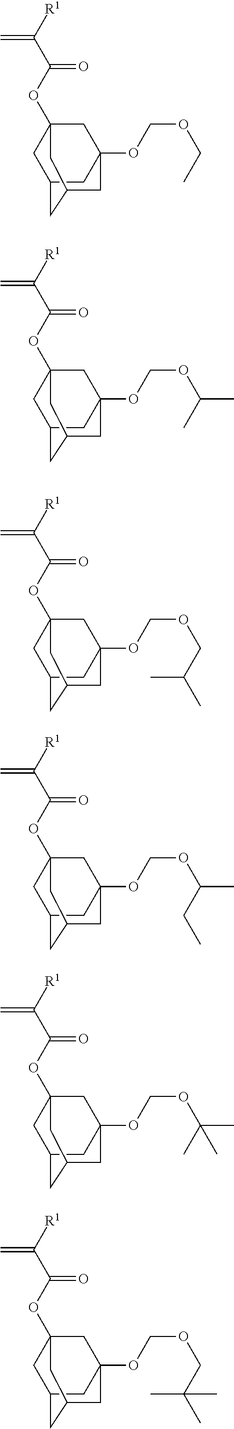

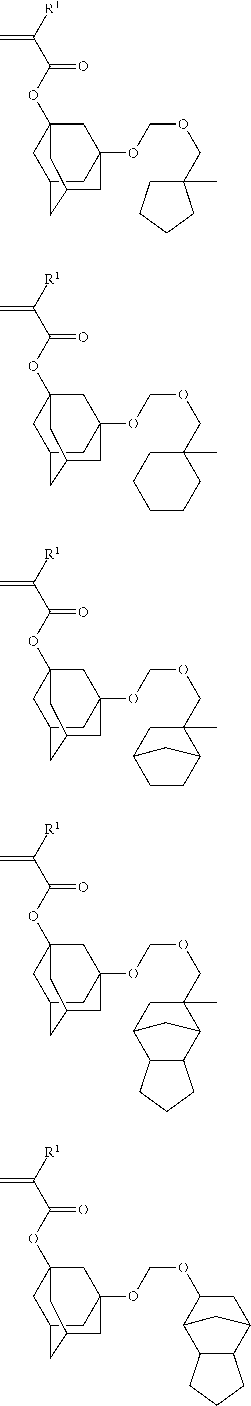

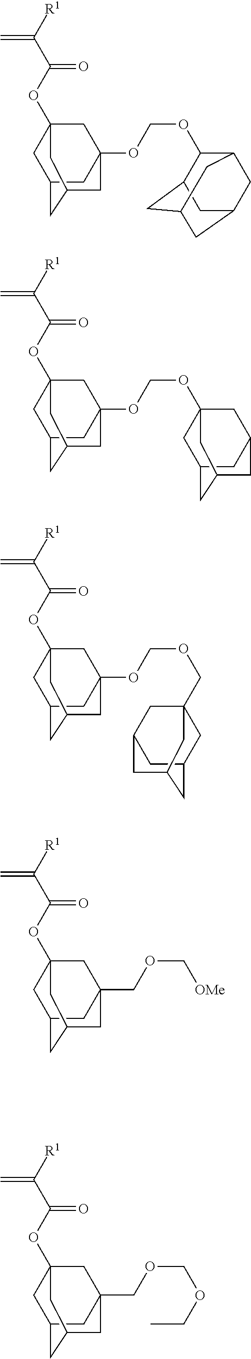

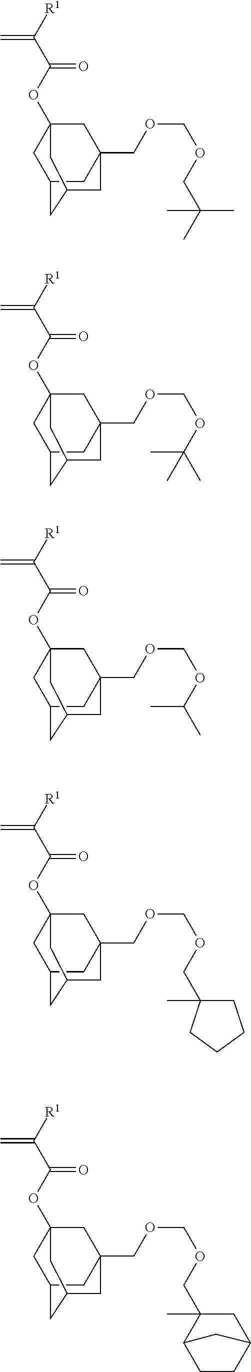

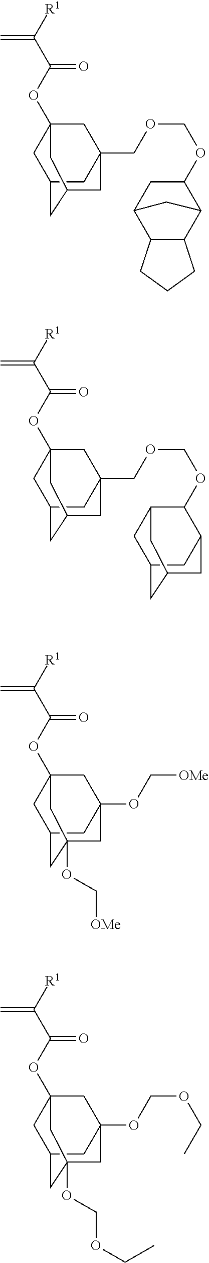

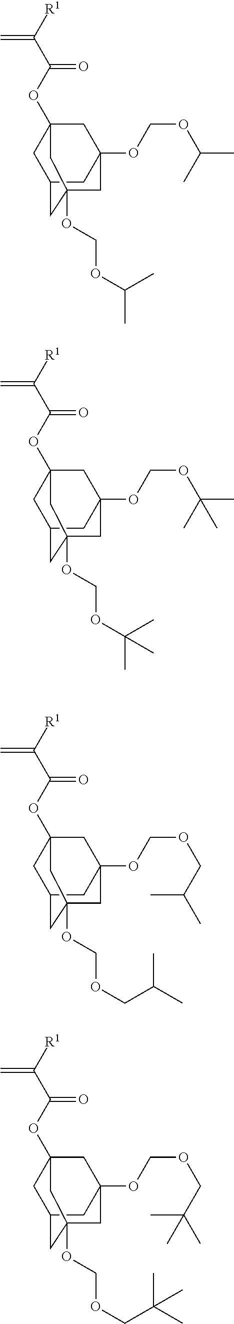

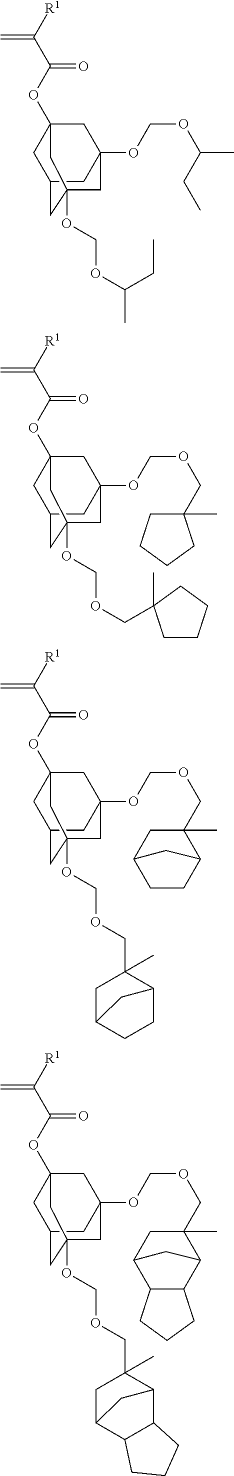

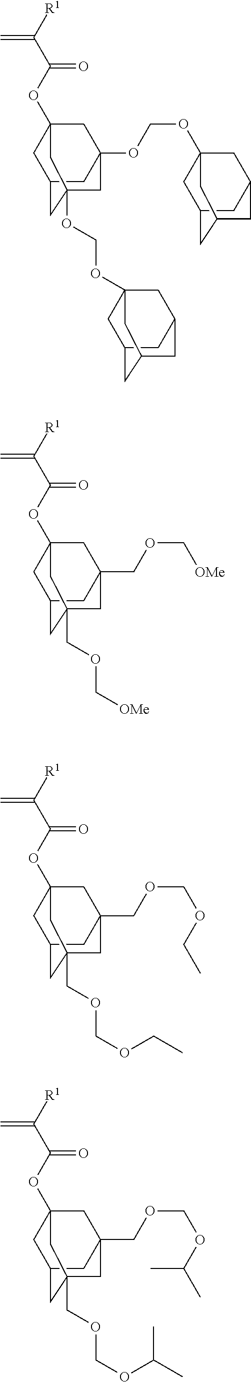

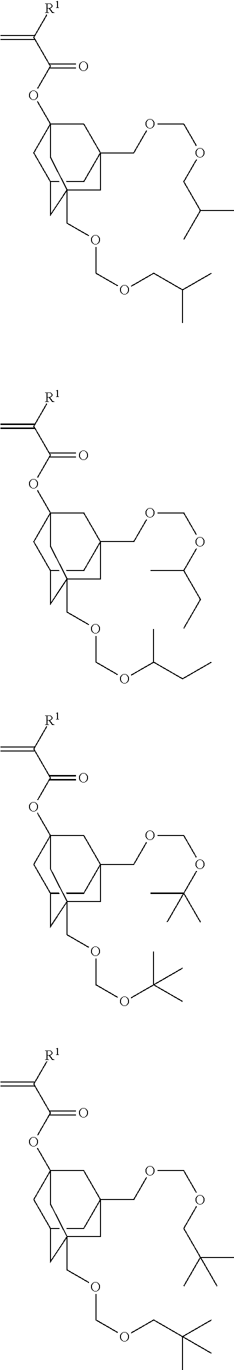

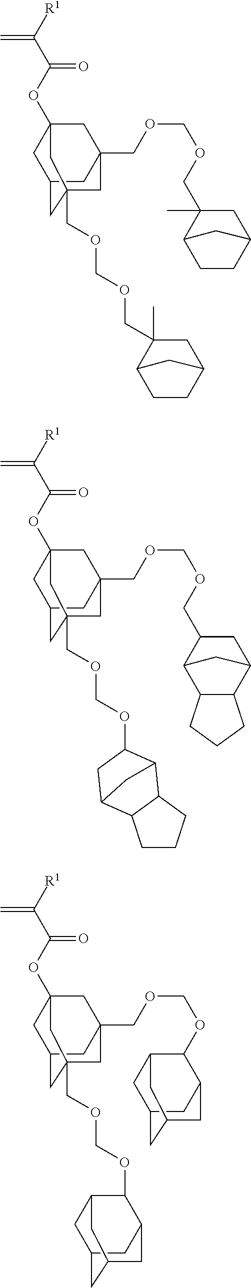

Examples of recurring units (a2) having formula (1-2) are given below, but not limited thereto. Herein, R¹ is as defined above, and Me stands for methyl.

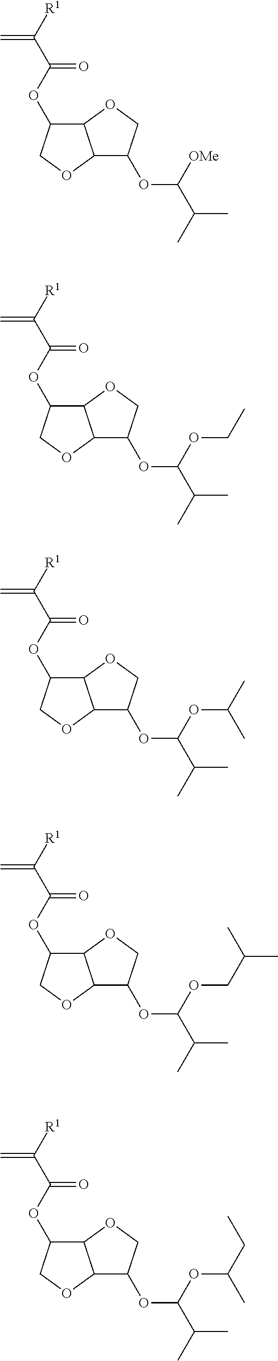

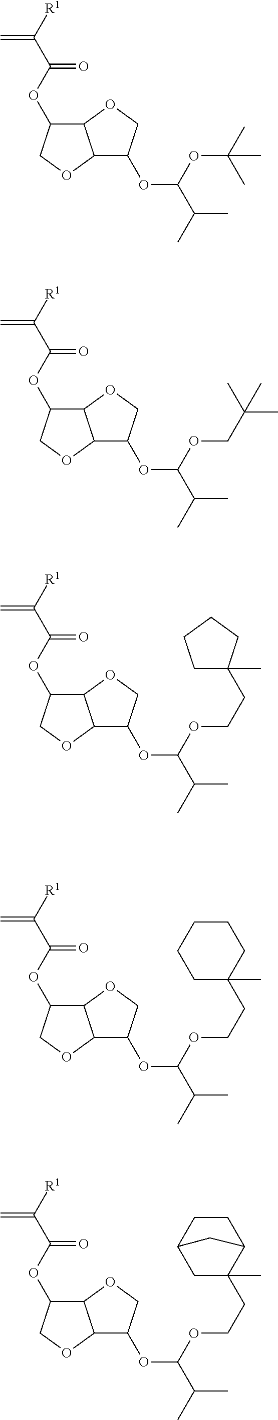

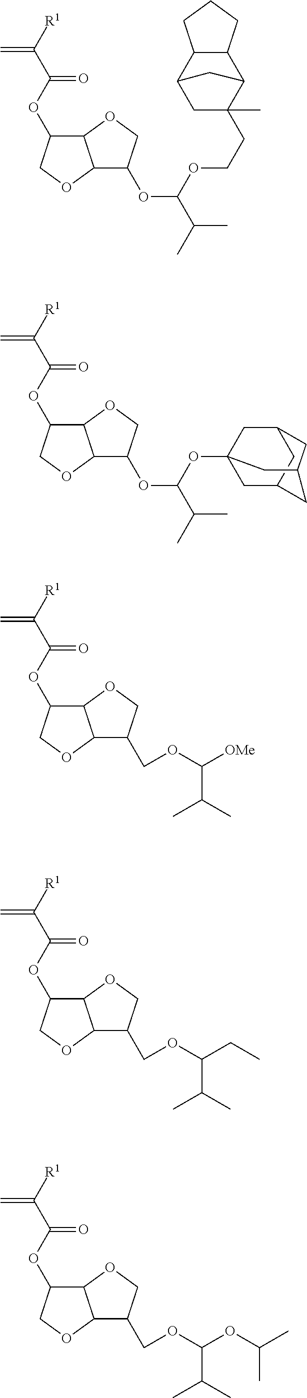

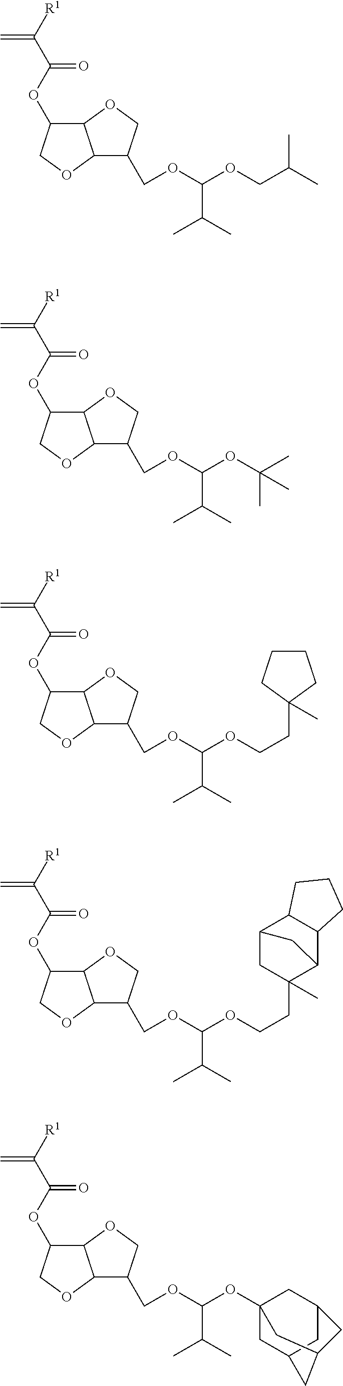

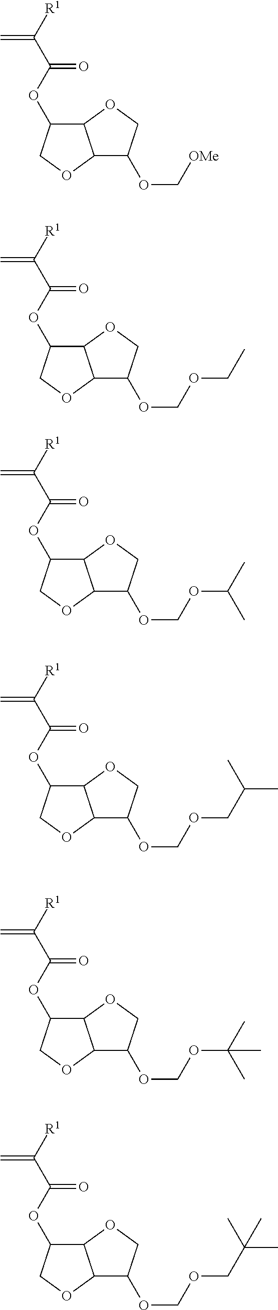

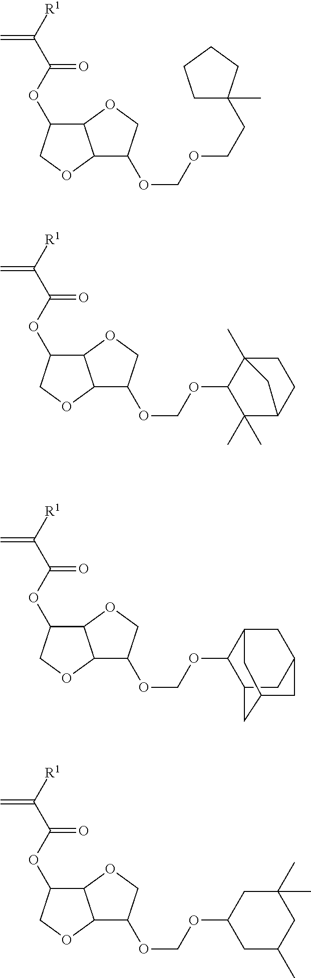

In addition to the recurring units (a1) and/or (a2) having formula (1-1) or (1-2), the polymer (A) may further comprise recurring units (a3) having a hydroxyl group substituted with an acid labile group, as illustrated below. While a polymer comprising recurring units (a3) alone may be used, a copolymer comprising recurring units (a1) and/or (a2) and recurring units (a3) copolymerized therewith may be used. When recurring unit (a3) is copolymerized, its content a3 is in the range: 0<a3<1.0, and preferably up to 50 mol %, more preferably up to 20 mol %, based on the moles of a1+a2. Herein, R¹ is as defined above, and Me stands for methyl.

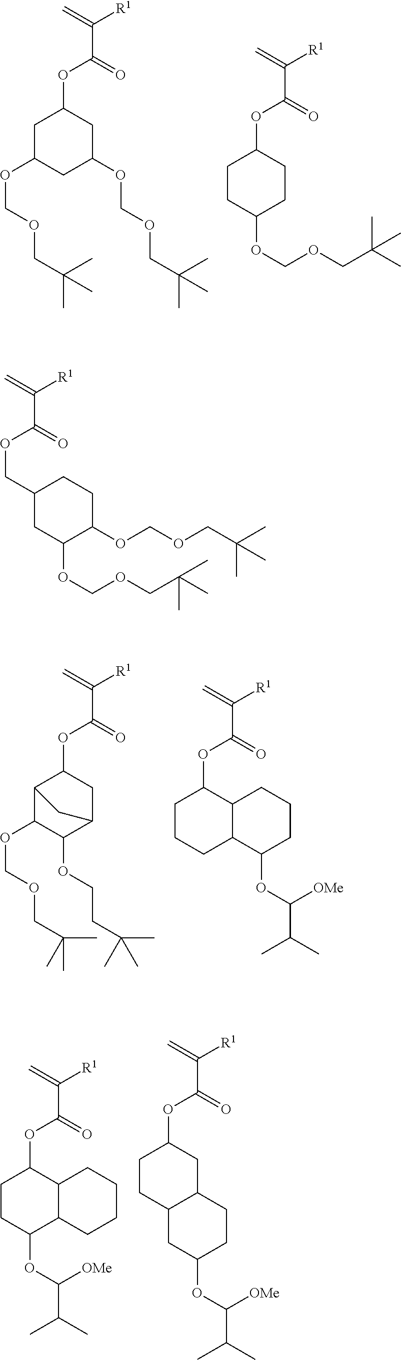

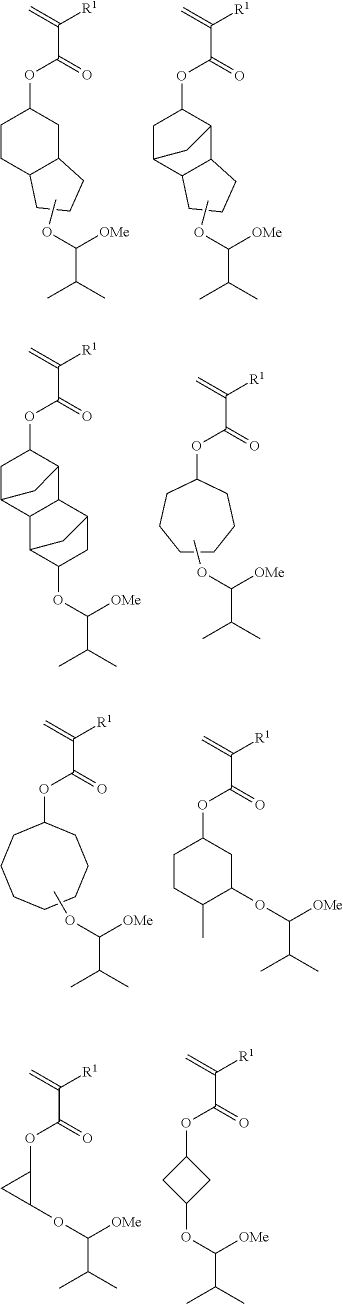

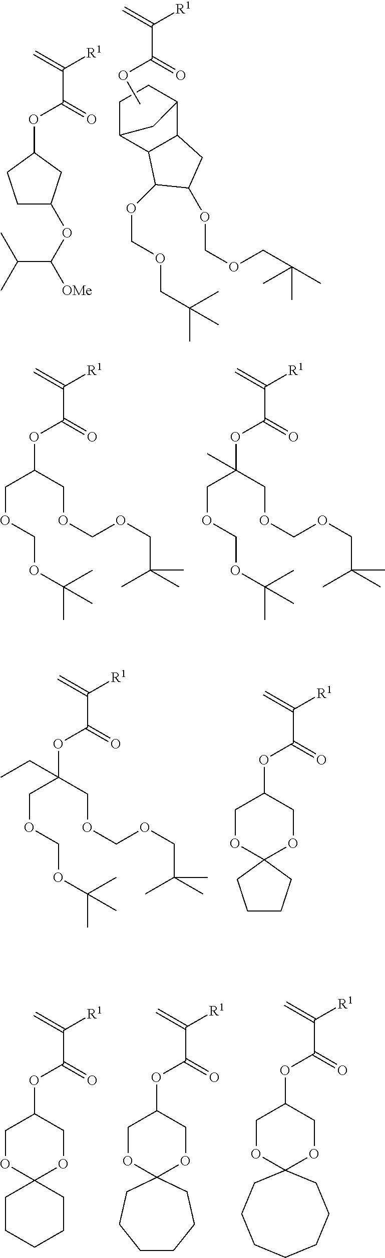

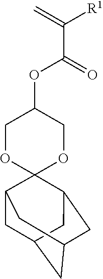

In addition to the recurring units (a) having formula (1), the polymer (A) may further comprise recurring units (b) having a carboxyl group substituted with an acid labile group, represented by the general formula (14).

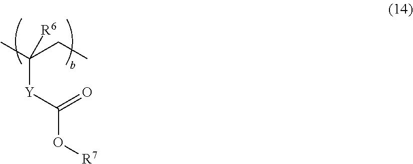

Herein R⁶ is hydrogen or methyl, R⁷ is an acid labile group, Y is a single bond or —C(═O)—O—R⁸— wherein R⁸ is a C₁-C₁₀ straight, branched or cyclic alkylene group which may contain an ether or ester radical, or a naphthylene group, and b is a number in the range: 0≦b<1.0.

Suitable monomers Mb from which recurring units (b) are derived have the following formula:

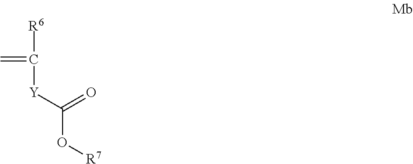

wherein R⁶, R⁷, and Y are as defined above.

Examples of the monomers Mb having different Y structures are given below wherein R⁶ and R⁷ are as defined above.

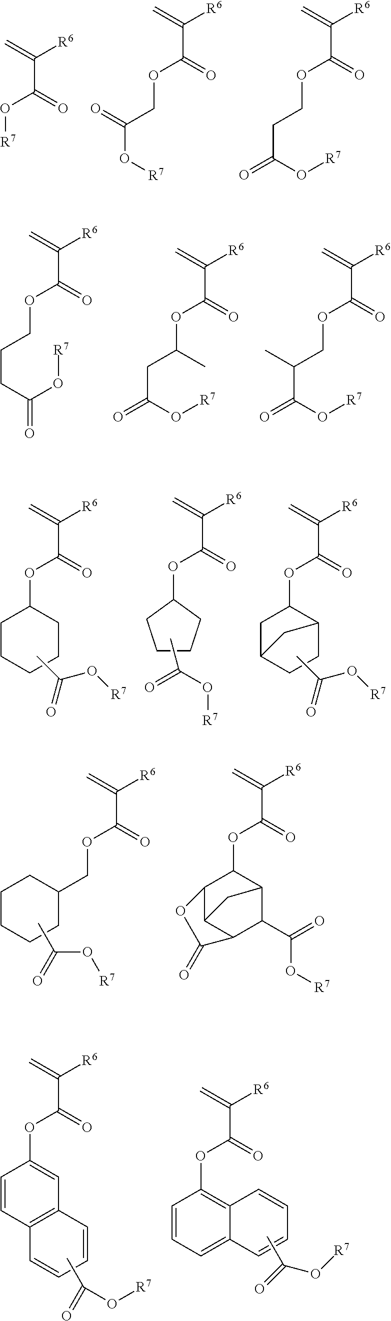

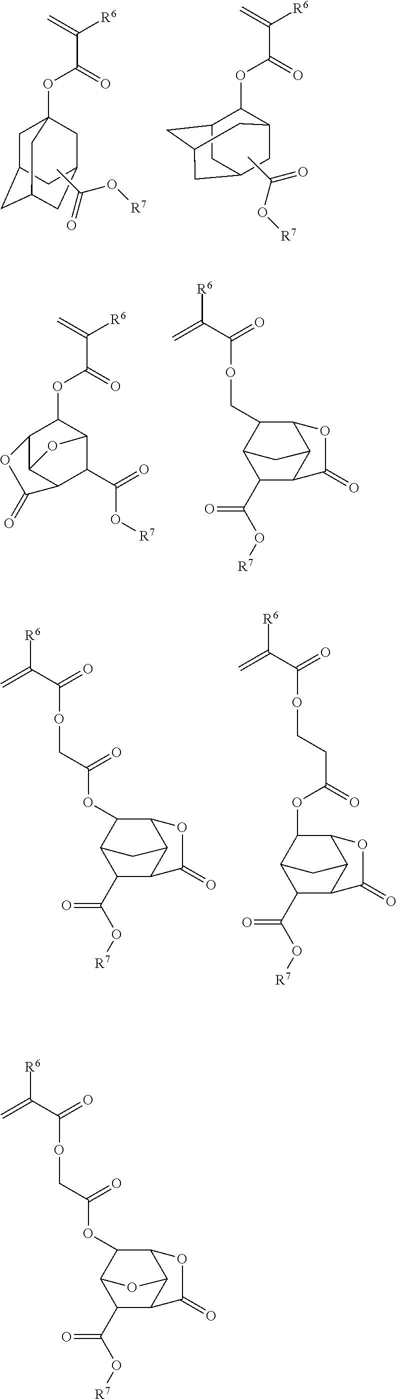

The acid labile group represented by R⁰ in formula (1) and R⁷ in formula (14) may be selected from a variety of such groups. Suitable acid labile groups include acetal groups of the following formula (AL-10), tertiary alkyl groups of the following formula (AL-11), and oxoalkyl groups of 4 to 20 carbon atoms, but are not limited thereto.

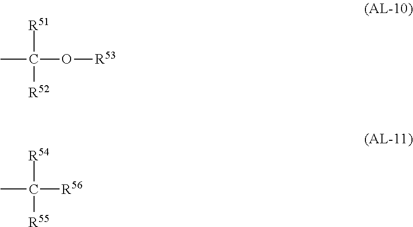

In formula (AL-10), R⁵³ is a monovalent hydrocarbon group, typically straight, branched or cyclic alkyl group, of 1 to 40 carbon atoms, more specifically 1 to 20 carbon atoms, which may contain a heteroatom such as oxygen, sulfur, nitrogen or fluorine. R⁵¹ and R⁵² each are hydrogen or a monovalent hydrocarbon group, typically straight, branched or cyclic alkyl group, of 1 to 20 carbon atoms which may contain a heteroatom such as oxygen, sulfur, nitrogen or fluorine. Alternatively, a pair of R⁵¹ and R⁵², R⁵¹ and R⁵³, or R⁵² and R⁵³ may bond together to form a ring, specifically aliphatic ring, with the carbon atom or the carbon and oxygen atoms to which they are attached, the ring having 3 to 20 carbon atoms, especially 4 to 16 carbon atoms.

In formula (AL-11), R⁵⁴, R⁵⁵ and R⁵⁶ each are a monovalent hydrocarbon group, typically straight, branched or cyclic alkyl group, of 1 to 20 carbon atoms which may contain a heteroatom such as oxygen, sulfur, nitrogen or fluorine. Alternatively, a pair of R⁵⁴ and R⁵⁵, R⁵⁴ and R⁵⁶, or R⁵⁵ and R⁵⁶ may bond together to form a ring, specifically aliphatic ring, with the carbon atom to which they are attached, the ring having 3 to 20 carbon atoms, especially 4 to 16 carbon atoms.

Illustrative examples of the acetal groups of formula (AL-10) include those of the following formulae (AL-10)-1 to (AL-10)-34.

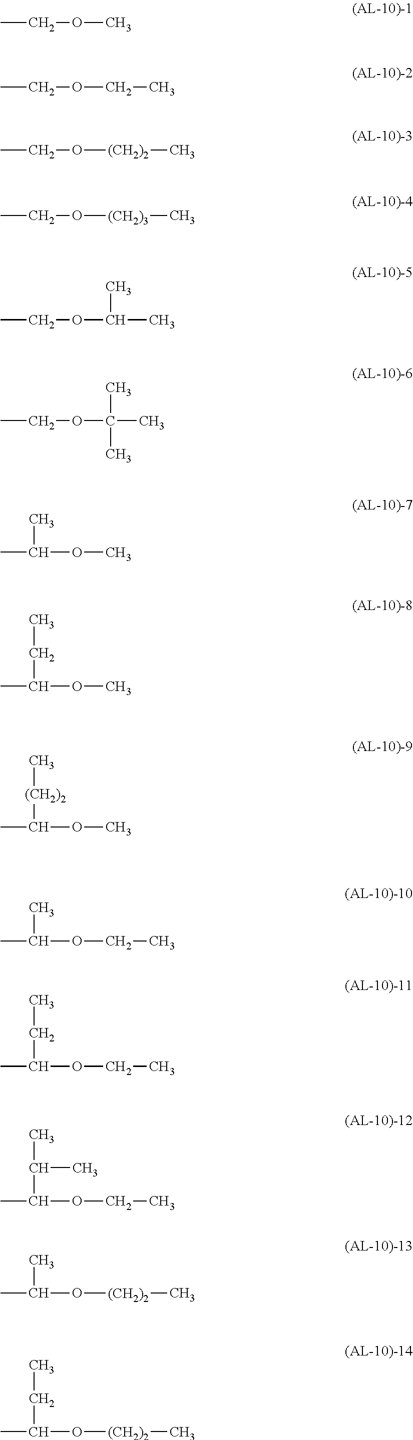

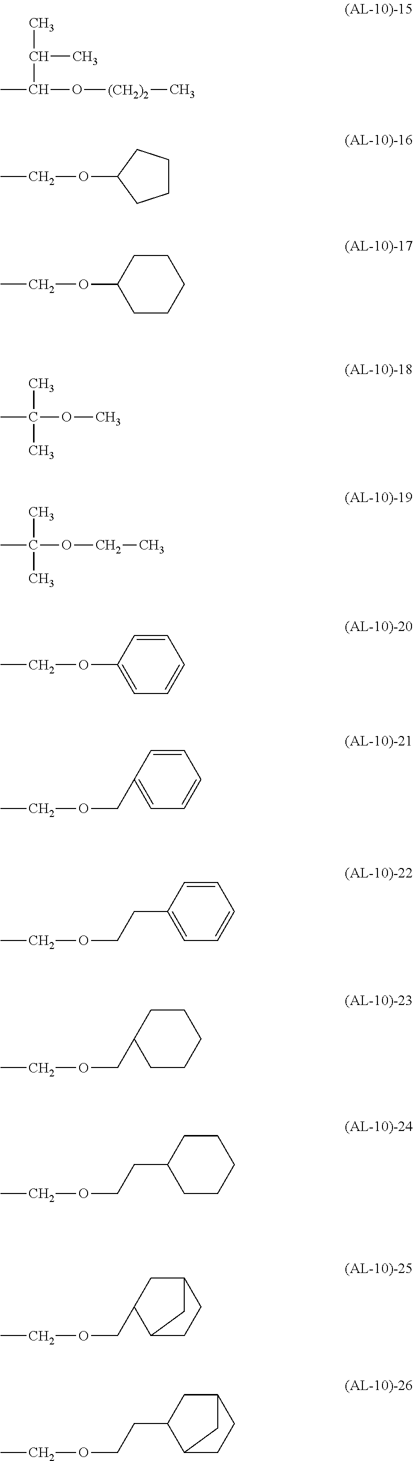

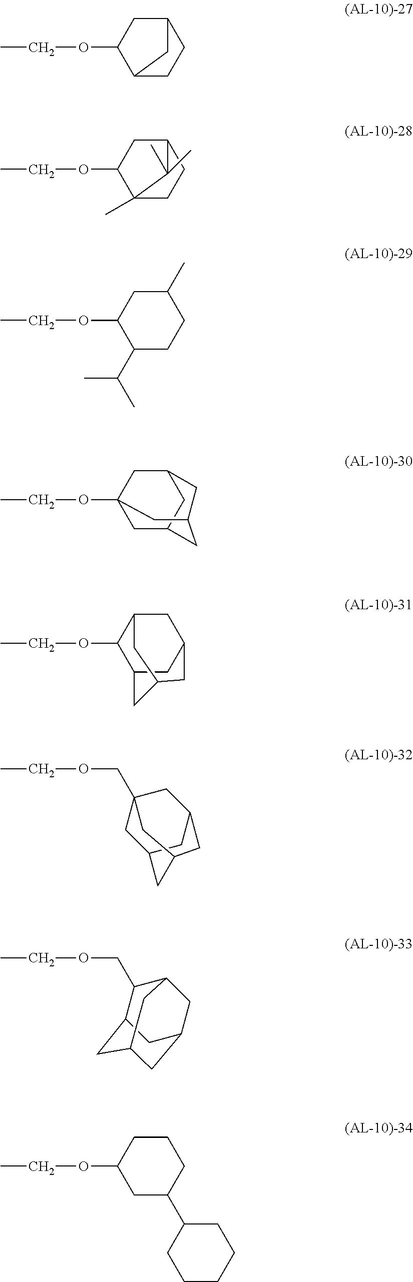

Other examples of acid labile groups include those of the following formula (AL-10a) or (AL-10b) while the polymer may be crosslinked within the molecule or between molecules with these acid labile groups.

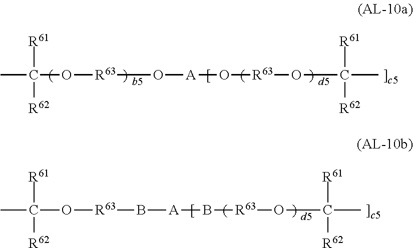

Herein R⁶¹ and R⁶² each are hydrogen or a C₁-C₈ straight, branched or cyclic alkyl group, or R⁶¹ and R⁶² may bond together to form a ring with the carbon atom to which they are attached, and R⁶¹ and R⁶² are C₁-C₈ straight or branched alkylene groups when they form a ring. R⁶³ is a C₁-C₁₀ straight, branched or cyclic alkylene group. Each of b5 and d5 is 0 or an integer of 1 to 10, preferably 0 or an integer of 1 to 5, and c5 is an integer of 1 to 7. “A” is a (c5+1)-valent aliphatic or alicyclic saturated hydrocarbon group, aromatic hydrocarbon group or heterocyclic group having 1 to 50 carbon atoms, which may be separated by a heteroatom such as oxygen, sulfur or nitrogen or in which some hydrogen atoms attached to carbon atoms may be substituted by hydroxyl, carboxyl, carbonyl radicals or fluorine atoms. “B” is —CO—O—, —NHCO—O— or —NHCONH—.

Preferably, “A” is selected from divalent to tetravalent, straight, branched or cyclic C₁-C₂₀ alkylene, alkanetriyl and alkanetetrayl groups, and C₆-C₃₀ arylene groups, which may be separated by a heteroatom such as oxygen, sulfur or nitrogen or in which some hydrogen atoms attached to carbon atoms may be substituted by hydroxyl, carboxyl, acyl radicals or halogen atoms. The subscript c5 is preferably an integer of 1 to 3.

The crosslinking acetal groups of formulae (AL-10a) and (AL-10b) are exemplified by the following formulae (AL-10)-35 through (AL-10)-42.

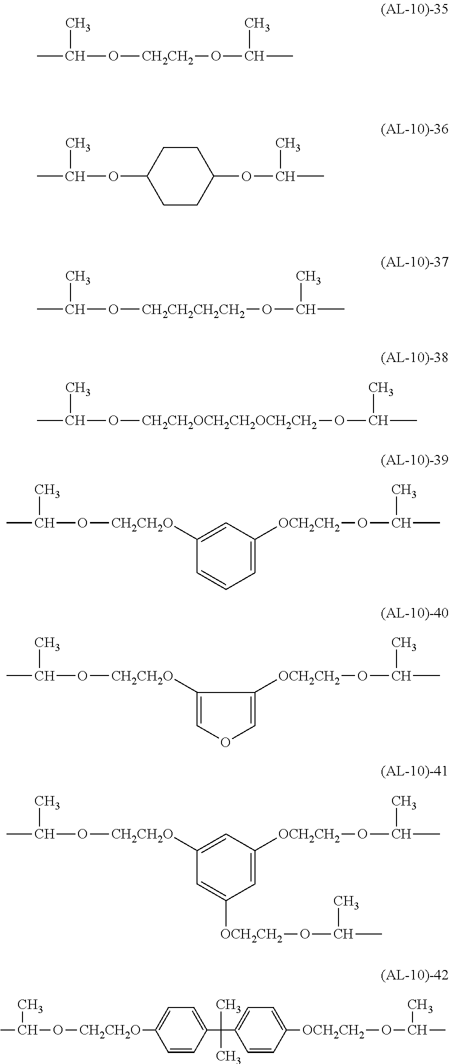

Illustrative examples of the tertiary alkyl of formula (AL-11) include tert-butyl, triethylcarbyl, 1-ethylnorbornyl, 1-methylcyclohexyl, 1-ethylcyclopentyl, and tert-amyl as well as those of formulae (AL-11)-1 to (AL-11)-16.

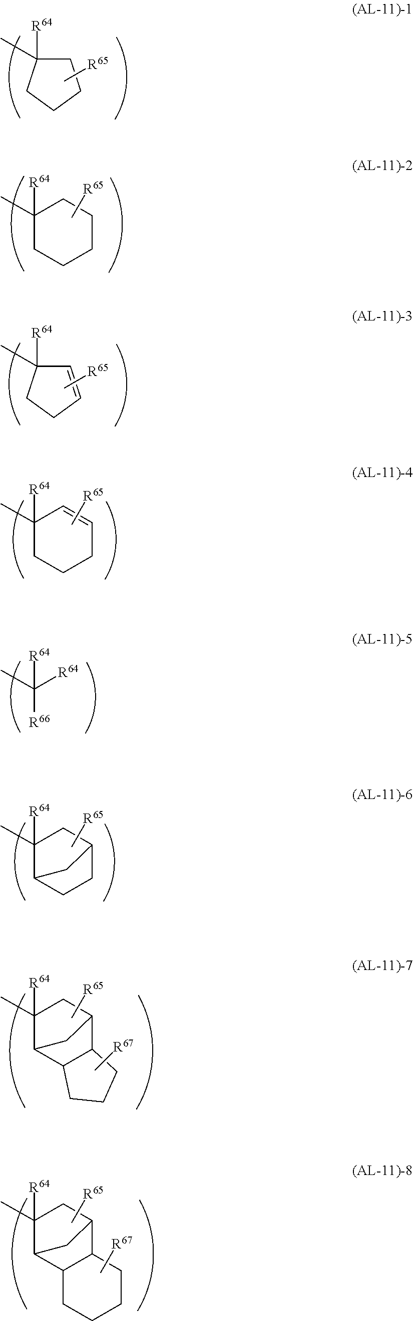

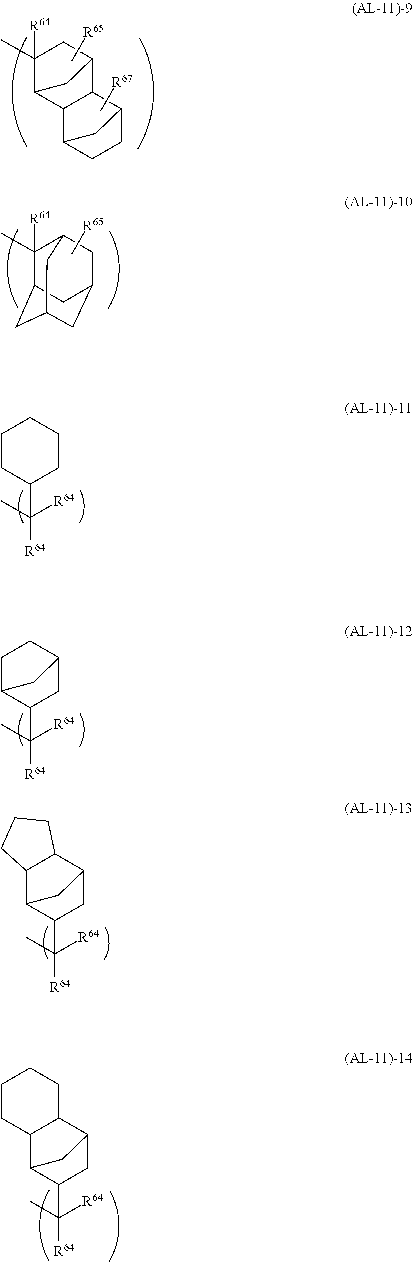

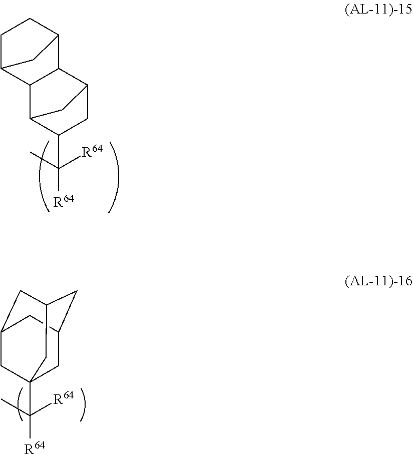

Herein R⁶⁴ is each independently a C₁-C₈ straight, branched or cyclic alkyl group, C₆-C₂₀ aryl group or C₇-C₂₀ aralkyl group, and two R⁶⁴ may bond together to form an aliphatic ring with the carbon atom to which they are attached. R⁶⁵ and R⁶⁷ each are hydrogen or a C₁-C₂₀ straight, branched or cyclic alkyl group. R⁶⁶ is a C₆-C₂₀ aryl group or C₇-C₂₀ aralkyl group.

With acid labile groups containing R⁶⁸ (representative of a di- or poly-valent alkylene or arylene group) as shown by formulae (AL-11)-17 and (AL-11)-18, the polymer may be crosslinked within the molecule or between molecules. In formulae (AL-11)-17 and (AL-11)-18, R⁶⁴ is as defined above, R⁶⁸ is a single bond, or a C₁-C₂₀ straight, branched or cyclic alkylene group or arylene group which may contain a heteroatom such as oxygen, sulfur or nitrogen, and b6 is an integer of 0 to 3.

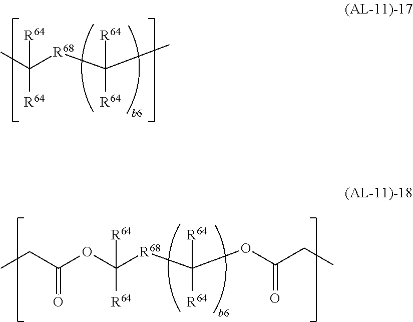

The groups represented by R⁶⁴, R⁶⁵, R⁶⁶ and R⁶⁷ may contain a heteroatom such as oxygen, nitrogen or sulfur. Such groups are exemplified by the following formulae (AL-12)-1 to (AL-12)-7.

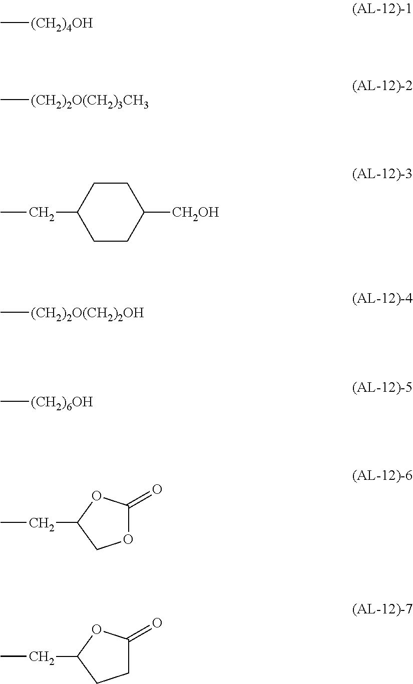

As the acid labile group of formula (AL-11), groups having an exo-form structure represented by the formula (AL-11)-19 are especially preferred.

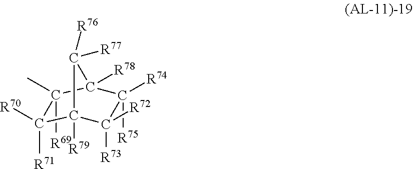

Herein, R⁶⁹ is a straight, branched or cyclic C₁-C₈ alkyl group or an optionally substituted C₆-C₂₀ aryl group; R⁷⁰ to R⁷⁵, R⁷⁸ and R⁷⁹ are each independently hydrogen or a monovalent hydrocarbon group, typically alkyl, of 1 to 15 carbon atoms which may contain a heteroatom; and R⁷⁶ and R⁷⁷ are hydrogen or a monovalent hydrocarbon group, typically alkyl, of 1 to 15 carbon atoms which may contain a heteroatom. Alternatively, a pair of R⁷⁰ and R⁷¹, R⁷² and R⁷⁴, R⁷² and R⁷⁵, R⁷³ and R⁷⁵, R⁷³ and R⁷⁹, R⁷⁴ and R⁷⁸, R⁷⁶ and R⁷⁷, or R⁷⁷ and R⁷⁸ may bond together to form a ring, specifically aliphatic ring, with the carbon atom(s) to which they are attached, and in this case, each ring-former R is a divalent hydrocarbon group, typically alkylene, of 1 to 15 carbon atoms which may contain a heteroatom. Also, a pair of R⁷⁰ and R⁷⁹, R⁷⁶ and R⁷⁹, or R⁷² and R⁷⁴ which are attached to vicinal carbon atoms may bond together directly to form a double bond. The formula also represents an enantiomer.

The ester form monomers from which recurring units having an exo-form structure represented by the formula (AL-11)-19 are derived are described in U.S. Pat. No. 6,448,420 (JP-A 2000-327633), with such recurring units being illustrated below.

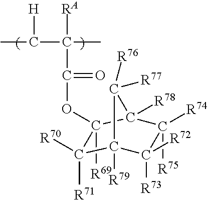

Herein R^{A} is hydrogen or methyl. Illustrative non-limiting examples of suitable monomers are given below.

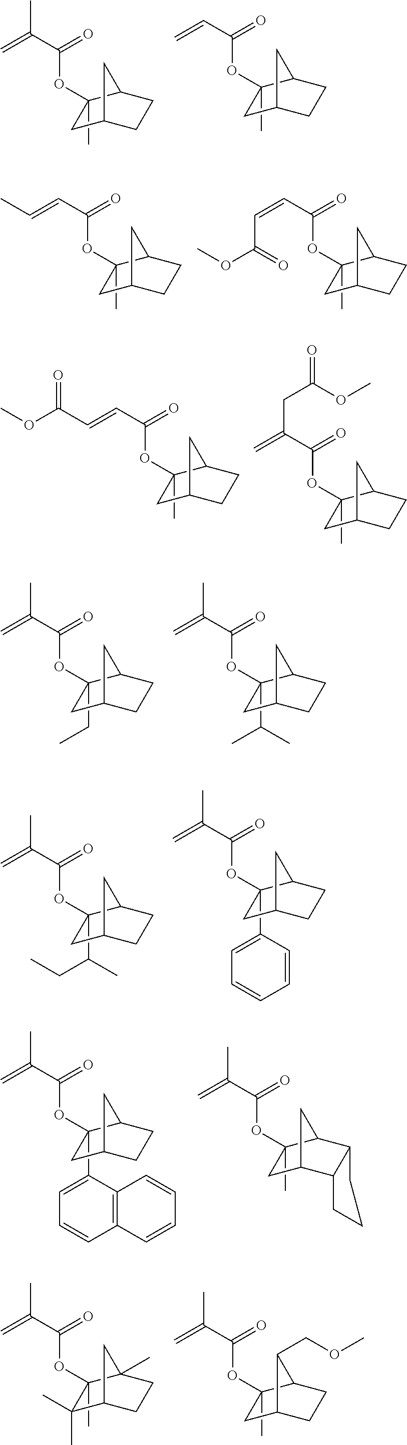

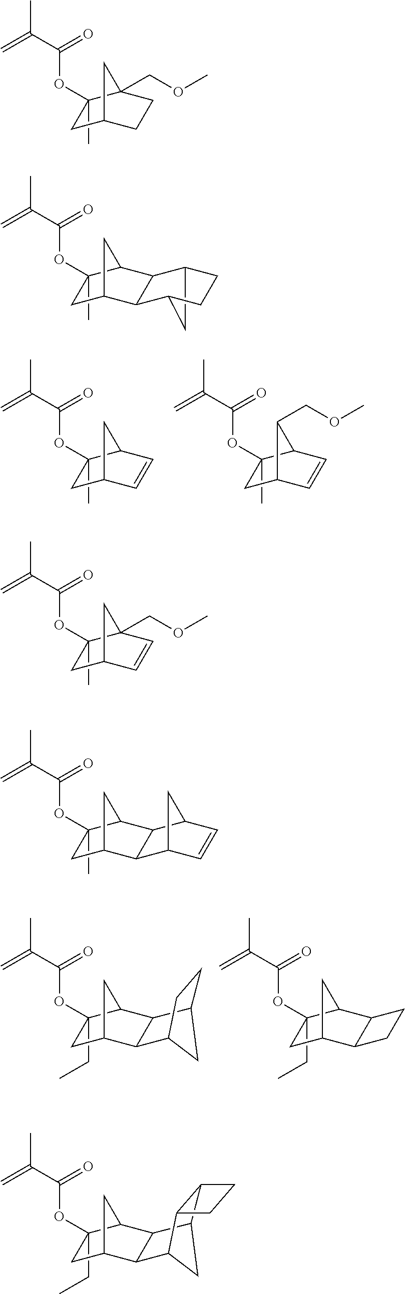

Also included in the acid labile groups of formula (AL-11) are acid labile groups having furandiyl, tetrahydrofurandiyl or oxanorbornanediyl as represented by the following formula (AL-11)-20.

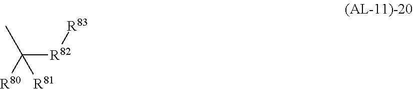

Herein, R⁸⁰ and R⁸¹ are each independently a monovalent hydrocarbon group, typically a straight, branched or cyclic C₁-C₁₀ alkyl. R⁸⁰ and R⁸¹ may bond together to form an aliphatic hydrocarbon ring of 3 to 20 carbon atoms with the carbon atom to which they are attached. R⁸² is a divalent group selected from furandiyl, tetrahydrofurandiyl and oxanorbornanediyl. R⁸³ is hydrogen or a monovalent hydrocarbon group, typically a straight, branched or cyclic C₁-C₁₀, alkyl, which may contain a heteroatom.

While the recurring units substituted with an acid labile group having furandiyl, tetrahydrofurandiyl or oxanorbornanediyl are represented by the formula:

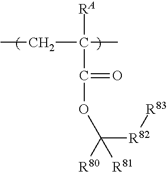

wherein R⁸⁰ to R⁸³, and R^{A} are as defined above, examples of the monomer from which these recurring units are derived are shown below. Note that Me is methyl and Ac is acetyl.

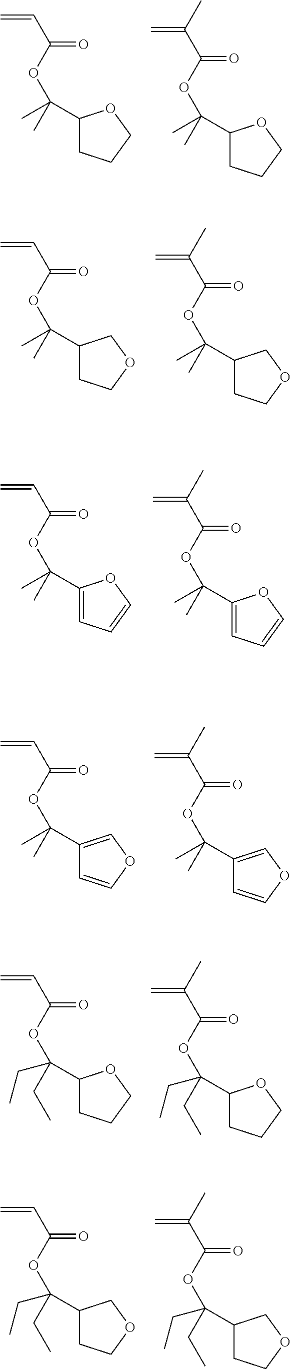

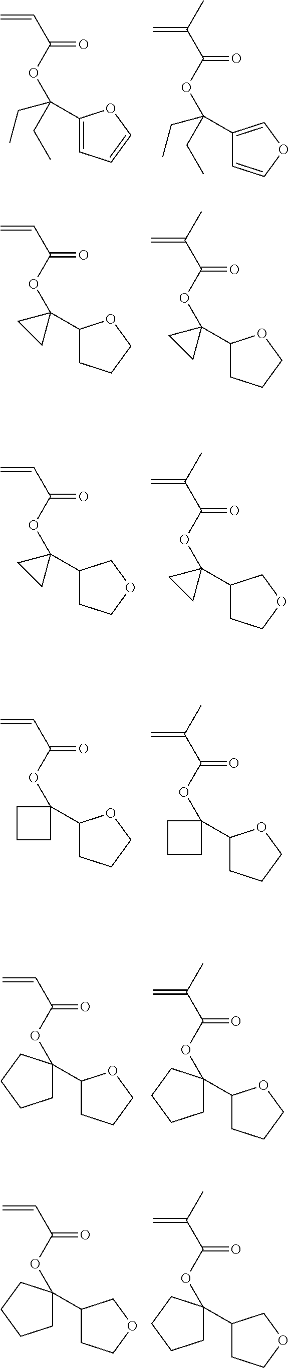

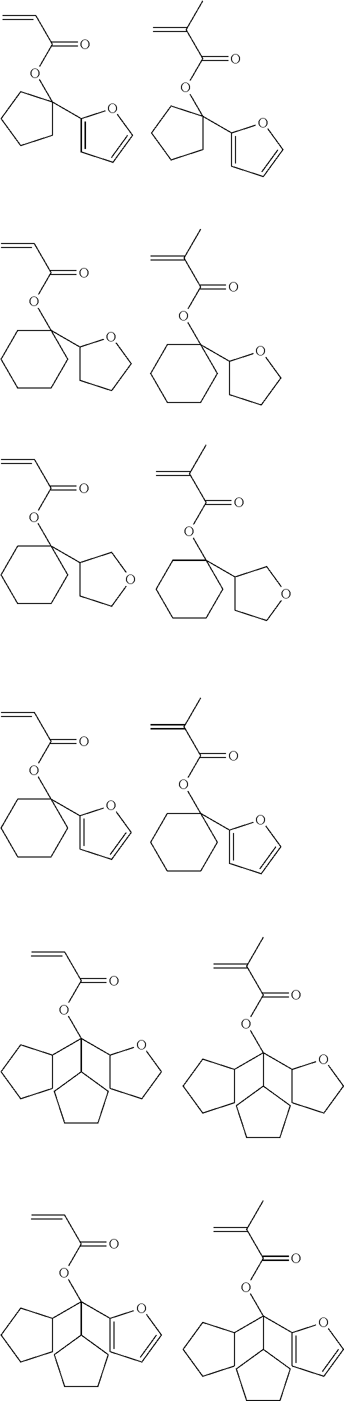

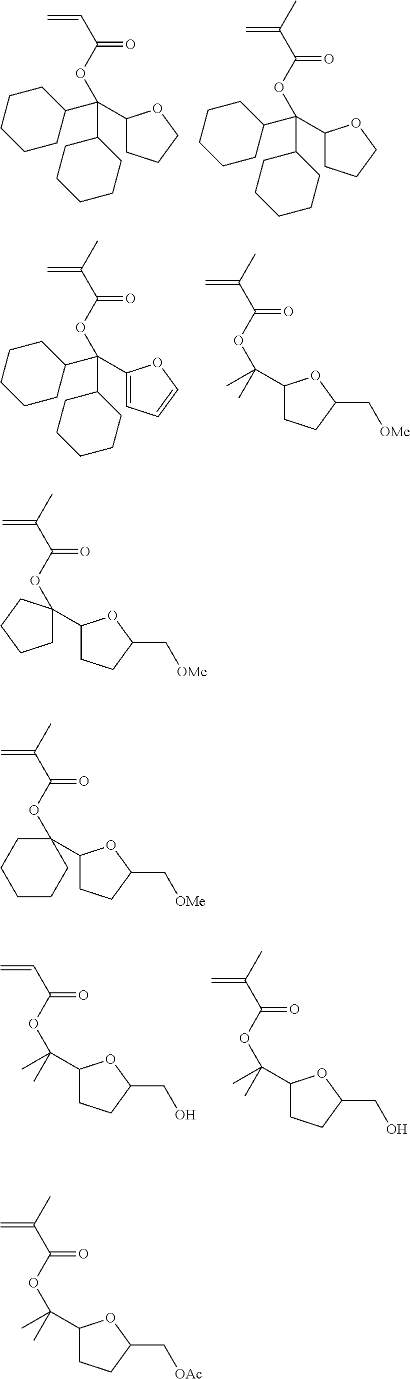

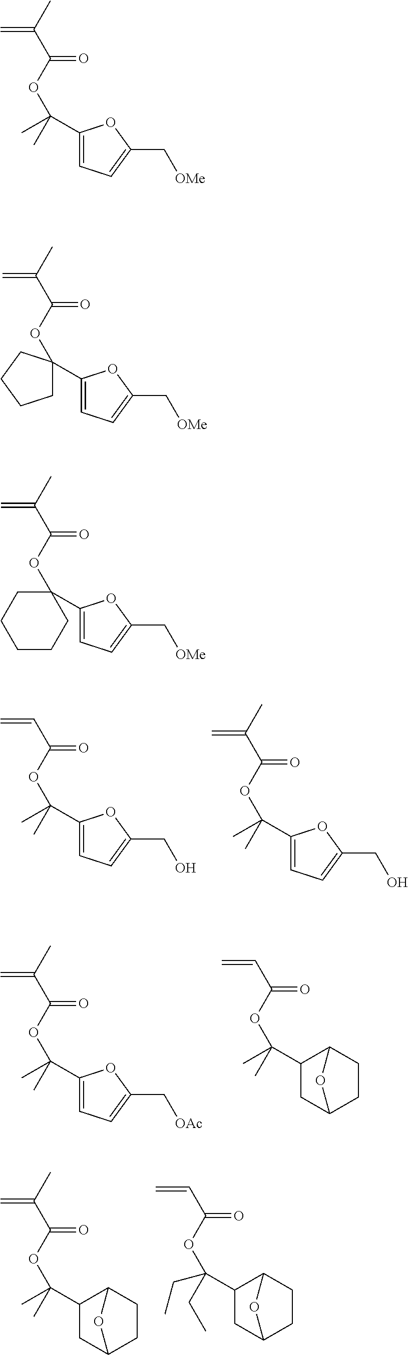

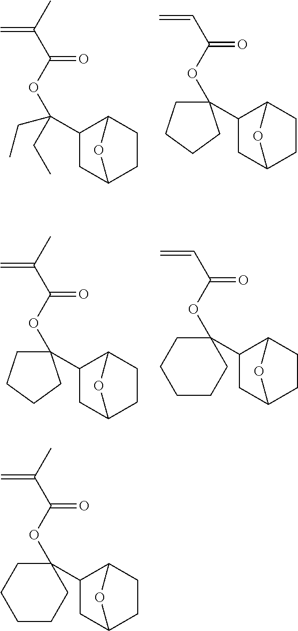

For the recurring units (b) having a carboxyl group substituted with acid labile group R⁷ as represented by formula (14), the preferred acid labile group R⁷ is a tertiary ester group, especially tertiary ester group of cyclic structure, as represented by formula (AL-11). The most preferred tertiary ester groups are those of formulae (AL-11)-1 to (AL-11)-16 and (AL-11)-19.

In addition to the recurring units (a) having formula (1), the polymer (A) in another preferred embodiment may further comprise recurring units (c) having an adhesive group selected from among hydroxyl, cyano, carbonyl, ester, ether, lactone ring, carboxyl, and carboxylic anhydride. Inter alia, units having a lactone ring are most preferred.

Examples of monomers from which recurring units (c) are derived are given below.

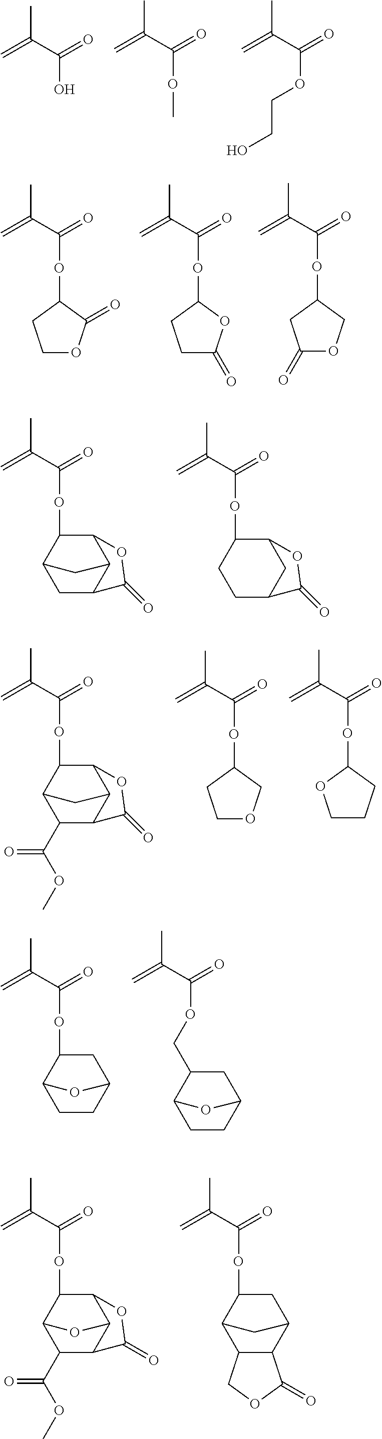

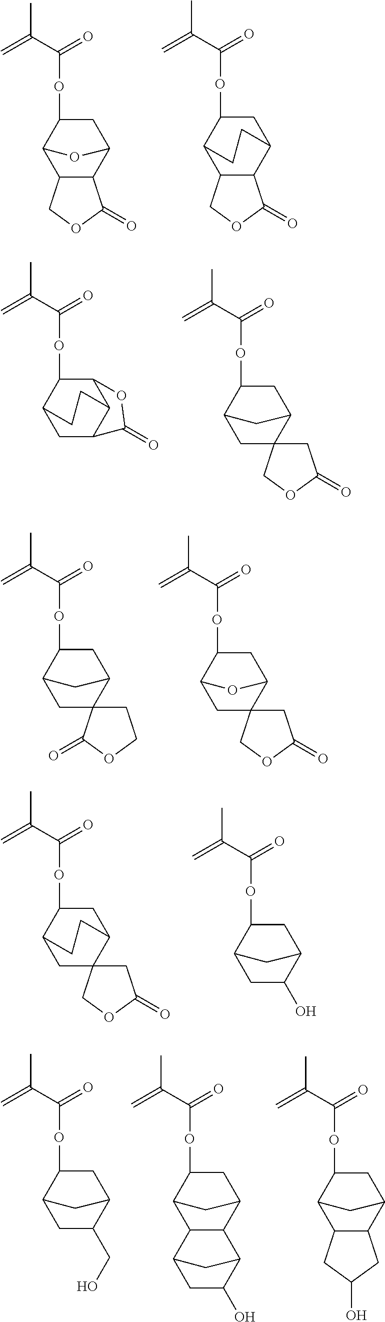

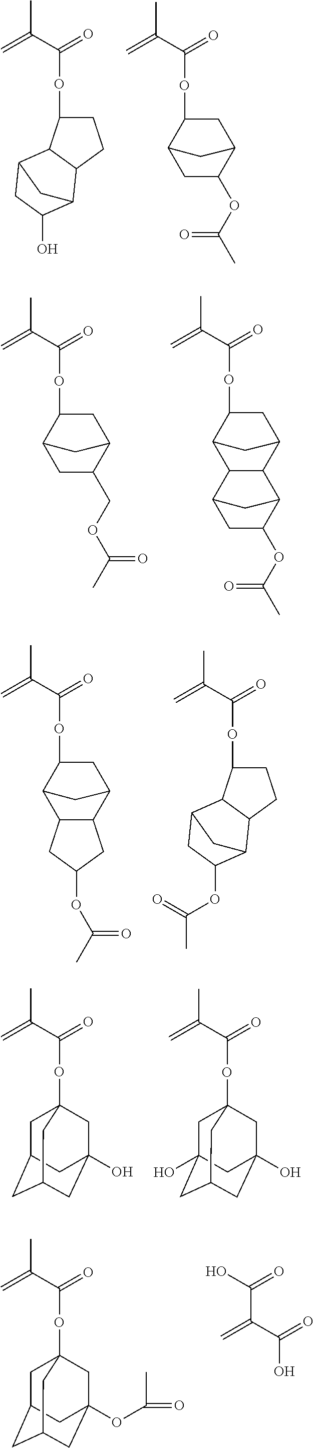

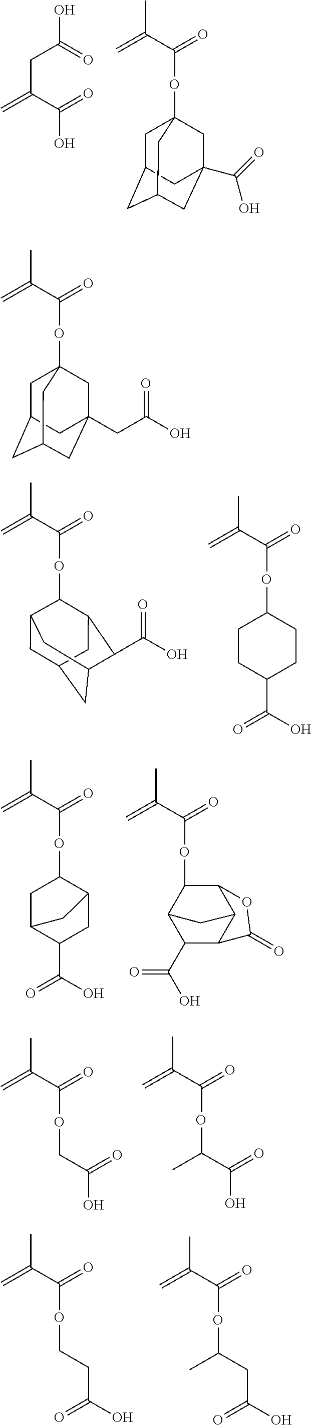

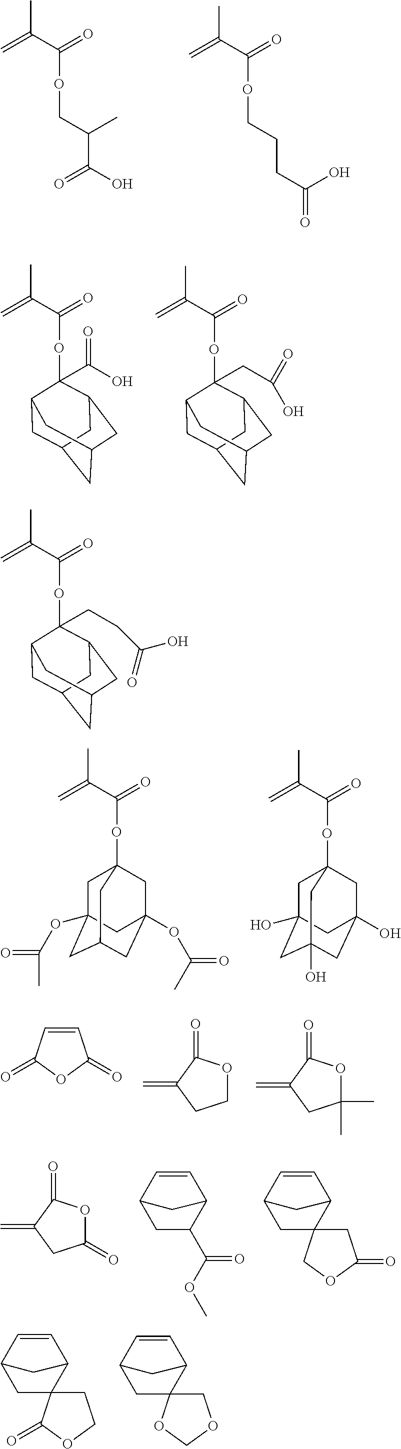

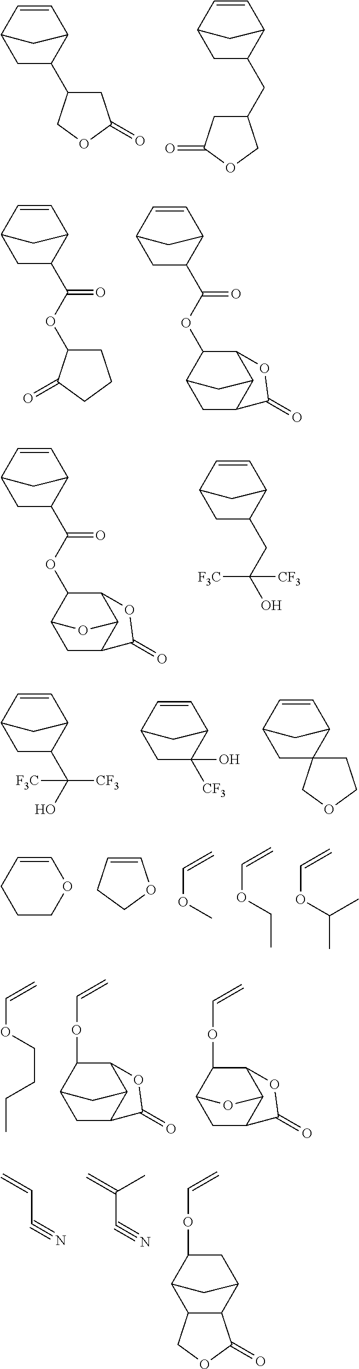

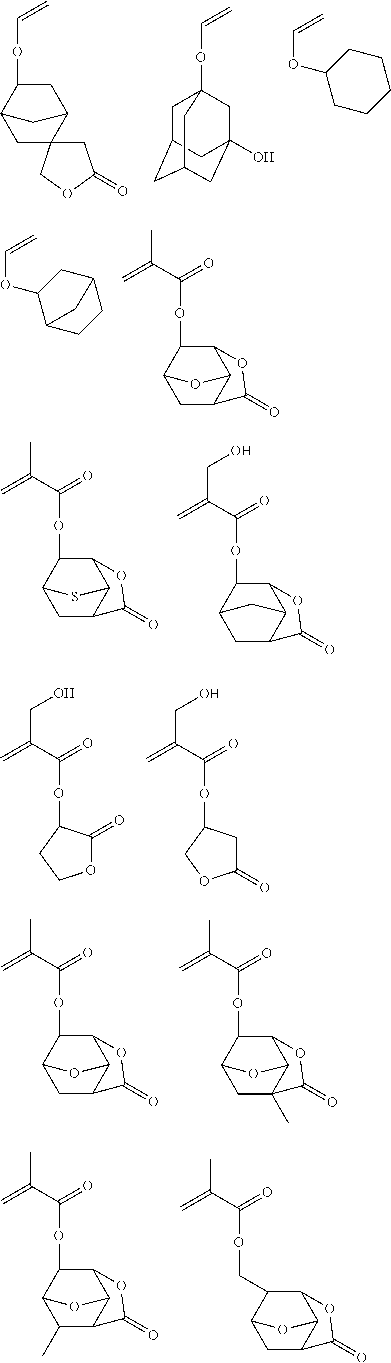

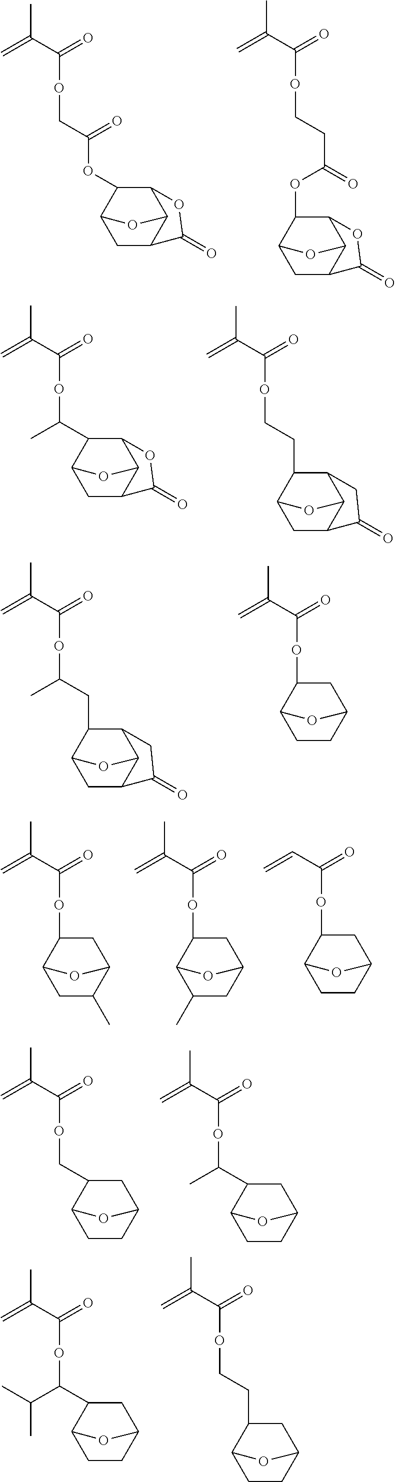

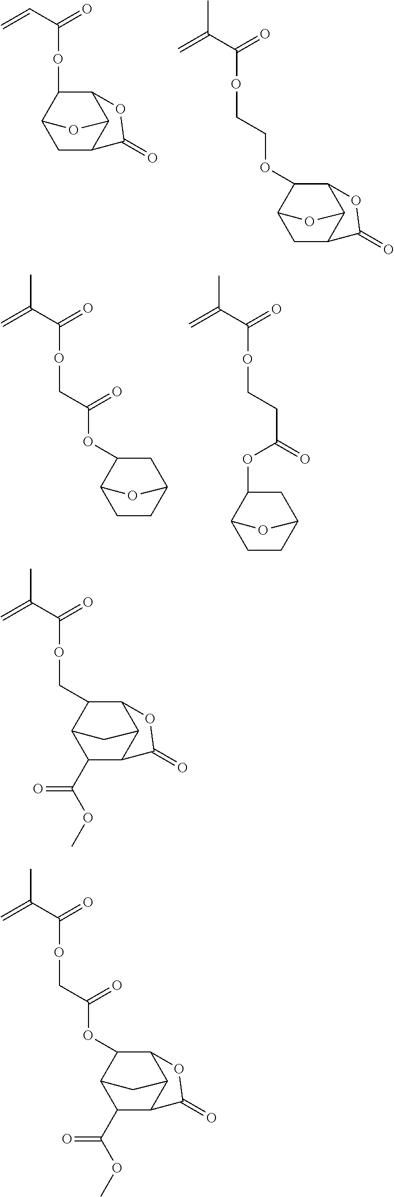

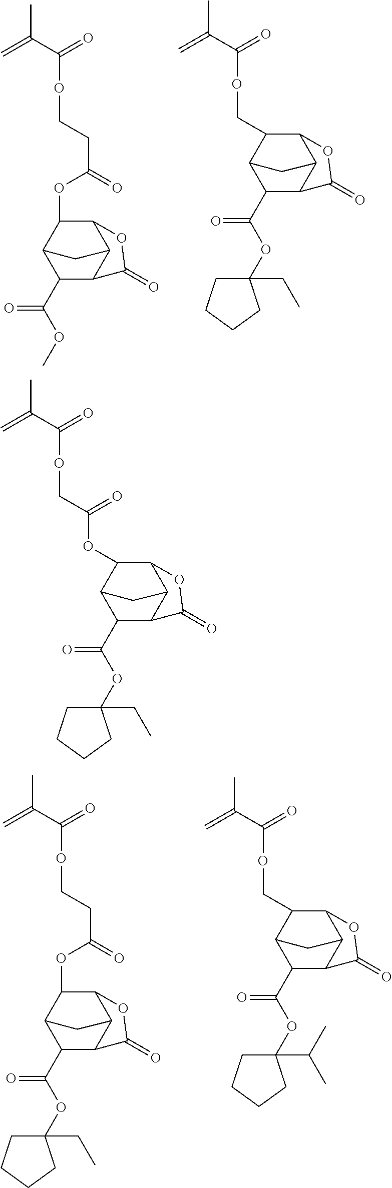

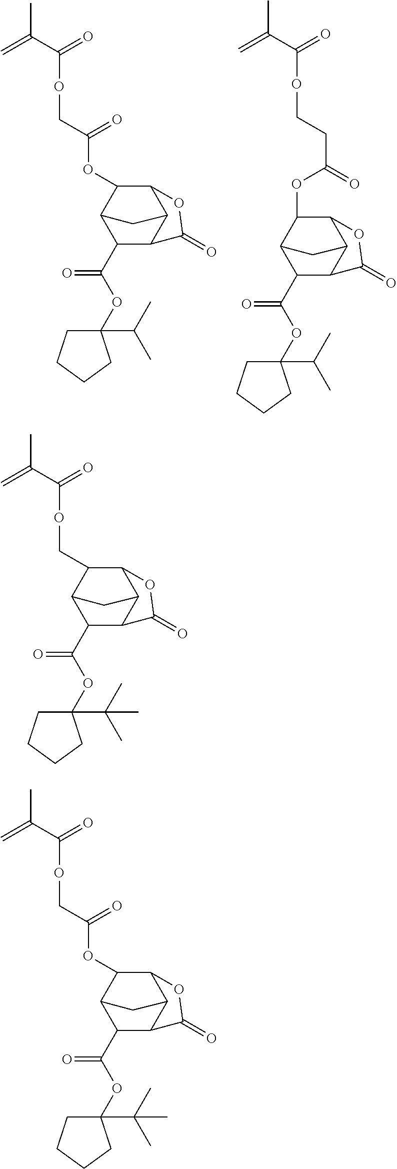

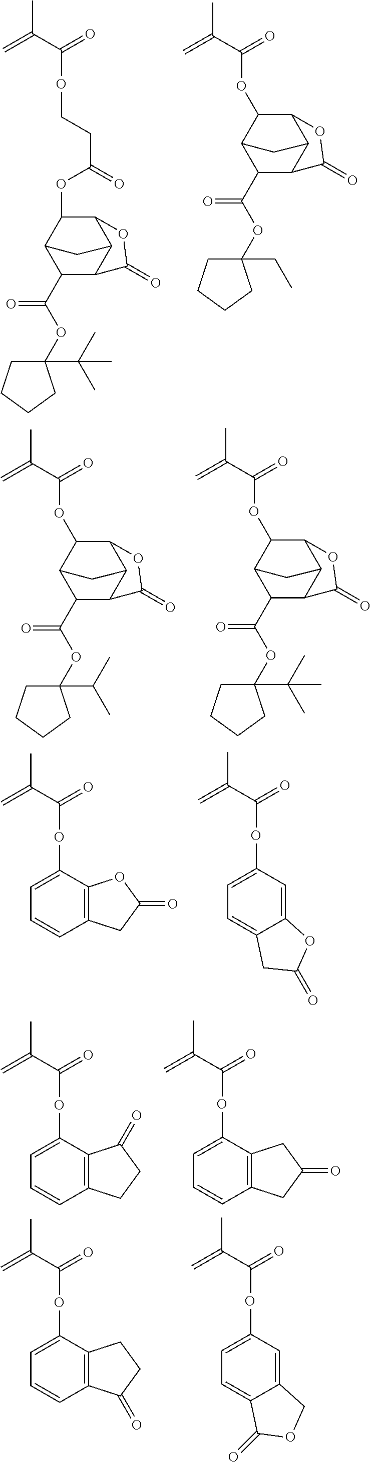

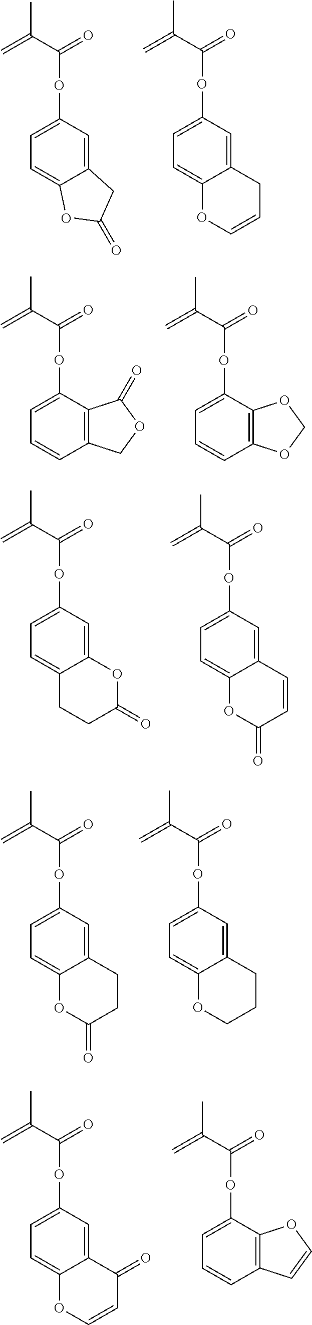

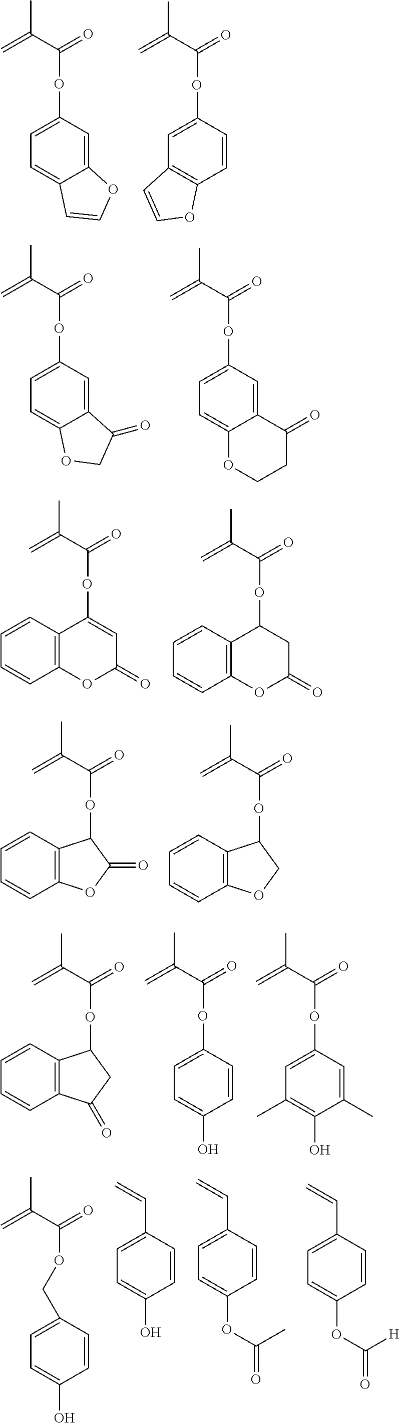

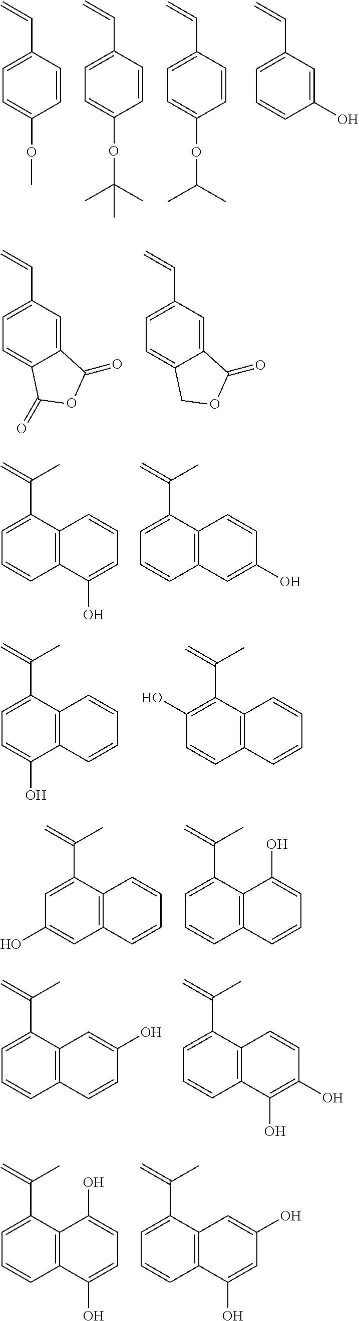

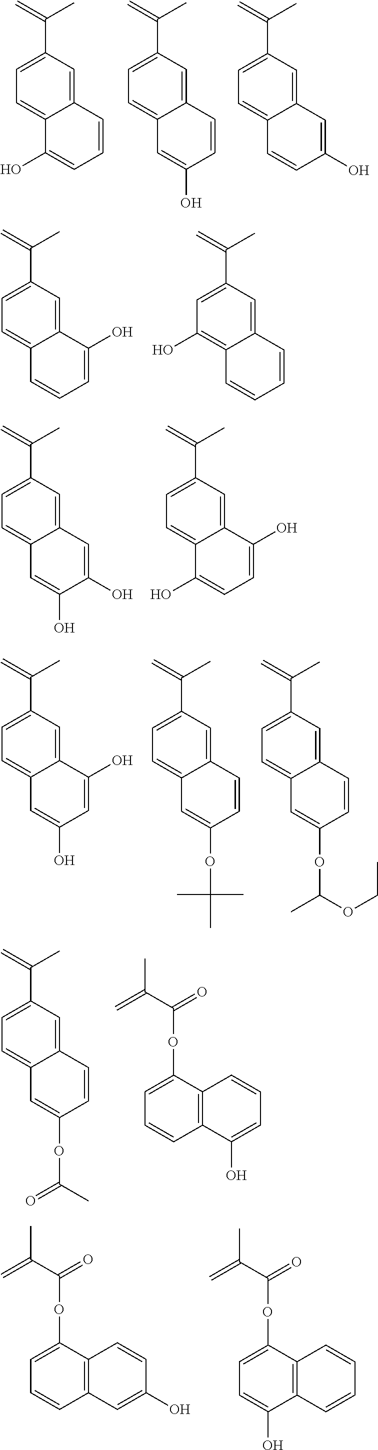

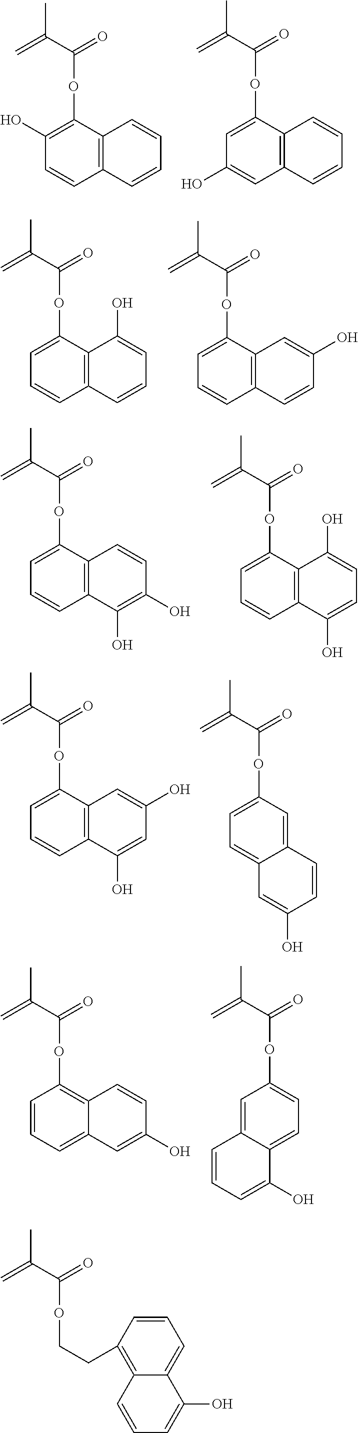

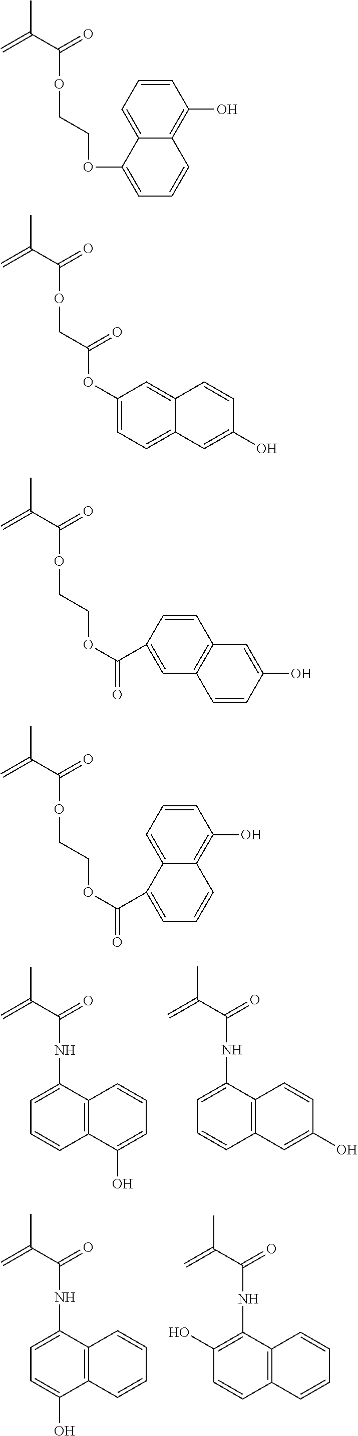

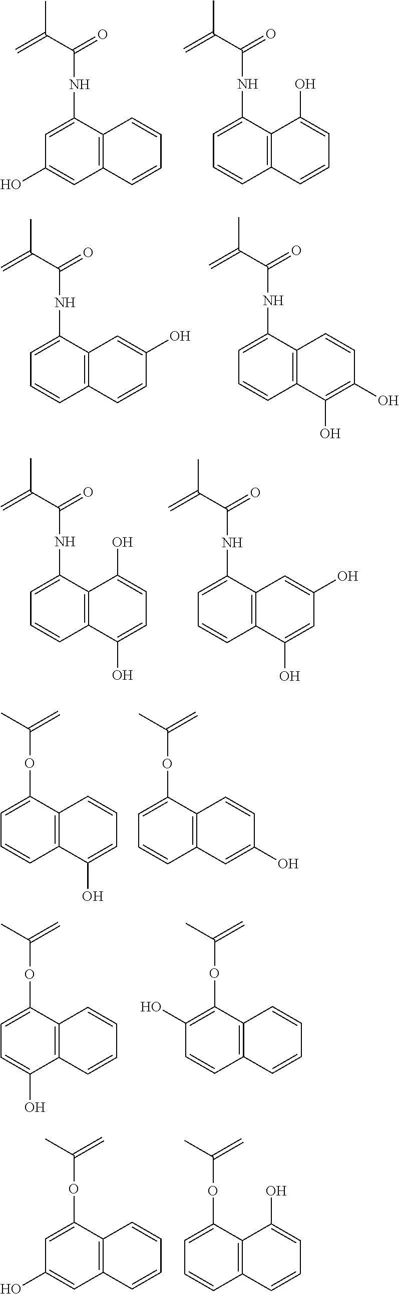

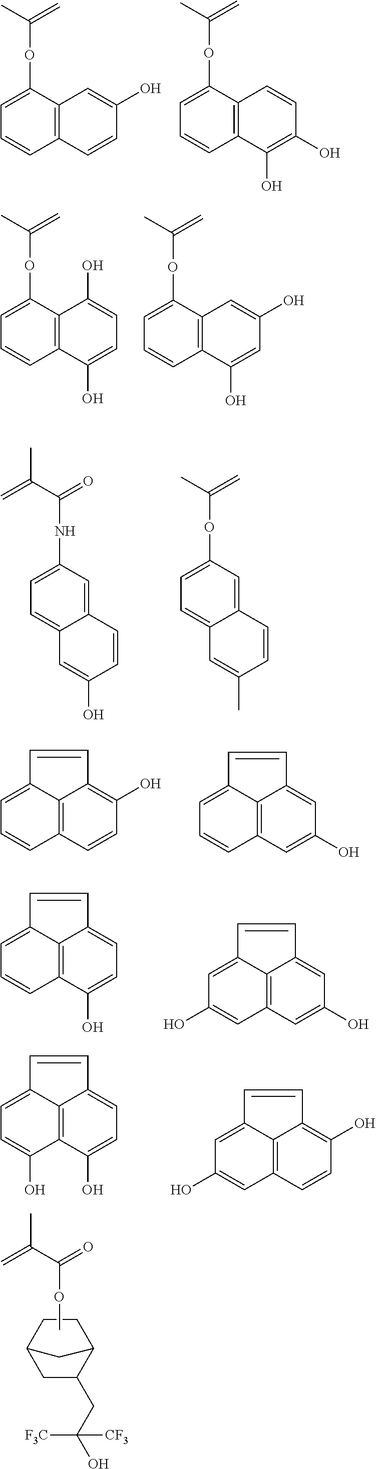

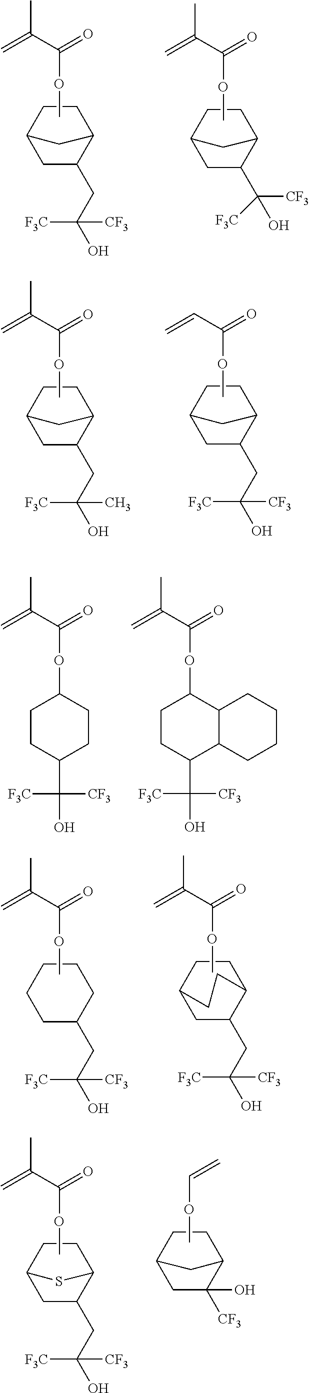

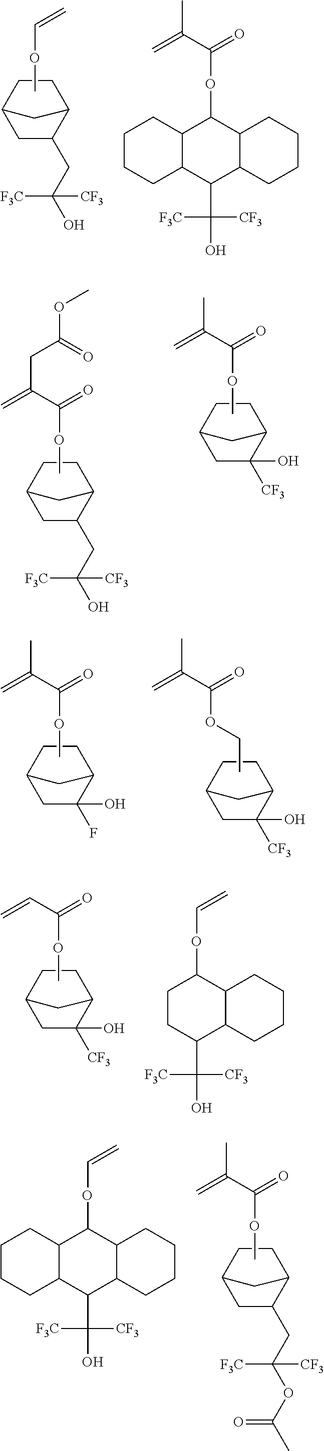

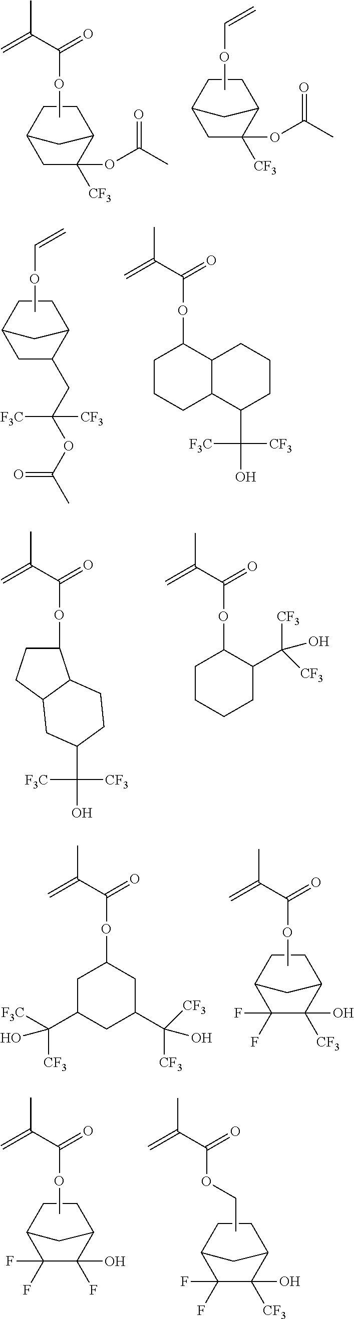

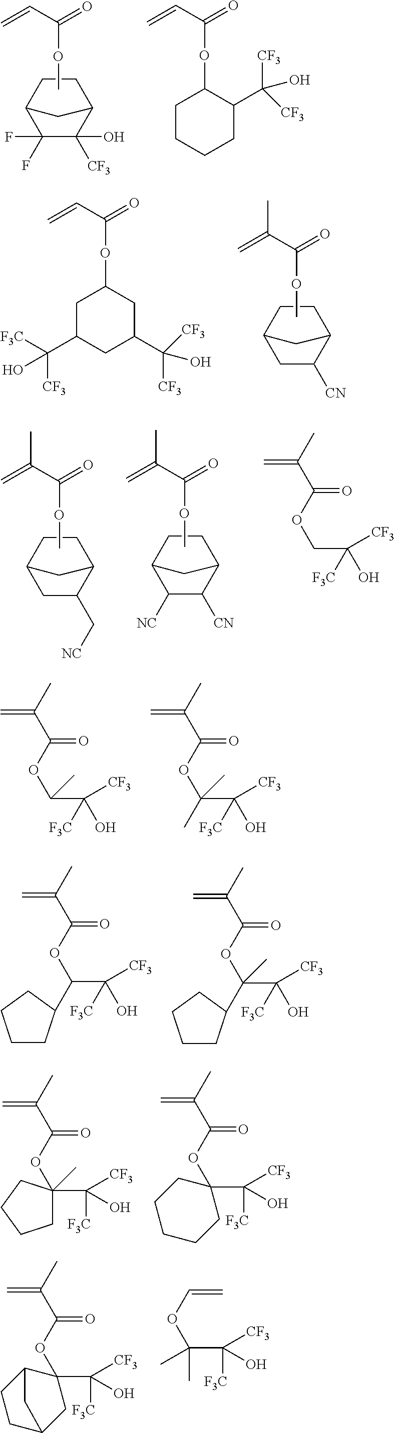

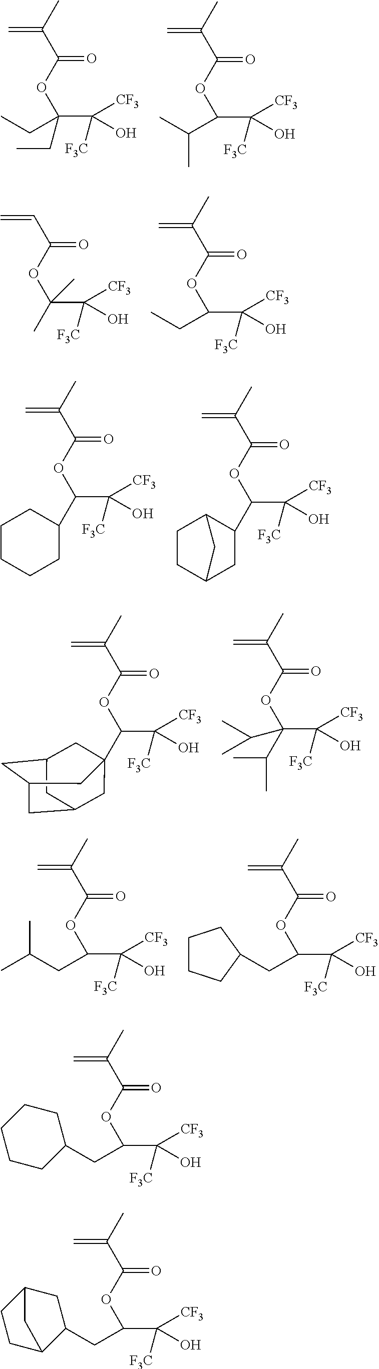

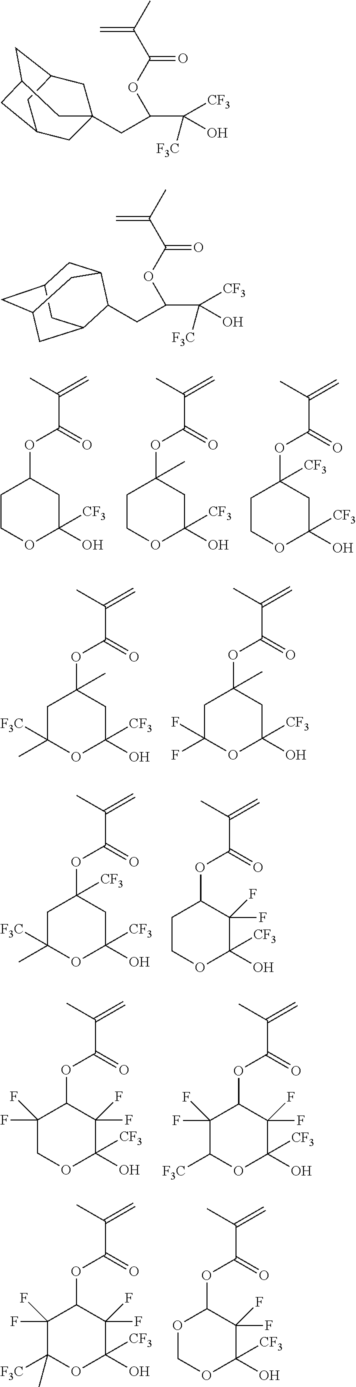

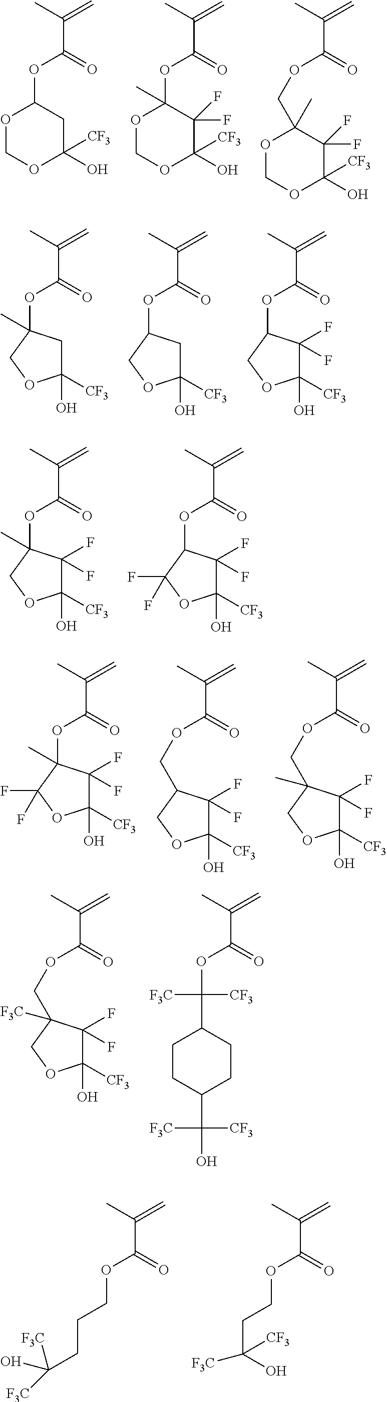

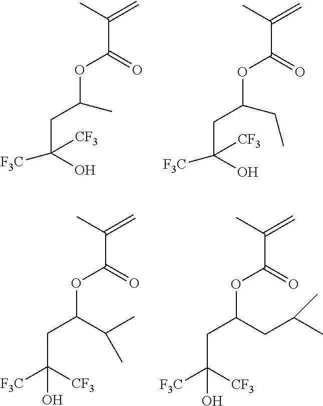

In a further preferred embodiment, the polymer (A) may have further copolymerized therein units of at least one type selected from sulfonium salts, represented by the general formulae (d1) to (d3).

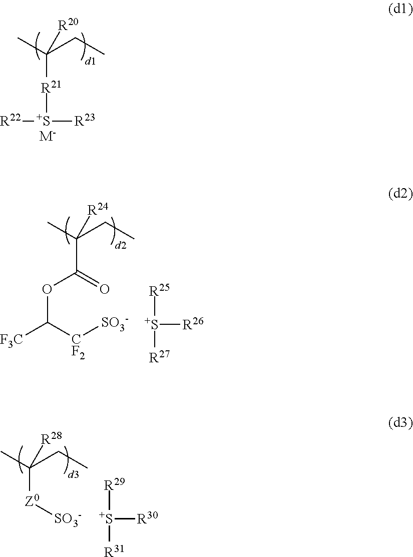

Herein R²⁰, R²⁴, and R²⁸ each are hydrogen or methyl. R²¹ is a single bond, phenylene, —O—R³³—, or —C(═O)—Y—R³³— wherein Y is oxygen or NH, and R³³ is a straight, branched or cyclic C₁-C₆ alkylene group, alkenylene or phenylene group, which may contain a carbonyl (—CO—), ester (—COO—), ether (—O—) or hydroxyl radical. R²², R²³, R²⁵, R²⁶, R²⁷, R²⁹, R³⁰, and R³¹ are each independently a straight, branched or cyclic C₁-C₁₂ alkyl group which may contain a carbonyl, ester or ether radical, or a C₆-C₁₂ aryl, C₇-C₂₀ aralkyl, or thiophenyl group. Z⁰ is a single bond, methylene, ethylene, phenylene, fluorophenylene, —O—R³²—, or —C(═O)—Z¹—R³²— wherein Z¹ is oxygen or NH, and R³² is a straight, branched or cyclic C₁-C₆ alkylene group, alkenylene or phenylene group, which may contain a carbonyl, ester, ether or hydroxyl radical. M⁻ is a non-nucleophilic counter ion. The subscripts d1, d2 and d3 are in the range of 0≦d1≦0.3, 0≦d2≦0.3, 0≦d3≦0.3, and 0≦d1+d2+d3≦0.3.

In the polymer (A), the recurring units (a), (b), (c), (d1), (d2), and (d3) (assume a=a1+a2+a3) are present in proportions: 0<a≦1.0, 0≦b≦1.0, 0≦c<1.0, 0≦d1≦0.3, 0≦d2≦0.3, 0≦d3≦0.3, and 0≦d1+d2+d3≦0.3; preferably 0<a<1.0, 0≦b<1.0, 0<c<1.0, 0≦d1<0.2, 0≦d2<0.2, and 0≦d3<0.2, and 0≦d1+d2+d3<0.2; and more preferably 0<a≦0.8, 0≦b≦0.8, 0<c≦0.8, 0≦d1<0.15, 0≦d2<0.15, 0≦d3<0.15, and 0≦d1+d2+d3<0.15; provided that a+b+c+d1+d2+d3=1.

It is noted that the meaning of a+b=1, for example, is that in a polymer comprising recurring units (a) and (b), the sum of recurring units (a) and (b) is 100 mol % based on the total amount of entire recurring units. The meaning of a+b<1 is that the sum of recurring units (a) and (b) is less than 100 mol % based on the total amount of entire recurring units, indicating the inclusion of other recurring units, for example, units (c), (d1), (d2) and (d3).

The polymer should preferably have a weight average molecular weight (Mw) in the range of 1,000 to 500,000, and more preferably 2,000 to 30,000, as measured by GPC versus polystyrene standards using tetrahydrofuran solvent. With too low a Mw, a loss of film thickness may occur during organic solvent development. A polymer with too high a Mw may lose solubility in organic solvent and have a likelihood of footing after pattern formation.

If a multi-component polymer has a wide molecular weight distribution or dispersity (Mw/Mn), which indicates the presence of lower and higher molecular weight polymer fractions, there is a possibility that following exposure, foreign matter is left on the pattern or the pattern profile is exacerbated. The influences of molecular weight and dispersity become stronger as the pattern rule becomes finer. Therefore, the multi-component copolymer should preferably have a narrow dispersity (Mw/Mn) of 1.0 to 2.0, especially 1.0 to 1.5, in order to provide a resist composition suitable for micropatterning to a small feature size.

It is acceptable to use a blend of two or more polymers which differ in compositional ratio, molecular weight or dispersity as well as a blend of an inventive polymer and another polymer free of an acid labile group-substituted hydroxyl group.

The polymer (A) may be synthesized by any desired method, for example, by dissolving unsaturated bond-containing monomers corresponding to unit (a), and optionally units (b), (c), (d1), (d2), and/or (d3) in an organic solvent, adding a radical initiator thereto, and effecting heat polymerization. Examples of the organic solvent which can be used for polymerization include toluene, benzene, tetrahydrofuran, diethyl ether and dioxane. Examples of the polymerization initiator used herein include 2,2′-azobisisobutyronitrile (AIBN), 2,2′-azobis(2,4-dimethylvaleronitrile), dimethyl 2,2-azobis(2-methylpropionate), benzoyl peroxide, and lauroyl peroxide. Preferably the system is heated at 50 to 80° C. for polymerization to take place. The reaction time is 2 to 100 hours, preferably 5 to 20 hours. The acid labile group that has been incorporated in the monomer may be kept as such, or the acid labile group may be protected or partially protected after polymerization.

The resist composition of the invention also comprises (B) at least one photoacid generator selected from among an onium salt type photoacid generator capable of generating a sulfonic acid of the general formula (2), an onium salt type photoacid generator capable of generating an imide acid of the general formula (3), and an onium salt type photoacid generator capable of generating a methide acid of the general formula (4), in response to high-energy radiation such as UV, DUV, EUV, EB, x-ray, excimer laser, gamma-ray or synchrotron radiation.

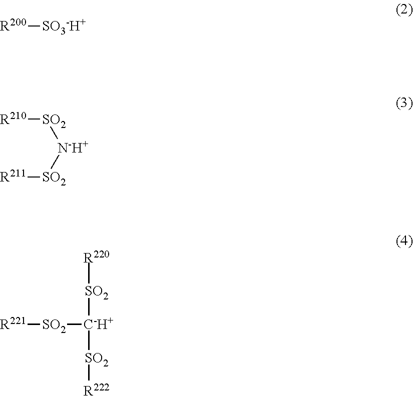

Herein R²⁰⁰ is a C₁-C₂₈ straight, branched or cyclic alkyl group, C₆-C₂₆ aryl group or C₁-C₂₈ aralkyl group, in which a methylene moiety (or moieties) may be substituted by an ether, ester, carbonyl, amide, carbonate or carbamate radical, and in which some or all hydrogen atoms may be substituted by at least one radical selected from among halogen, hydroxyl, carboxyl, amino, cyano, nitro, and sulfonic acid ester. R²¹⁰ and R²¹¹ each are an optionally substituted C₁-C₈ straight or branched fluoroalkyl group, or R²¹⁰ and R²¹¹ may bond together to form a ring, wherein R²¹⁰ and R²¹¹ each are a C₁-C₈ fluoroalkylene group. R²²⁰, R²²¹ and R²²² each are an optionally substituted C₁-C₈ straight or branched fluoroalkyl group, or R²²⁰ and R²²¹ may bond together to form a ring, wherein R²²⁰ and R²²¹ each are a C₁-C₈ fluoroalkylene group.

Examples of the sulfonic acid include perfluoroalkylsulfonic acids such as trifluoromethanesulfonic acid, pentafluoroethanesulfonic acid, nonafluorobutenesulfonic acid, dodecafluorohexanesulfonic acid, and heptadecafluorooctanesulfonic acid, alkylsulfonic acids and aralkylsulfonic acids in which some hydrogen atoms are substituted by fluorine such as 1,1-difluoro-2-naphthylethanesulfonic acid and 1,1,2,2-tetrafluoro-2-(norbornan-2-yl)ethanesulfonic acid.

The preferred onium salt type PAG is a PAG capable of generating a sulfonic acid having the structure of the general formula (8), that is, a sulfonic acid other than perfluoroalkylsulfonic acid.

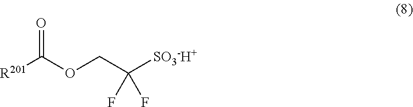

Herein R²⁰¹ is a C₁-C₂₃ straight, branched or cyclic alkyl group, C₆-C₂₃ aryl group or C₇-C₂₃ aralkyl group, in which a methylene moiety (or moieties) may be substituted by an ether, ester or carbonyl radical, and in which some or all hydrogen atoms may be substituted by at least one radical selected from among halogen, hydroxyl, carboxyl, amino, cyano, nitro, and sulfonic acid ester, with the proviso that R²⁰¹ is not perfluoroalkyl.

In ArF chemically amplified resist compositions, PAGs capable of generating perfluoroalkanesulfonic acids are generally used. Among others, perfluorooctanesulfonic acid and homologues thereof are well known by the acronym PFOS. They are considered problematic with respect to their stability (non-degradability) due to C—F bonds, and biological concentration and accumulation due to hydrophobic and lipophilic natures. To overcome these problems of PFOS, partially fluorinated alkanesulfonic acids having a reduced degree of fluorine substitution as represented by formula (8) are effective. Suitable sulfonic acids include 1,1-difluoro-2-naphthylethanesulfonic acid, 1,1,2,2-tetrafluoro-2-(norbornan-2-yl)ethanesulfonic acid, and 1,1,2,2-tetrafluoro-2-(tetracyclo[4.4.0.1^{2,5}.1^{7,10}]dodec-3-en-8-yl)ethanesulfonic acid.

Some PAGs capable of generating partially fluorinated alkanesulfonic acids are known. For instance, Patent Document 9 describes the development of α,α-difluoroalkylsulfonic acid salts from α,α-difluoroalkene and a sulfur compound and discloses a resist composition comprising a PAG capable of generating such sulfonic acid upon exposure, specifically di(4-tert-butylphenyl)iodonium 1,1-difluoro-2-(1-naphthyl)ethanesulfonate. Patent Documents 10 to 12 disclose resist compositions comprising PAGs capable of generating partially fluorinated alkanesulfonic acids.

The preferred onium salt type PAG is a compound capable of generating a sulfonic acid having an ester group represented by the general formula (9) or (10).

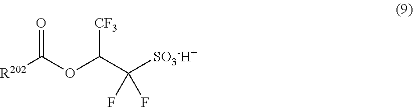

Herein R²⁰² is a C₁-C₂₃ straight, branched or cyclic alkyl group, C₆-C₂₃ aryl group or C₇-C₂₃ aralkyl group, in which a methylene moiety (or moieties) may be substituted by an ether, ester or carbonyl radical, and in which some or all hydrogen atoms may be substituted by at least one radical selected from among halogen, hydroxyl, carboxyl, amino, and cyano, with the proviso that R²⁰² is not perfluoroalkyl.

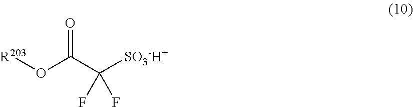

Herein R²⁰³ is an optionally substituted C₁-C₂₀ straight, branched or cyclic alkyl group or optionally substituted C₆-C₁₄ aryl group, with the proviso that R²⁰³ is not perfluoroalkyl.

In formula (9), examples of the alkyl and aryl groups represented by R²⁰² include methyl, ethyl, n-propyl, sec-propyl, cyclopropyl, n-butyl, sec-butyl, isobutyl, tert-butyl, n-pentyl, cyclopentyl, n-hexyl, cyclohexyl, n-octyl, n-decyl, n-dodecyl, 1-adamantyl, 2-adamantyl, bicyclo[2.2.1]hepten-2-yl, phenyl, 4-methoxyphenyl, 4-tert-butylphenyl, 4-biphenyl, 1-naphthyl, 2-naphthyl, 10-anthranyl, and 2-furanyl.

Examples of the substituted alkyl and aryl groups include 2-carboxyethyl, 2-(methoxycarbonyl)ethyl, 2-(cyclohexyloxycarbonyl)ethyl, 2-(1-adamantylmethyloxycarbonyl)ethyl, 2-carboxycyclohexyl, 2-(methoxycarbonyl)cyclohexyl, 2-(cyclohexyloxycarbonyl)cyclohexyl, 2-(1-adamantylmethyloxycarbonyl)cyclohexyl, 4-oxocyclohexyl, 4-oxo-1-adamantyl, 2-carboxyphenyl, and 2-carboxynaphthyl.

Among these groups, tert-butyl, cyclohexyl, 1-adamantyl, phenyl, 4-tert-butylphenyl, 4-methoxyphenyl, 4-biphenyl, 1-naphthyl, and 2-naphthyl are preferred. Inter alia, tert-butyl, cyclohexyl, phenyl, and 4-tert-butylphenyl are most preferred.

Illustrative examples of the sulfonic acid of formula (9) are shown below.

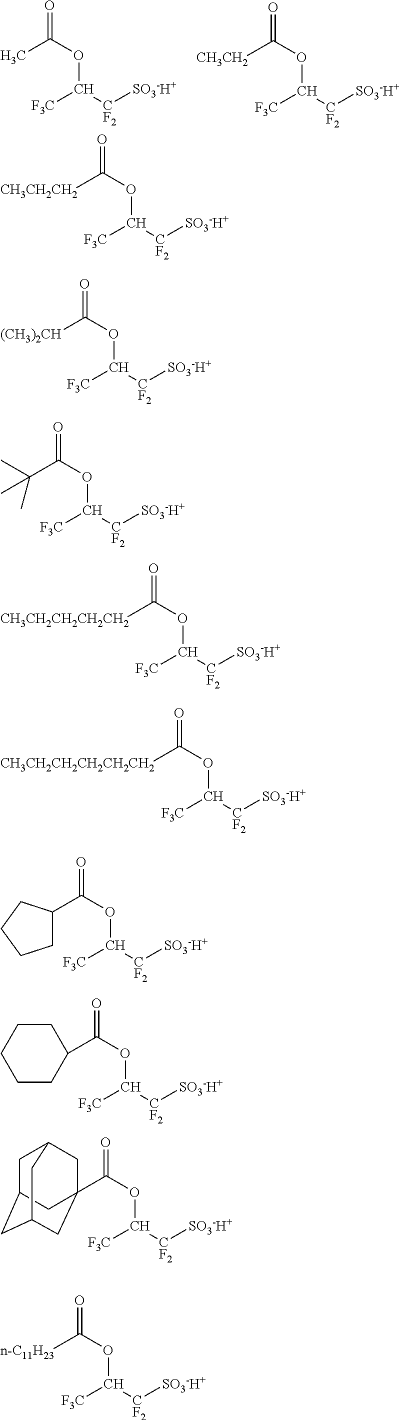

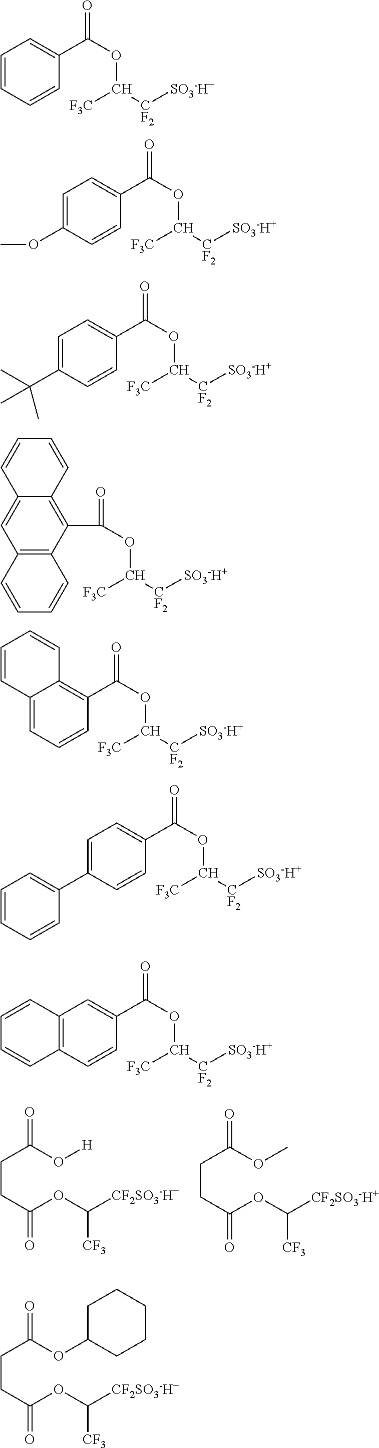

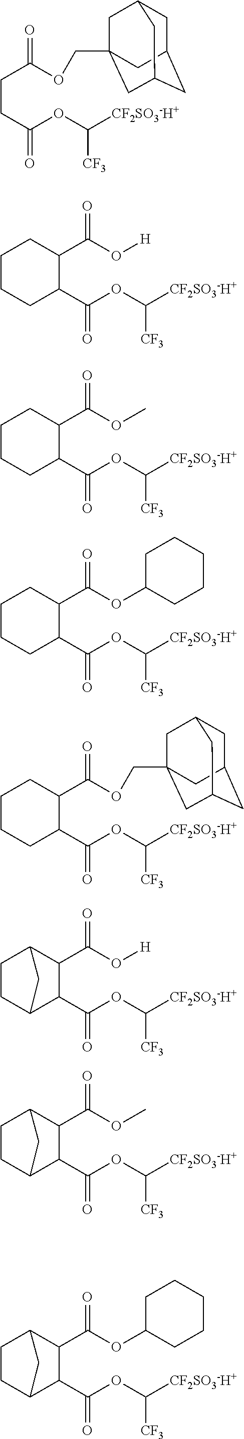

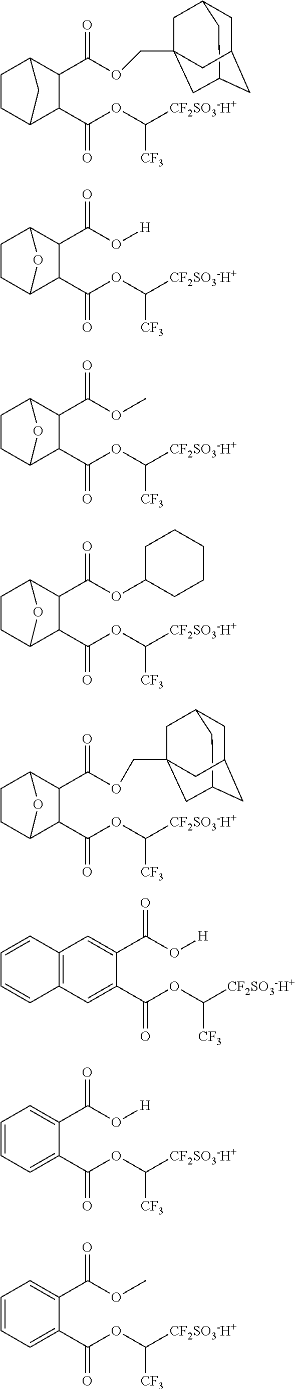

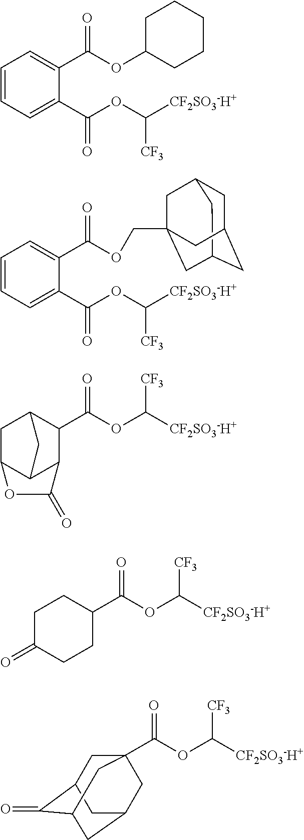

In formula (10), examples of the substituted or unsubstituted, straight, branched or cyclic C₁-C₂₀ alkyl groups represented by R²⁰³ include methyl, ethyl, n-propyl, sec-propyl, cyclopropyl, n-butyl, sec-butyl, isobutyl, tert-butyl, n-pentyl, cyclopentyl, n-hexyl, cyclohexyl, n-octyl, n-decyl, n-dodecyl, 1-adamantyl, 2-adamantyl, 1-adamantylmethyl, 1-(3-hydroxymethyl)adamantylmethyl, 4-oxo-1-adamantyl, 1-(hexahydro-2-oxo-3,5-methano-2H-cyclo-penta[b]furan-6-yl, and 1-(3-hydroxy)adamantylmethyl.

Examples of the substituted or unsubstituted C₆-C₁₄ aryl groups represented by R²⁰³ include phenyl, 4-biphenyl, 1-naphthyl, 2-naphthyl, 10-anthranyl, 2-furanyl, methoxyphenyl, 4-tert-butylphenyl, 2-carboxyphenyl, and 2-carboxynaphthyl.

Illustrative examples of the sulfonic acid of formula (10) are shown below.

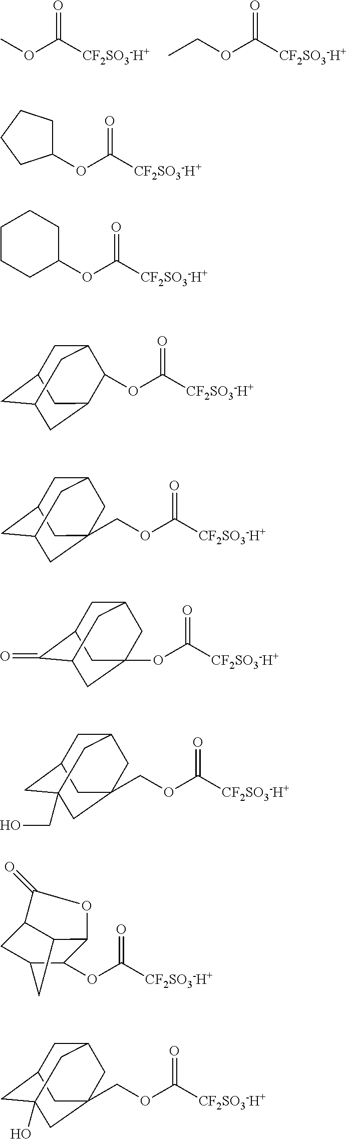

The onium salt type PAG (B) may generate a sulfonic acid which is not fluorinated at α-position of the sulfo group, as represented by the general formula (11) or (12).

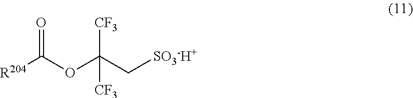

Herein R²⁰⁴ is a C₁-C₂₃ straight, branched or cyclic alkyl group, C₆-C₂₃ aryl group or C₇-C₂₃ aralkyl group, in which a methylene moiety (or moieties) may be substituted by an ether, ester or carbonyl radical, and in which some or all hydrogen atoms may be substituted by at least one radical selected from among halogen, hydroxyl, carboxyl, amino, and cyano, with the proviso that R²⁰⁴ is not perfluoroalkyl.

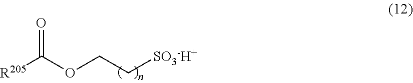

Herein R²⁰⁵ is an optionally substituted C₁-C₂₀ straight, branched or cyclic alkyl group or optionally substituted C₆-C₁₄ aryl group, and n is an integer of 1 to 3, with the proviso that R²⁰⁵ is not perfluoroalkyl.

In formula (11), examples of the substituted or unsubstituted, straight, branched or cyclic C₁-C₂₀ alkyl groups represented by R²⁰⁴ include methyl, ethyl, n-propyl, sec-propyl, cyclopropyl, n-butyl, sec-butyl, isobutyl, tert-butyl, n-pentyl, cyclopentyl, n-hexyl, cyclohexyl, n-octyl, n-decyl, n-dodecyl, 1-adamantyl, 2-adamantyl, 1-adamantylmethyl, 1-(3-hydroxymethyl)adamantylmethyl, 4-oxo-1-adamantyl, 1-(hexahydro-2-oxo-3,5-methano-2H-cyclo-penta[b]furan-6-yl, and 1-(3-hydroxy)adamantylmethyl.

Examples of the substituted or unsubstituted C₆-C₁₄ aryl groups represented by R²⁰⁴ include phenyl, 4-biphenyl, 1-naphthyl, 2-naphthyl, 10-anthranyl, 2-furanyl, methoxyphenyl, 4-tert-butylphenyl, 2-carboxyphenyl, and 2-carboxynaphthyl.

Illustrative examples of the sulfonic acid of formula (11) are shown below.

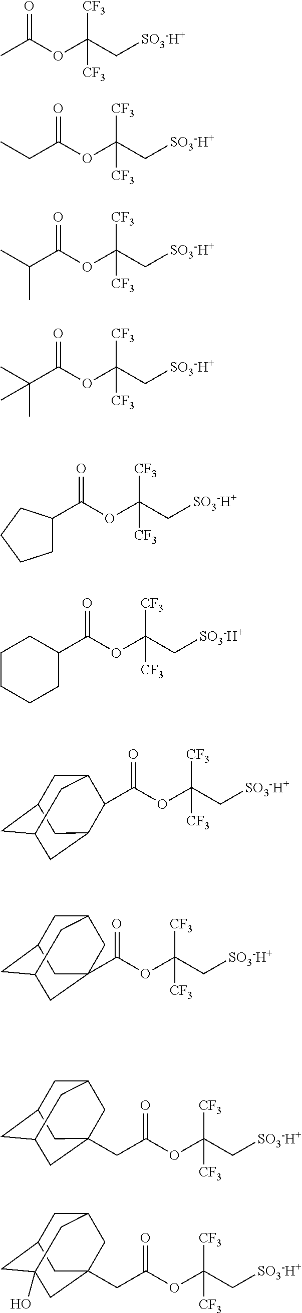

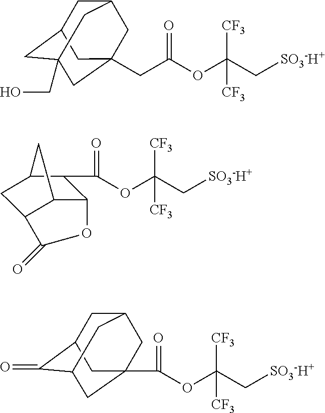

In formula (12), examples of the substituted or unsubstituted, straight, branched or cyclic C₁-C₂₀ alkyl groups represented by R²⁰⁵ include methyl, ethyl, n-propyl, sec-propyl, cyclopropyl, n-butyl, sec-butyl, isobutyl, tert-butyl, n-pentyl, cyclopentyl, n-hexyl, cyclohexyl, n-octyl, n-decyl, n-dodecyl, 1-adamantyl, 2-adamantyl, 1-adamantylmethyl, 1-(3-hydroxymethyl)adamantylmethyl, 4-oxo-1-adamantyl, 1-(hexahydro-2-oxo-3,5-methano-2H-cyclo-penta[b]furan-6-yl, and 1-(3-hydroxy)adamantylmethyl.

Examples of the substituted or unsubstituted C₆-C₁₄ aryl groups represented by R²⁰⁵ include phenyl, 4-biphenyl, 1-naphthyl, 2-naphthyl, 10-anthranyl, 2-furanyl, methoxyphenyl, 4-tert-butylphenyl, 2-carboxyphenyl, and 2-carboxynaphthyl.

Illustrative examples of the sulfonic acid of formula (12) are shown below.

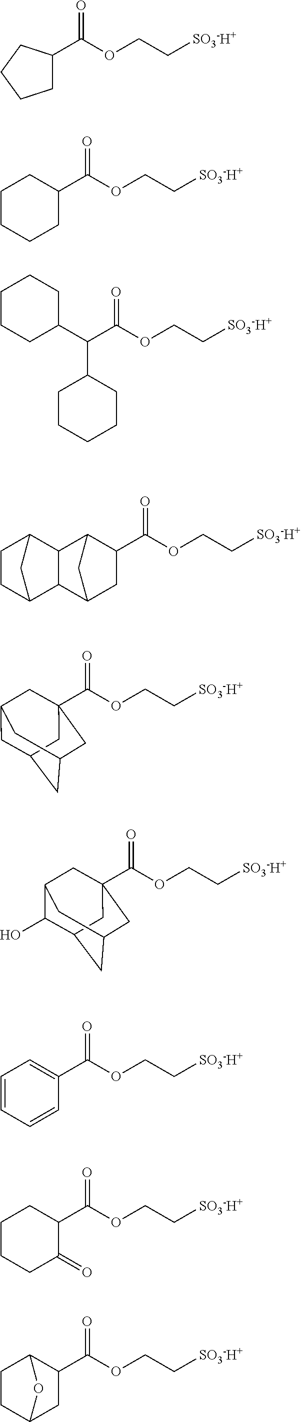

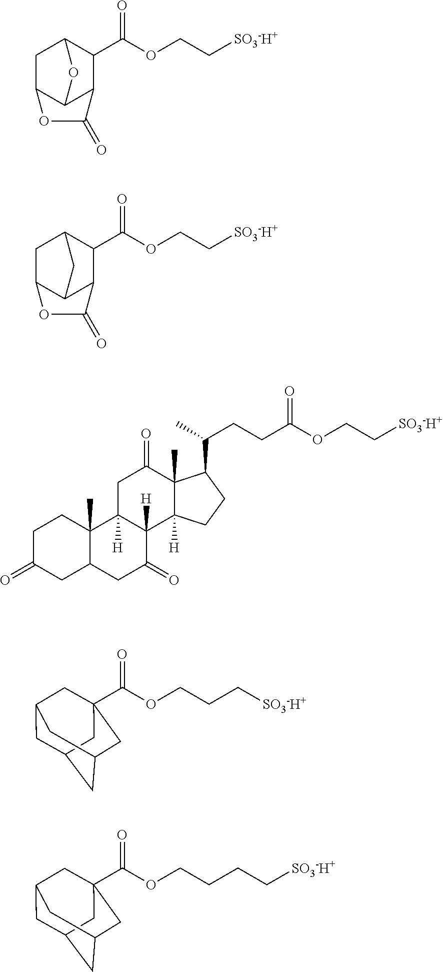

In another embodiment, the PAG (B) is an onium salt type PAG capable of generating an imide acid having the general formula (3).

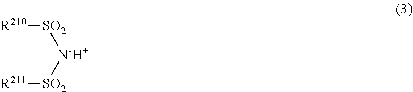

Herein R²¹⁰ and R²¹¹ each are an optionally substituted C₁-C₈ straight or branched fluoroalkyl group, or R²¹⁰ and R²¹¹ may bond together to form a ring, and R²¹⁰ and R²¹¹ each are a C₁-C₈ fluoroalkylene group when they form a ring.

Preferred examples of the imide acid having formula (3) are shown below.

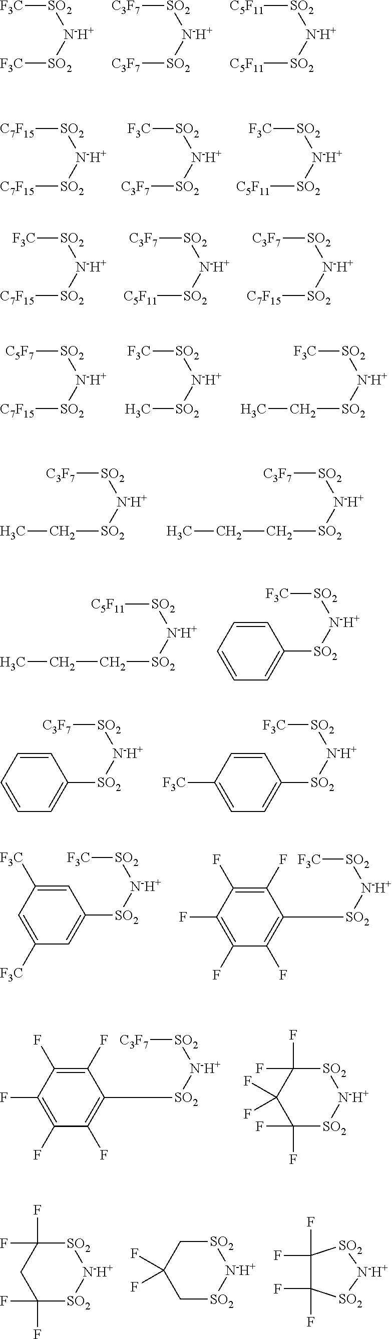

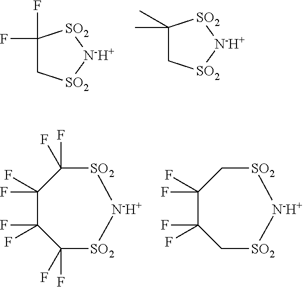

In a further embodiment, the PAG (B) is an onium salt type PAG capable of generating a methide acid having the general formula (4).

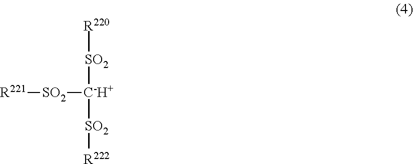

Herein R²²⁰, R²²¹ and R²²² each are an optionally substituted C₁-C₈ straight or branched fluoroalkyl group, or R²²⁰ and R²²¹ may bond together to form a ring, and R²²⁰ and R²²¹ each are a C₁-C₈ fluoroalkylene group when they form a ring.

Preferred examples of the methide acid having formula (4) are shown below.

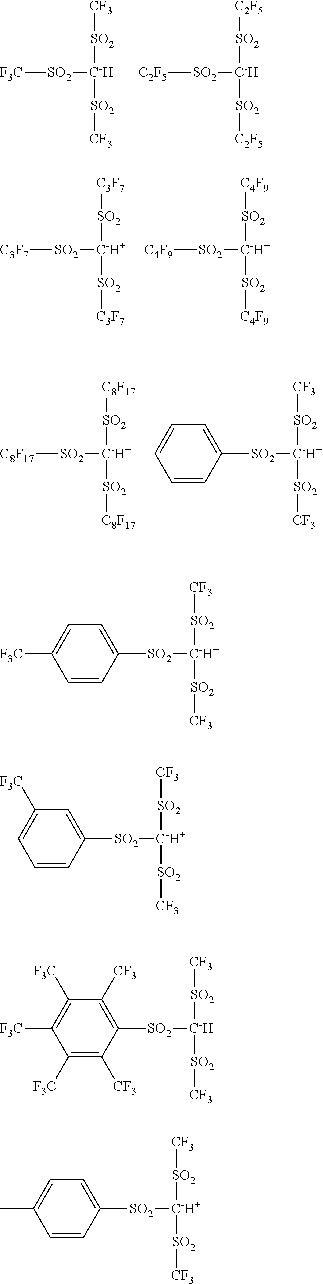

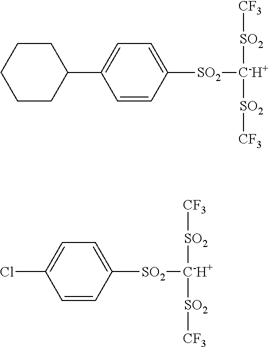

The onium salt PAG (B) capable of generating a sulfonic acid having formula (2) is a sulfonium or iodonium salt. The cation of the sulfonium or iodonium salt is a sulfonium cation having the general formula (6) or an iodonium cation having the general formula (7).

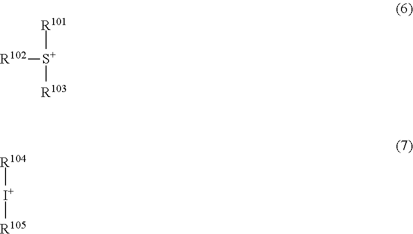

Herein R¹⁰¹, R¹⁰² and R¹⁰³ are each independently a C₁-C₂₀ straight or cyclic alkyl group, C₂-C₂₀ alkenyl group, C₆-C₂₀ aryl group or C₇-C₂₀ aralkyl group, in which a methylene moiety (or moieties) may be substituted by an ether, ester or carbonyl radical, and in which some or all hydrogen atoms may be substituted by at least one radical selected from among halogen, hydroxyl, carboxyl, amino, and cyano. Alternatively, two of R¹⁰¹, R¹⁰² and R¹⁰³ may bond together to form a ring with the sulfur atom, the ring having 4 to 8 carbon atoms, preferably 4 to 6 carbon atoms. R¹⁰⁴ and R¹⁰⁵ are each independently a C₁-C₂₀ straight or cyclic alkyl group, C₂-C₂₀ alkenyl group, C₆-C₂₀ aryl group or C₇-C₂₀ aralkyl group, in which a methylene moiety (or moieties) may be substituted by an ether, ester or carbonyl radical, and in which some or all hydrogen atoms may be substituted by at least one radical selected from among halogen, hydroxyl, carboxyl, amino, and cyano.

Examples of the sulfonium cation having formula (6) include triphenylsulfonium, 4-hydroxyphenyldiphenylsulfonium, 4-tert-butylphenyldiphenylsulfonium, 4-tert-butoxyphenyldiphenylsulfonium, tris(4-tert-butylphenyl)sulfonium, bis(4-hydroxyphenyl)phenylsulfonium, tris(4-hydroxyphenyl)sulfonium, (4-tert-butoxyphenyl)diphenylsulfonium, bis(4-tert-butoxyphenyl)phenylsulfonium, tris(4-tert-butoxyphenyl)sulfonium, (3-tert-butoxyphenyl)diphenylsulfonium, bis(3-tert-butoxyphenyl)phenylsulfonium, tris(3-tert-butoxyphenyl)sulfonium, (3,4-di-tert-butoxyphenyl)diphenylsulfonium, bis(3,4-di-tert-butoxyphenyl)phenylsulfonium, tris(3,4-di-tert-butoxyphenyl)sulfonium, diphenyl(4-thiophenoxyphenyl)sulfonium, (4-tert-butoxycarbonylmethyloxyphenyl)diphenylsulfonium, tris(4-tert-butoxycarbonylmethyloxyphenyl)sulfonium, (4-tert-butoxyphenyl)bis(4-dimethylaminophenyl)sulfonium, tris(4-dimethylaminophenyl)sulfonium, 2-naphthyldiphenylsulfonium, dimethyl-2-naphthylsulfonium, 4-hydroxyphenyldimethylsulfonium, 4-methoxyphenyldimethylsulfonium, trimethylsulfonium, 2-oxocyclohexylcyclohexylmethylsulfonium, trinaphthylsulfonium, tribenzylsulfonium, diphenylmethylsulfonium, dimethylphenylsulfonium, 2-oxo-2-phenylethylthiacyclopentanium, diphenyl-2-thienylsulfonium, 4-n-butoxynaphthyl-1-thiacyclopentanium, 2-n-butoxynaphthyl-1-thiacyclopentanium, 4-methoxynaphthyl-1-thiacyclopentanium, and 2-methoxynaphthyl-1-thiacyclopentanium. Preferred cations are triphenylsulfonium, 4-tert-butylphenyldiphenylsulfonium, 4-tert-butoxyphenyldiphenylsulfonium, tris(4-tert-butylphenyl)sulfonium, and (4-tert-butoxycarbonylmethyloxyphenyl)diphenylsulfonium.

Illustrative examples of the iodonium cation having formula (7) include bis(4-methylphenyl)iodonium, bis(4-ethylphenyl)iodonium, bis(4-tert-butylphenyl)iodonium, bis(4-(1,1-dimethylpropyl)phenyl)iodonium, 4-methoxyphenylphenyliodonium, 4-tert-butoxyphenylphenyliodonium, 4-acryloyloxyphenylphenyliodonium, and 4-methacryloyloxyphenylphenyliodonium, with the bis(4-tert-butylphenyl)iodonium being preferred.

Preferred cation-anion combinations to form an onium salt include combinations of a cation selected from triphenylsulfonium, 4-tert-butylphenyldiphenylsulfonium, 4-tert-butoxyphenyldiphenylsulfonium, tris(4-tert-butylphenyl)sulfonium, and bis(4-tert-butylphenyl)iodonium with an anion selected from 2-adamantanecarbonyloxy-1,1,3,3,3-pentafluoropropanesulfonate, 2-cyclohexanecarbonyloxy-1,1,3,3,3-pentafluoropropanesulfonate, and 2-adamantanecarbonyloxyethanesulfonate.

As exemplary synthesis of the onium salt PAG (B), synthesis of PAG capable of generating a sulfonic acid having formula (8) is described. First, an aliphatic or aromatic carboxylic acid ester of 1,1,3,3,3-pentafluoropropen-2-yl, typically 1,1,3,3,3-pentafluoropropen-2-yl benzoate, which was developed by Nakai et al. (see Tetrahedron Lett., vol. 29, 4119, 1988) using 1,1,1,3,3,3-hexafluoro-2-propanol as the starting reactant, is reacted with sodium hydrogen sulfite or sodium sulfite in a solvent such as water or alcohol or a mixture thereof in the presence of a radical initiator such as azobisisobutyronitrile or benzoyl peroxide, forming a corresponding sulfonic acid salt (see R. B. Wagner et al., Synthetic Organic Chemistry, p. 813-814, John Wiley & Sons, Inc., 1965). The resulting sulfonic acid salt is subjected to hydrolysis with the aid of an alkali such as sodium hydroxide or potassium hydroxide, or solvolysis with the aid of an alcohol and base, and then reacted with an aliphatic carboxylic acid halide, aliphatic carboxylic acid anhydride, aromatic carboxylic acid halide or aromatic carboxylic acid anhydride, yielding a sulfonic acid salt having a carboxylic acid ester structure different from the original carboxylic acid ester structure.

This sulfonic acid salt may be converted to a sulfonium or iodonium salt by a well-known method. The imide sulfonate or oxime sulfonate may be synthesized by converting the sulfonic acid salt to a sulfonyl halide or sulfonic acid anhydride by a well-known method, and reacting it with a corresponding hydroxyimide or oxime.

Since the sulfonic acids having formulae (8), (9), (10), (11) and (12) have an ester moiety within their molecule, it is easy to introduce a variety of groups including less bulky acyl groups to bulky acyl groups, benzoyl, naphthoyl, and anthranyl groups, allowing for a wide span of molecular design. The PAGs capable of generating these sulfonic acids can be advantageously used in the microelectronic device fabrication process including coating, prebake, exposure and development steps. When used in the ArF immersion lithography, the sulfonic acids have advantages including suppressed dissolution in water, less influence of water remaining on the wafer, and few defects.

In the resist composition, the FAG (B) is preferably added in an amount of 0.1 to 20 parts, more preferably 0.1 to 10 parts by weight per 100 parts by weight of the polymer (polymer (A) defined herein and optional polymer) serving as base resin. Too much amount of PAG (B) may give rise to problems like degraded resolution and foreign matter upon development and resist film stripping. With too less amount of PAG (B), deprotection reaction may not take place, resulting in degraded resolution. The PAGs (B) may be used alone or in admixture of two or more. The transmittance of the resist film can be controlled by using a PAG having a low transmittance at the exposure wavelength and adjusting the amount of the PAG added.

In addition to the polymer (A) and the onium salt PAG (B), the resist composition comprises (C) an onium salt type photoacid generator capable of generating a carboxylic acid of the general formula (5).

R³⁰⁰—COO⁻H⁺ (5)

Herein R³⁰⁰ is a C₁-C₂₅ straight, branched or cyclic alkyl group, C₂-C₂, alkenyl group, C₆-C₂₅ aryl group or C₁-C₂₅ aralkyl group, in which a methylene moiety (or moieties) may be substituted by an ether, ester or carbonyl radical, and in which some or all hydrogen atoms may be substituted by at least one radical selected from among halogen, hydroxyl, carboxyl, amino, cyano, nitro, and sulfonic acid ester.

Examples of the anion of the carboxylic acid having formula (5) include anions of formic acid, acetic acid, propionic acid, butyric acid, isobutyric acid, valeric acid, isovaleric acid, pivalic acid, hexanoic acid, octanoic acid, cyclohexylacetic acid, lauric acid, myristic acid, palmitic acid, stearic acid, phenylacetic acid, diphenylacetic acid, phenoxyacetic acid, mandelic acid, benzoylformic acid, cinnamic acid, dihydrocinnamic acid, methylbenzoic acid, anthracenecarboxylic acid, hydroxyacetic acid, lactic acid, methoxyacetic acid, 2-(2-methoxyethoxy)acetic acid, 2-(2-(2-methoxyethoxy)ethoxy)acetic acid, diphenolic acid, monochloroacetic acid, dichloroacetic acid, trichloroacetic acid, trifluoroacetic acid, pentafluoropropionic acid, heptafluorobutyric acid, and cholic acid. Also included are monoanions of dicarboxylic acids such as succinic acid, tartaric acid, glutaric acid, pimelic acid, sebacic acid, phthalic acid, isophthalic acid, terephthalic acid, naphthalenedicarboxylic acid, cyclohexanedicarboxylic acid, and cyclohexenedicarboxylic acid.

Preferred examples of the carboxylic acid anion are shown below, but not limited thereto.

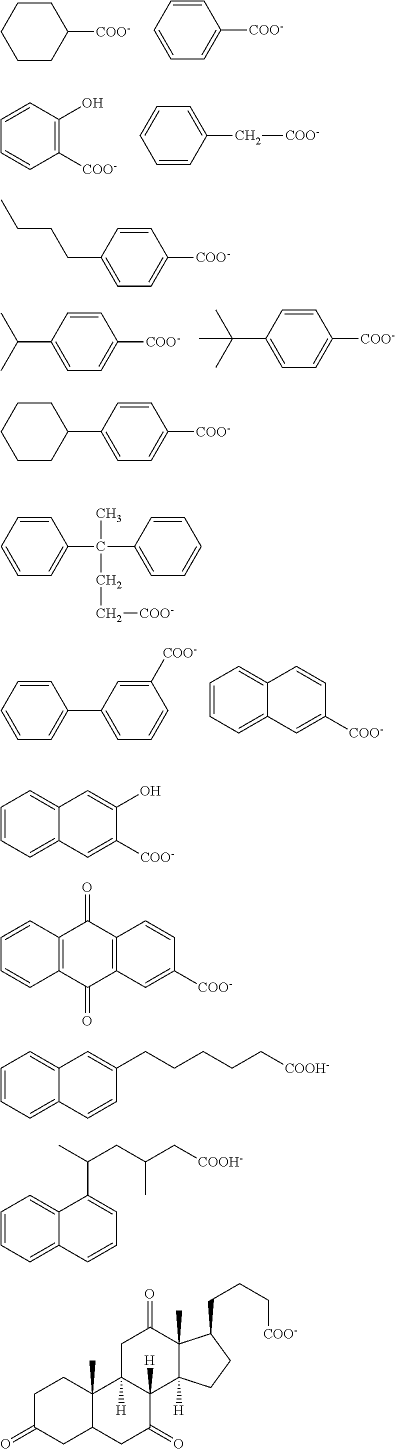

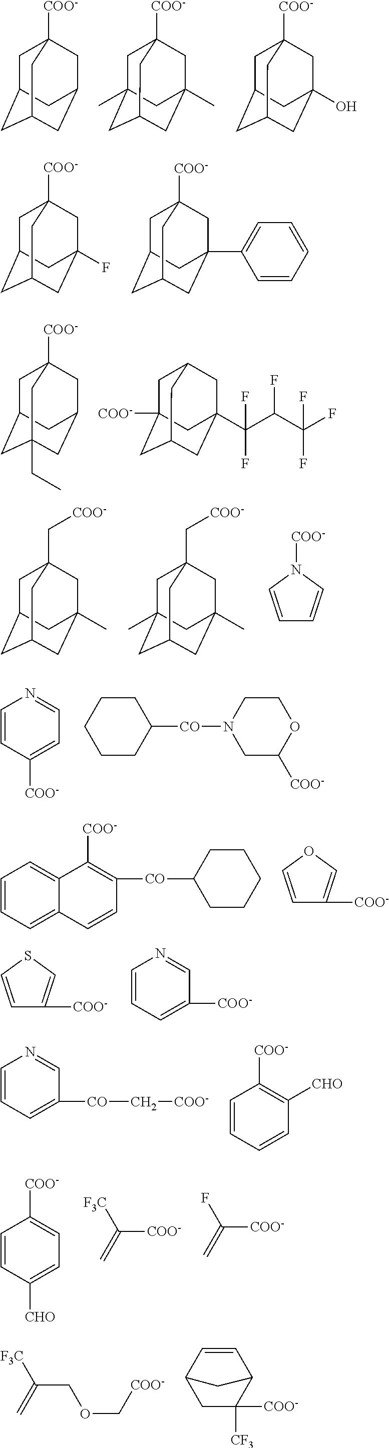

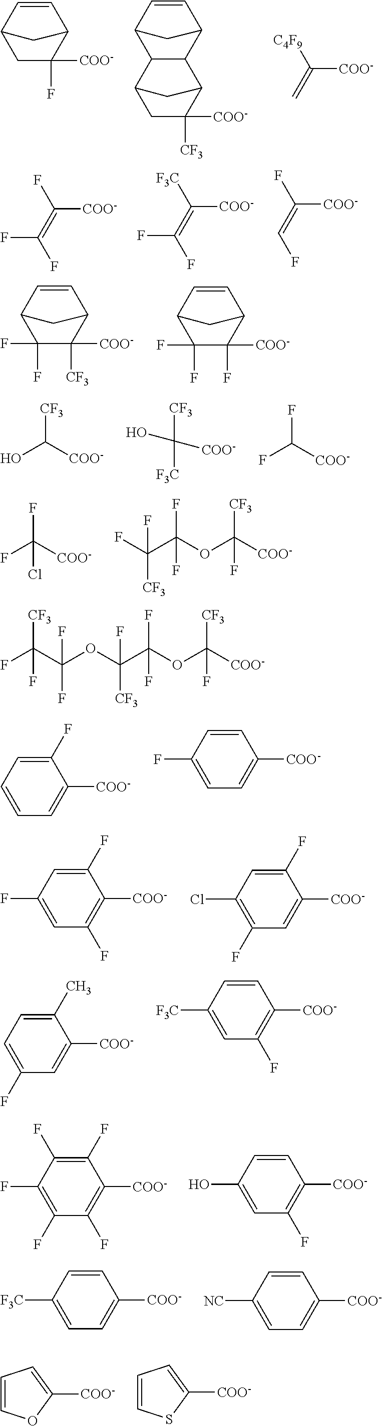

The onium salt PAG (C) is a sulfonium or iodonium salt. The cation of the sulfonium or iodonium salt is a sulfonium cation having the general formula (6) or an iodonium cation having the general formula (7), both defined above. Examples of these cations are as enumerated above.

Preferred cation-anion combinations to form an onium salt include combinations of a cation selected from triphenylsulfonium, 4-tert-butylphenyldiphenylsulfonium, 4-tert-butoxyphenyldiphenylsulfonium, tris(4-tert-butylphenyl)sulfonium, and bis(4-tert-butylphenyl)iodonium with an anion selected from 1-adamantanecarboxylate and 4-tert-butylbenzoate.

The onium salt PAG (C) may be synthesized by the well-known anion exchange method although the synthesis method is not particularly limited. Since a carboxylate is unsusceptible to quantitative anion exchange with a precursor onium chloride or bromide, it is converted into an onium hydroxide via an ion-exchange resin before anion exchange. Alternatively, a silver or lead ion is used to convert a chloride or bromide ion in the system to a silver or lead salt, which is precipitated and removed before synthesis.

When the onium salt PAG (C) is used in combination with the onium salt PAG (B), the sulfonic acid, which is a strong acid, generated by PAG (B) undergoes salt exchange reaction with PAG (C), which is a salt of weak acid. The reaction yields a strong acid salt and a weak acid. Since the weak acid (carboxylic acid) substantially lacks the ability to incur deprotection reaction on the polymer, excessive deprotection reaction inherent to an acetal protective group is eventually restrained. Particularly in combination with the polymer (A) having a hydroxyl group protected with an acetal protective group of the structure defined herein, the use of PAGs (B) and (C) offers an appropriate deprotection-restraining ability, maintains resolution, and achieves an improvement in the dissolution of a minor exposure dose region, that is, surface roughening and side lobe resistance on exposure through a halftone phase shift mask.

In the resist composition, the PAG (C) is preferably added in an amount of 0.1 to 20 parts, more preferably 0.1 to 10 parts by weight per 100 parts by weight of the polymer serving as base resin. Too much amount of PAG (C) may give rise to problems like degraded resolution and foreign matter upon development and resist film stripping. With too less amount of PAG (C), the acid diffusion-controlling ability may be substantially reduced, resulting in degraded resolution. The PAGs (C) may be used alone or in admixture of two or more.

To the resist composition, a compound which is decomposed with an acid to generate another acid, that is, acid amplifier compound may be added. For these compounds, reference should be made to J. Photopolym. Sci. and Tech., 8, 43-44, 45-46 (1995), and ibid., 9, 29-30 (1996).

Examples of the acid amplifier compound include tert-butyl-2-methyl-2-tosyloxymethyl acetoacetate and 2-phenyl-2-(2-tosyloxyethyl)-1,3-dioxolane, but are not limited thereto. Of well-known photoacid generators, many of those compounds having poor stability, especially poor thermal stability exhibit an acid amplifier-like behavior.

In the resist composition, an appropriate amount of the acid amplifier compound is up to 2 parts, and especially up to 1 part by weight per 100 parts by weight of the polymer as base resin. Excessive amounts of the acid amplifier compound make diffusion control difficult, leading to degradation of resolution and pattern profile.

The resist composition defined herein as comprising polymer (A), PAG (B) and PAG (C) may further comprise (D) an organic solvent, and optionally (E) a basic compound and (F) a surfactant. If desired, the composition may further comprise a dissolution regulator, an acetylene alcohol and other components.

Examples of the organic solvent (D) used herein are described in JP-A 2008-111103, paragraphs [0144] to [0145] (U.S. Pat. No. 7,537,880). Specifically, exemplary solvents include ketones such as cyclohexanone and methyl-2-n-amyl ketone; alcohols such as 3-methoxybutanol, 3-methyl-3-methoxybutanol, 1-methoxy-2-propanol, and 1-ethoxy-2-propanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone, and mixtures thereof.

An appropriate amount of the organic solvent used is 100 to 10,000 parts, and especially 300 to 8,000 parts by weight per 100 parts by weight of the polymer as base resin.

Examples of the basic compound (E) used herein include primary, secondary, and tertiary amine compounds as described in JP-A 2008-111103, paragraphs [0146] to [0164], specifically amine compounds having a hydroxyl, ether, ester, lactone, cyano or sulfonic ester group, and compounds having a carbamate group as described in JP 3790649. An appropriate amount of the basic compound used is 0.0001 to 30 parts, and especially 0.001 to 20 parts by weight per 100 parts by weight of the polymer as base resin.

The surfactant (F) used herein may be typically selected from those described in JP-A 2008-111103, paragraphs to [0166]. Exemplary dissolution regulators are described in JP-A 2008-122932, paragraphs [0155] to [0178], and exemplary acetylene alcohols in paragraphs [0179] to [0182]. These components may be added in any desired amounts as long as the benefits of the invention are not impaired.

Also a polymeric additive may be added for improving the water repellency on surface of a resist film as spin coated. This additive may be used in the topcoatless immersion lithography. These additives include polymers of specific structure having a 1,1,1,3,3,3-hexafluoro-2-propanol residue and are described in JP-A 2007-297590, 2008-111103, 2008-122932, 2009-98638, and 2009-276363. The water repellency improver to be added to the resist composition should be soluble in the organic solvent as the developer. The water repellency improver of specific structure with a 1,1,1,3,3,3-hexafluoro-2-propanol residue is well soluble in the developer. A polymer having an amino group or amine salt copolymerized as recurring units may serve as the water repellent additive and is effective for preventing evaporation of acid during PEB and avoiding any hole pattern opening failure after development. The resist composition which can be used herein may comprise a water-repellent polymer having an amino group copolymerized as described in JP-A 2009-31767, a polymer having a sulfonic acid amine salt copolymerized as described in JP-A 2008-107443, and a polymer having carboxylic acid amine salt copolymerized as described in JP-A 2008-239918. An appropriate amount of the water repellency improver, if added, is 0.1 to 20 parts, preferably 0.5 to 10 parts by weight per 100 parts by weight of the polymer as base resin.

### Process

Pattern formation using the resist composition of the invention may be performed by well-known lithography processes. The process generally involves coating, prebaking, exposure, PEB, and development. If necessary, any additional steps may be added.

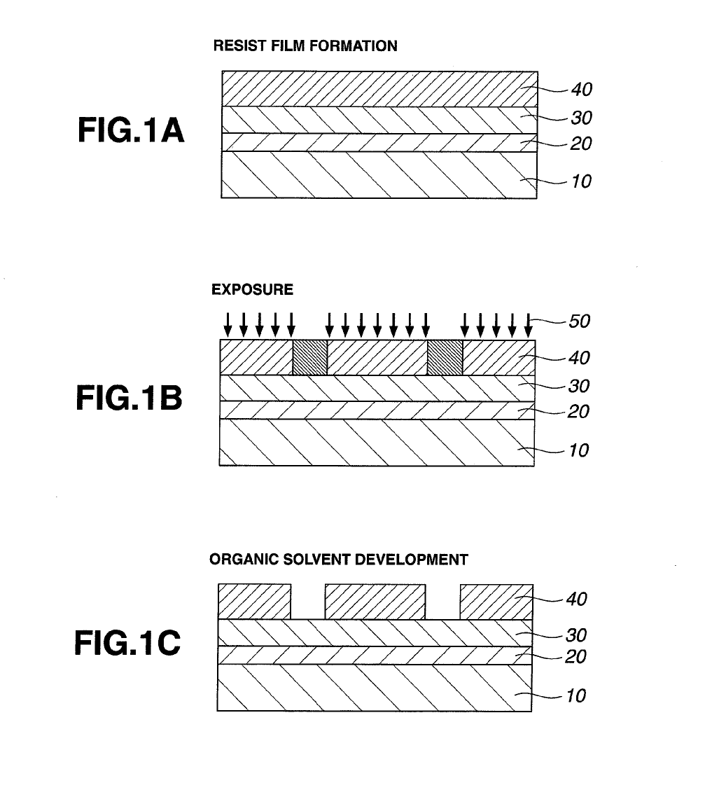

Now referring to the drawings, the pattern forming process of the invention is illustrated in FIG. 1. First, the resist composition is coated on a substrate to form a resist film thereon. Specifically, a resist film 40 of a resist composition is formed on a processable layer 20 disposed on a substrate 10 directly or via an intermediate intervening layer 30 as shown in FIG. 1A. The resist film preferably has a thickness of 10 to 1,000 nm and more preferably 20 to 500 nm. Prior to exposure, the resist film is heated or prebaked, preferably at a temperature of 60 to 180° C., especially 70 to 150° C. for a time of 10 to 300 seconds, especially 15 to 200 seconds.

The substrate 10 used herein is generally a silicon substrate. The processable layer (or target film) 20 used herein includes SiO₂, SiN, SiON, SiOC, p-Si, α-Si, TiN, WSi, BPSG, SOG, Cr, CrO, CrON, MoSi, low dielectric film, and etch stopper film. The intermediate intervening layer 30 includes hard masks of SiO₂, SiN, SiON or p-Si, an undercoat in the form of carbon film, a silicon-containing intermediate film, and an organic antireflective coating.

Next comes exposure depicted at 50 in FIG. 1B. For the exposure, preference is given to high-energy radiation having a wavelength of 140 to 250 nm and EUV having a wavelength of 13.5 nm, and especially ArF excimer laser radiation of 193 nm. The exposure may be done either in a dry atmosphere such as air or nitrogen stream or by immersion lithography in water. The ArF immersion lithography uses deionized water or liquids having a refractive index of at least 1 and highly transparent to the exposure wavelength such as alkanes as the immersion solvent. The immersion lithography involves exposing the prebaked resist film to light through a projection lens, with water introduced between the resist film and the projection lens. Since this allows lenses to be designed to a NA of 1.0 or higher, formation of finer feature size patterns is possible. The immersion lithography is important for the ArF lithography to survive to the 45-nm node. In the case of immersion lithography, deionized water rinsing (or post-soaking) may be carried out after exposure for removing water droplets left on the resist film, or a protective film may be applied onto the resist film after pre-baking for preventing any leach-out from the resist film and improving water slip on the film surface.

The other embodiment of the invention is a process for forming a pattern by applying the resist composition defined herein onto a substrate, baking the composition to form a resist film, forming a protective film on the resist film, exposing the resist film to high-energy radiation to define exposed and unexposed regions, baking, and applying an organic solvent-based developer to the coated substrate to form a negative pattern wherein the unexposed region of resist film and the protective film are dissolved and the exposed region of resist film is not dissolved.

The resist protective film used in the immersion lithography is preferably formed from a solution of a polymer comprising recurring units having a 1,1,1,3,3,3-hexafluoro-2-propanol residue which is insoluble in water, but soluble in an alkaline developer, in a solvent selected from alcohols of at least 4 carbon atoms, ethers of 8 to 12 carbon atoms, and mixtures thereof. While the protective film must dissolve in organic solvent developers, the polymer comprising recurring units having a 1,1,1,3,3,3-hexafluoro-2-propanol residue dissolves in organic solvent developers. In particular, protective film-forming materials having 1,1,1,3,3,3-hexafluoro-2-propanol residues as described in JP-A 2007-025634, 2008-003569, 2008-81716, and 2008R-111089 readily dissolve in organic solvent developers.

In the protective film-forming composition, an amine compound or amine salt may be added, or a polymer comprising recurring units having a 1,1,1,3,3,3-hexafluoro-2-propanol residue and having copolymerized therein recurring units containing an amine group or amine salt may be used as base resin. This component is effective for controlling diffusion of the acid generated in the exposed region of the resist film to the unexposed region for thereby preventing any hole opening failure. Useful protective film materials having an amine compound added thereto are described in JP-A 2008-003569, and useful protective film materials having an amino group or amine salt copolymerized are described in JP-A 2007-316448. The amine compound or amine salt may be selected from the compounds enumerated as the basic compound to be added to the resist composition. An appropriate amount of the amine compound or amine salt added is 0.01 to 10 parts, preferably 0.02 to 8 parts by weight per 100 parts by weight of the base polymer.

After formation of the resist film, deionized water rinsing (or post-soaking) may be carried out for extracting the acid generator and the like from the film surface or washing away particles, or after exposure, rinsing (or post-soaking) may be carried out for removing water droplets left on the resist film. If the acid evaporating from the exposed region during PEB deposits on the unexposed region to deprotect the protective group on the surface of the unexposed region, there is a possibility that the surface edges of holes after development are bridged to close the holes. Particularly in the case of negative development, regions surrounding the holes receive light so that acid is generated therein. There is a possibility that the holes are not opened if the acid outside the holes evaporates and deposits inside the holes during PEB. Provision of a protective film is effective for preventing evaporation of acid and for avoiding any hole opening failure. A protective film having an amine compound or amine salt added thereto is more effective for preventing acid evaporation. On the other hand, a protective film of a composition to which an acid compound containing a carboxyl or sulfo group is added or which is based on a polymer having copolymerized therein monomeric units containing a carboxyl or sulfo group is undesirable because of a potential hole opening failure.

The protective film is preferably formed from a composition comprising a polymer comprising recurring units having a 1,1,1,3,3,3-hexafluoro-2-propanol residue and an amine compound or amine salt, or a composition comprising a polymer comprising recurring units having a 1,1,1,3,3,3-hexafluoro-2-propanol residue and having amino group or amine salt-containing recurring units copolymerized, the composition further comprising an alcohol solvent of at least 4 carbon atoms, an ether solvent of 8 to 12 carbon atoms, or a mixture thereof.

Suitable alcohols of at least 4 carbon atoms include 1-butyl alcohol, 2-butyl alcohol, isobutyl alcohol, tert-butyl alcohol, 1-pentanol, 2-pentanol, 3-pentanol, tert-amyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol. Suitable ether solvents of 8 to 12 carbon atoms include di-n-butyl ether, diisobutyl ether, di-sec-butyl ether, di-n-pentyl ether, diisopentyl ether, di-sec-pentyl ether, di-tert-amyl ether, and di-n-hexyl ether.

Exposure is preferably performed in an exposure dose of about 1 to 200 mJ/cm², more preferably about 10 to 100 mJ/cm². This is followed by baking (PEB) on a hot plate at 60 to 150° C. for 1 to 5 minutes, preferably at 80 to 120° C. for 1 to 3 minutes.

Thereafter the exposed resist film is developed in an organic solvent-based developer for 0.1 to 3 minutes, preferably 0.5 to 2 minutes by any conventional techniques such as dip, puddle and spray techniques. In this way, the unexposed region of resist film is dissolved away, leaving a negative resist pattern 40 on the substrate 10 as shown in FIG. 1C.

The developer used herein is preferably selected from among ketones such as 2-octanone, 2-nonanone, 2-heptanone, 3-heptanone, 4-heptanone, 2-hexanone, 3-hexanone, diisobutyl ketone, 2-methylcyclohexanone, 3-methylcyclohexanone, 4-methylcyclohexanone, acetophenone, 2′-methylacetophenone, 4′-methylacetophenone, and esters such as propyl acetate, butyl acetate, isobutyl acetate, amyl acetate, butenyl acetate, isoamyl acetate, phenyl acetate, propyl formate, butyl formate, isobutyl formate, amyl formate, isoamyl formate, methyl valerate, methyl pentenoate, methyl crotonate, ethyl crotonate, methyl lactate, ethyl lactate, propyl lactate, butyl lactate, isobutyl lactate, amyl lactate, isoamyl lactate, methyl 2-hydroxyisobutyrate, ethyl 2-hydroxyisobutyrate, methyl benzoate, ethyl benzoate, benzyl acetate, methyl phenylacetate, benzyl formate, phenylethyl formate, methyl 3-phenylpropionate, benzyl propionate, ethyl phenylacetate, and 2-phenylethyl acetate, and mixtures thereof.

At the end of development, the resist film is rinsed. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents. Specifically, suitable alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Suitable alkenes of 6 to 12 carbon atoms include hexene, heptene, octene, cyclohexene, methylcyclohexene, dimethylcyclohexene, cycloheptane, and cyclooctene. Suitable alkynes of 6 to 12 carbon atoms include hexyne, heptyne, and octyne. Suitable alcohols of 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-amyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol. Suitable ether compounds of 8 to 12 carbon atoms include di-n-butyl ether, diisobutyl ether, di-sec-butyl ether, di-n-pentyl ether, diisopentyl ether, di-sec-pentyl ether, di-tert-amyl ether, and di-n-hexyl ether. Suitable aromatic solvents include toluene, xylene, ethylbenzene, isopropylbenzene, tert-butylbenzene, and mesitylene. The solvents may be used alone or in admixture.

Where a hole pattern is formed by negative tone development, exposure by double dipole illuminations of X- and Y-direction line patterns provides the highest contrast light. The contrast may be further increased by combining dipole illumination with s-polarized illumination.

In a preferred embodiment, a halftone phase shift mask bearing a lattice-like shifter pattern is used, whereby a pattern of holes is formed at the intersections between gratings of the lattice-like shifter pattern after development. More preferably the halftone phase shift mask bearing a lattice-like shifter pattern has a transmittance of 3% to 15%.

In a more preferred embodiment, a phase shift mask including a lattice-like first shifter having a line width equal to or less than a half pitch and a second shifter arrayed on the first shifter and consisting of lines whose on-wafer size is 2 to 30 nm thicker than the line width of the first shifter is used, whereby a pattern of holes is formed only where the thick shifter is arrayed. Alternatively, a phase shift mask including a lattice-like first shifter having a line width equal to or less than a half pitch and a second shifter arrayed on the first shifter and consisting of dots whose on-wafer size is 2 to 100 nm thicker than the line width of the first shifter is used, whereby a pattern of holes is formed only where the thick shifter is arrayed.

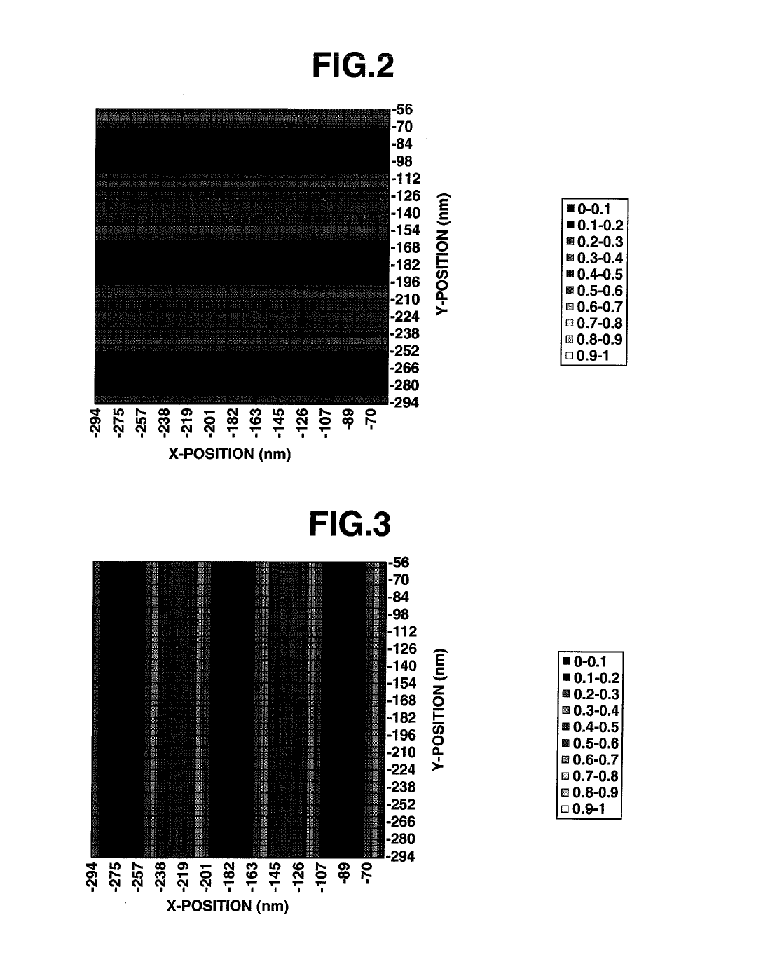

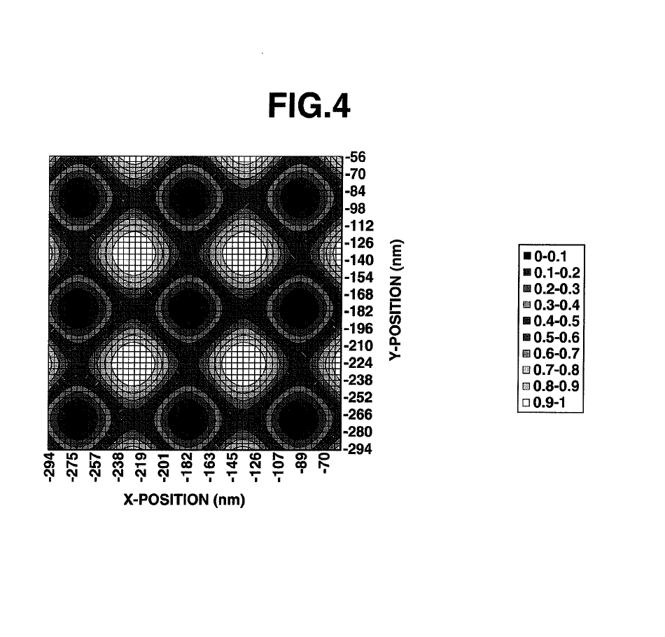

FIG. 2 is an optical image of X-direction lines having a pitch of 90 nm and a line size of 45 nm printed under conditions: ArF excimer laser of wavelength 193 nm, NA 1.3 lens, dipole illumination, 6% halftone phase shift mask, and s-polarization. FIG. 3 is an optical image of Y-direction lines having a pitch of 90 nm and a line size of 45 nm printed under conditions: ArF excimer laser of wavelength 193 nm, NA 1.3 lens, dipole illumination, 6% halftone phase shift mask, and s-polarization. A black area is a light shielded area while a white area is a high light intensity area. A definite contrast difference is recognized between white and black, indicating the presence of a fully light shielded area. FIG. 4 shows a contrast image obtained by overlaying the optical image of X-direction lines in FIG. 2 with that of Y-direction lines in FIG. 3. Against the expectation that a combination of X and Y lines may form a lattice-like image, weak light black areas draw circular shapes. As the pattern (circle) size becomes larger, the circular shape changes to a rhombic shape to merge with adjacent ones. As the circle size becomes smaller, circularity is improved, which is evidenced by the presence of a fully light shielded small circle.

Exposure by double dipole illuminations of X- and Y-direction lines combined with polarized illumination presents a method of forming light of the highest contrast. This method, however, has the drawback that the throughput is substantially reduced by double exposures and mask exchange therebetween. It is then proposed in Non-Patent Document 1 to carry out two exposures by dipole illuminations in X and Y directions using a mask having a lattice-like pattern. The throughput is somewhat improved with this method that dispenses with a mask exchange and involves only two consecutive exposures. However, there remain problems that two exposures using an expensive immersion scanner lead to a reduction of throughput and a cost increase, and the position of holes is shifted from the desired position due to a misalignment between two exposures.

The method of combining X and Y polarized illuminations with cross-pole illumination using a mask having a lattice-like pattern can form a hole pattern through a single exposure. The method is estimated to attain a substantial improvement in throughput and avoids the problem of misalignment between two exposures. Using such a mask and illumination, a hole pattern of the order of 40 nm can be formed at a practically acceptable cost.

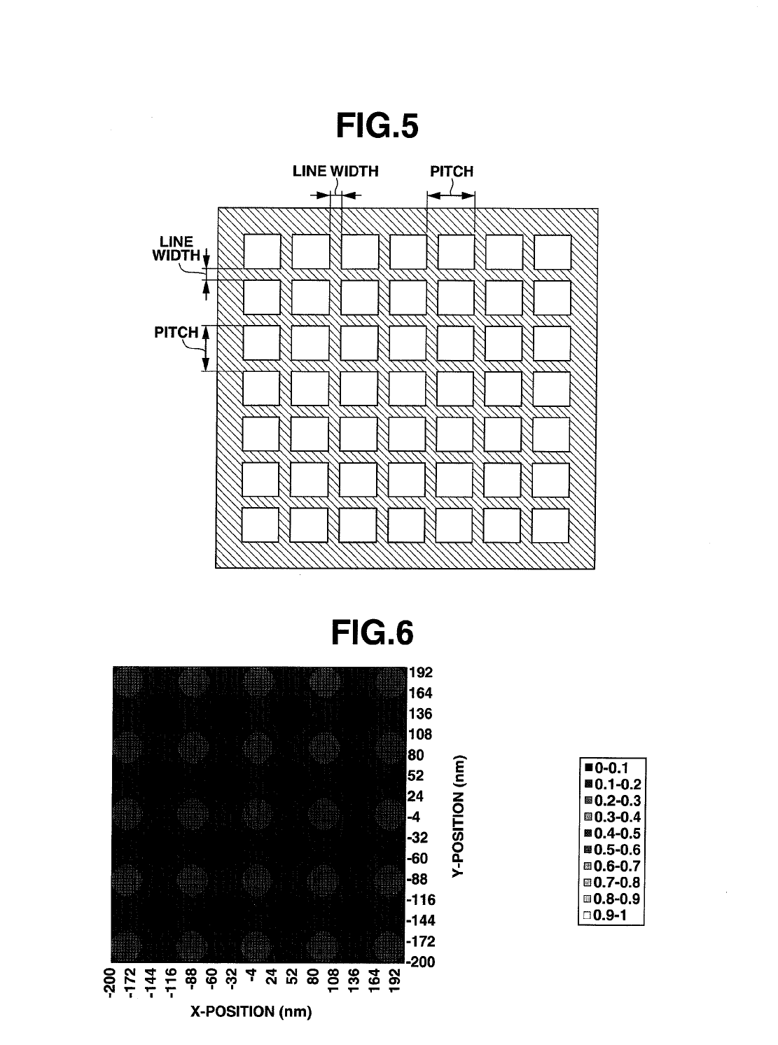

On use of a mask bearing a lattice-like pattern as shown in FIG. 5 where light is fully shielded at intersections between gratings, black spots having a very high degree of light shielding appear as shown in FIG. 6. FIG. 6 is an optical image of a lattice-like line pattern having a pitch of 90 nm and a line width of 30 nm printed under conditions: NA 1.3 lens, cross-pole illumination, 6% halftone phase shift mask, and azimuthally polarized illumination. A fine hole pattern may be formed by performing exposure through a mask bearing such a pattern and organic solvent development entailing positive/negative reversal.

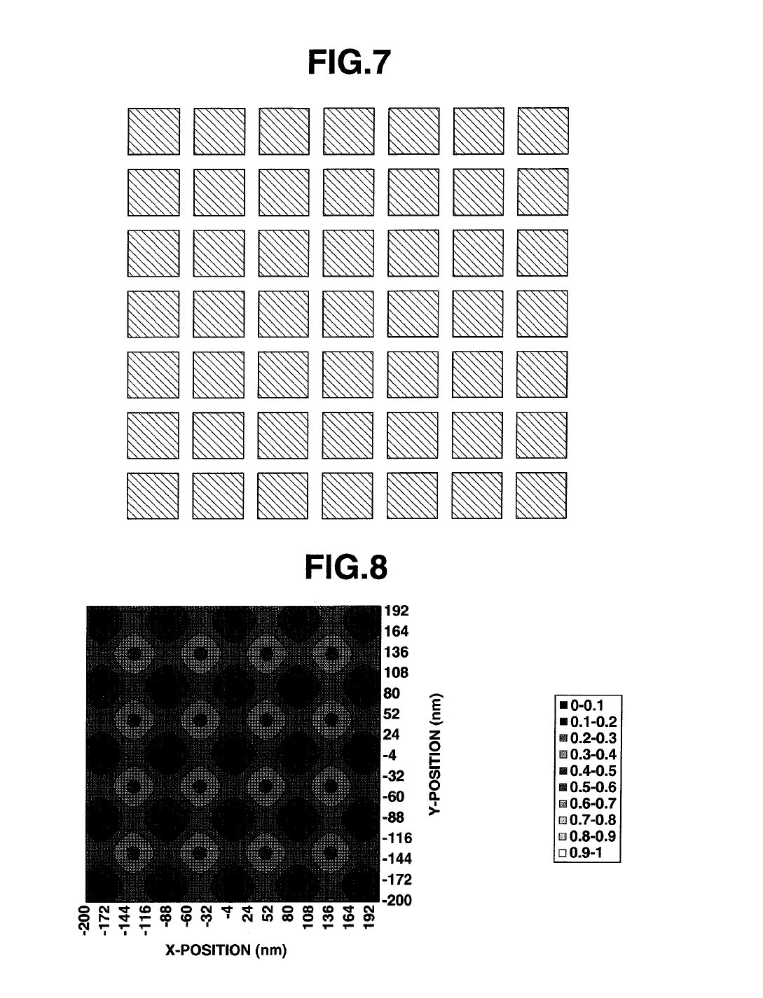

On use of a mask bearing a dot pattern of square dots having a pitch of 90 nm and a side width of 60 nm as shown in FIG. 7, under conditions: NA 1.3 lens, cross-pole illumination, 6% halftone phase shift mask, and azimuthally polarized illumination, an optical image is obtained as shown in FIG. 8 that depicts the contrast thereof. The circle of fully light shielded spot in FIG. 8 has a smaller area than in FIG. 6, which indicates a low contrast as compared with the lattice-like pattern mask.

It is difficult to form a fine hole pattern that holes are randomly arrayed at varying pitch and position. The super-resolution technology using off-axis illumination (such as dipole or cross-pole illumination) in combination with a phase shift mask and polarization is successful in improving the contrast of dense (or grouped) patterns, but not so the contrast of isolated patterns.

When the super-resolution technology is applied to repeating dense patterns, the pattern density bias between dense and isolated patterns, known as proximity bias, becomes a problem. As the super-resolution technology used becomes stronger, the resolution of a dense pattern is more improved, but the resolution of an isolated pattern remains unchanged. Then the proximity bias is exaggerated. In particular, an increase of proximity bias in a hole pattern resulting from further miniaturization poses a serious problem. One common approach taken to suppress the proximity bias is by biasing the size of a mask pattern. Since the proximity bias varies with properties of a photoresist composition, specifically dissolution contrast and acid diffusion, the proximity bias of a mask varies with the type of photoresist composition. For a particular type of photoresist composition, a mask having a different proximity bias must be used. This adds to the burden of mask manufacturing. Then the pack and unpack (PAU) method is proposed in Proc. SPIE Vol. 5753, p 171 (2005), which involves strong super-resolution illumination of a first positive resist to resolve a dense hole pattern, coating the first positive resist pattern with a negative resist film material in alcohol solvent which does not dissolve the first positive resist pattern, exposure and development of an unnecessary hole portion to close the corresponding holes, thereby forming both a dense pattern and an isolated pattern. One problem of the PAU method is misalignment between first and second exposures, as the authors point out in the report. The hole pattern which is not closed by the second development experiences two developments and thus undergoes a size change, which is another problem.

To form a random pitch hole pattern by organic solvent development entailing positive/negative reversal, a mask is used in which a lattice-like pattern is arrayed over the entire surface and the width of gratings is thickened only where holes are to be formed.

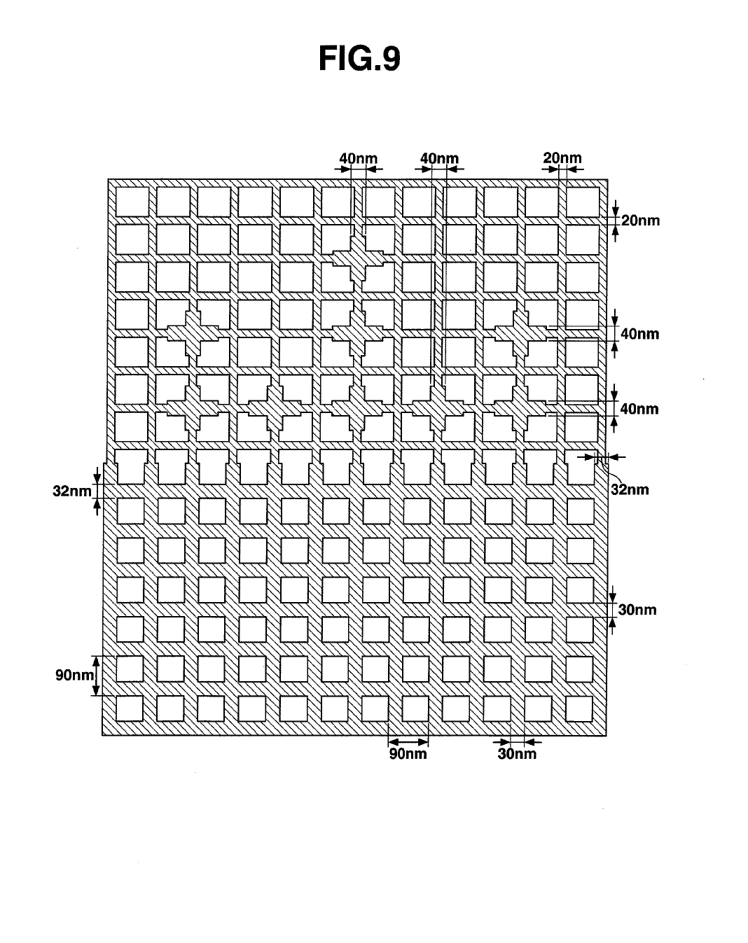

As shown in FIG. 9, on a lattice-like pattern having a pitch of 90 nm and a line width of 20 nm, thick crisscross or intersecting line segments are disposed where dots are to be formed. A black area corresponds to the halftone shifter portion. Line segments with a width of 30 nm are disposed in the dense pattern portion whereas thicker line segments (width 40 nm in FIG. 9) are disposed in more isolated pattern portions. Since the isolated pattern provides light with a lower intensity than the dense pattern, thicker line segments are used. Since the peripheral area of the dense pattern provides light with a relatively low intensity, line segments having a width of 32 nm are assigned to the peripheral area which width is slightly greater than that in the internal area of the dense pattern.

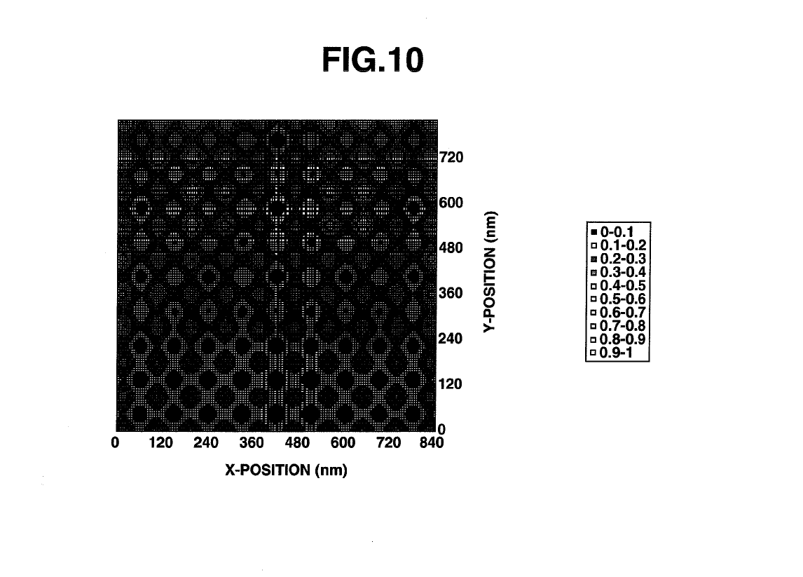

FIG. 10 shows an optical image from the mask of FIG. 9, indicating the contrast thereof. Black or light shielded areas are where holes are formed via positive/negative reversal. Black spots are found at positions other than where holes are formed, but few are transferred in practice because they are of small size. Optimization such as reduction of the width of grating lines corresponding to unnecessary holes can inhibit transfer of unnecessary holes.

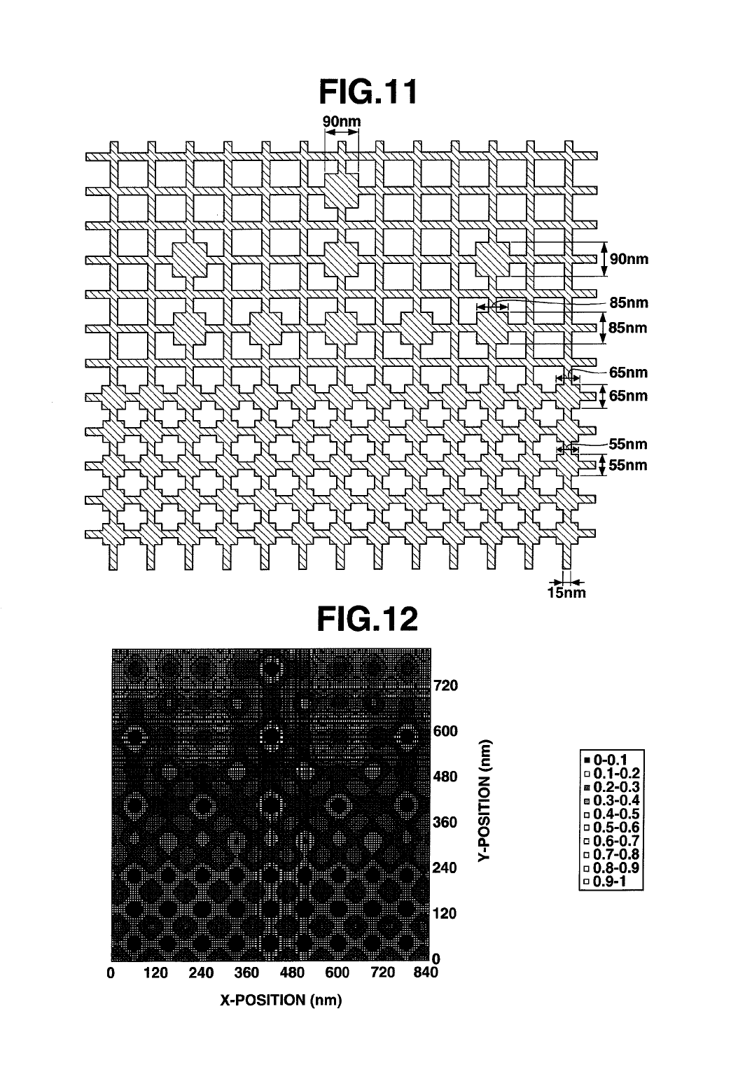

Also useful is a mask in which a lattice-like pattern is arrayed over the entire surface and thick dots are disposed only where holes are to be formed. As shown in FIG. 11, on a lattice-like pattern having a pitch of 90 nm and a line width of 15 nm, thick dots are disposed where dots are to be formed. A black area corresponds to the halftone shifter portion. Square dots having one side with a size of 55 nm are disposed in the dense pattern portion whereas larger square dots (side size 90 nm in FIG. 11) are disposed in more isolated pattern portions. Although square dots are shown in the figure, the dots may have any shape including rectangular, rhombic, pentagonal, hexagonal, heptagonal, octagonal, and polygonal shapes and even circular shape.

FIG. 12 shows an optical image from the mask of FIG. 11, indicating the contrast thereof. The presence of black or light shielded spots substantially equivalent to those of FIG. 10 indicates that holes are formed via positive/negative reversal.

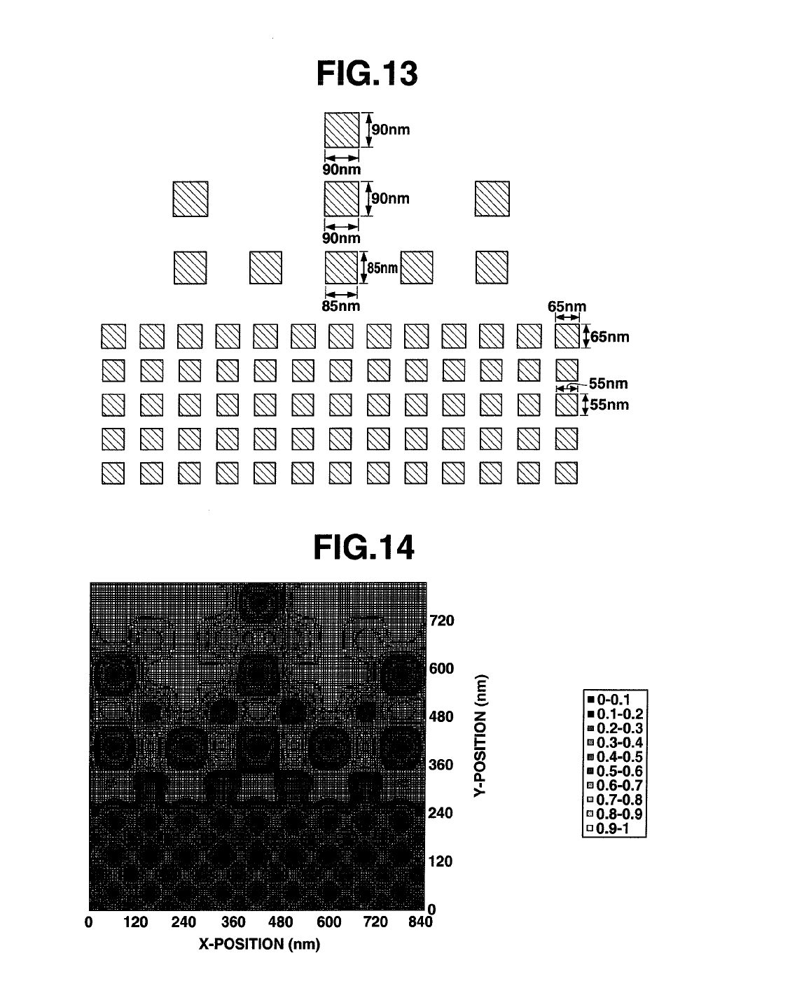

On use of a mask bearing no lattice-like pattern arrayed as shown in FIG. 13, black or light shielded spots do not appear as shown in FIG. 14. In this case, holes are difficult to form, or even if holes are formed, a variation of mask size is largely reflected by a variation of hole size because the optical image has a low contrast.

### EXAMPLE

Examples of the invention are given below by way of illustration and not by way of limitation. The abbreviation “pbw” is parts by weight. Me stands for methyl.

For all polymers, Mw and Mn are determined by GPC versus polystyrene standards using tetrahydrofuran solvent. For pattern profile observation, a top-down scanning electron microscope (TDSEM) S-9380 (Hitachi High Technologies Corp.) was used.

### Synthesis Example

Various polymers (Polymers 1 to 16 and Comparative Polymers 1 and 2) for use in resist compositions were prepared by combining suitable monomers, effecting copolymerization reaction in tetrahydrofuran solvent, pouring into methanol for crystallization, repeatedly washing with hexane, isolation, and drying. The polymers were analyzed by ¹H-NMR to determine their composition and by GPC to determine Mw and dispersity Mw/Mn.

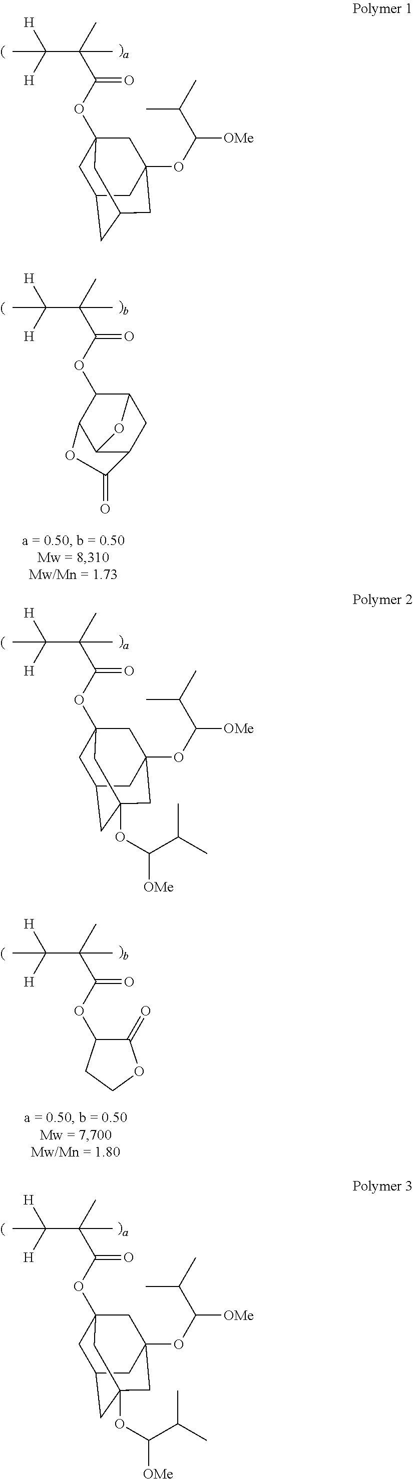

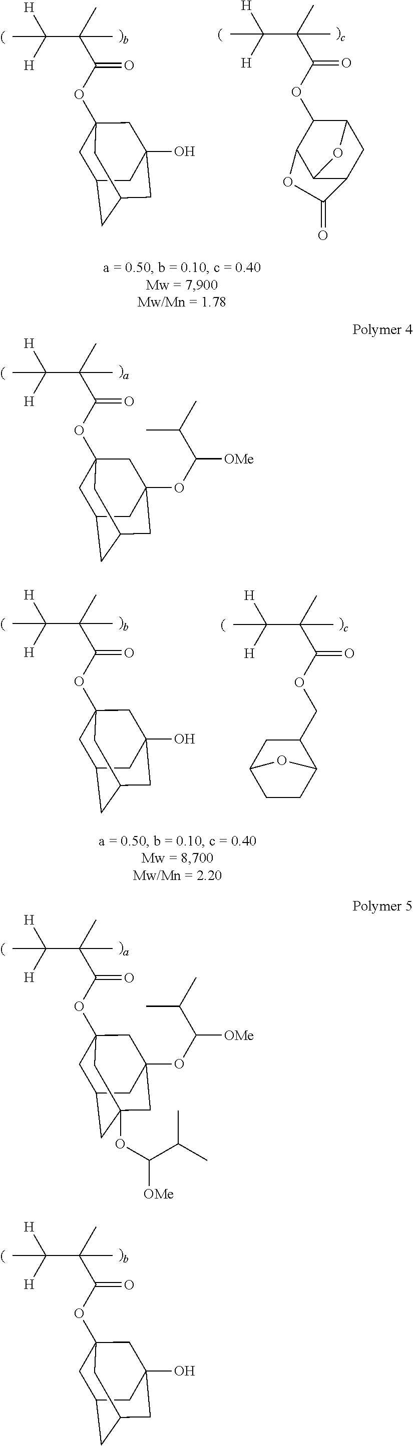

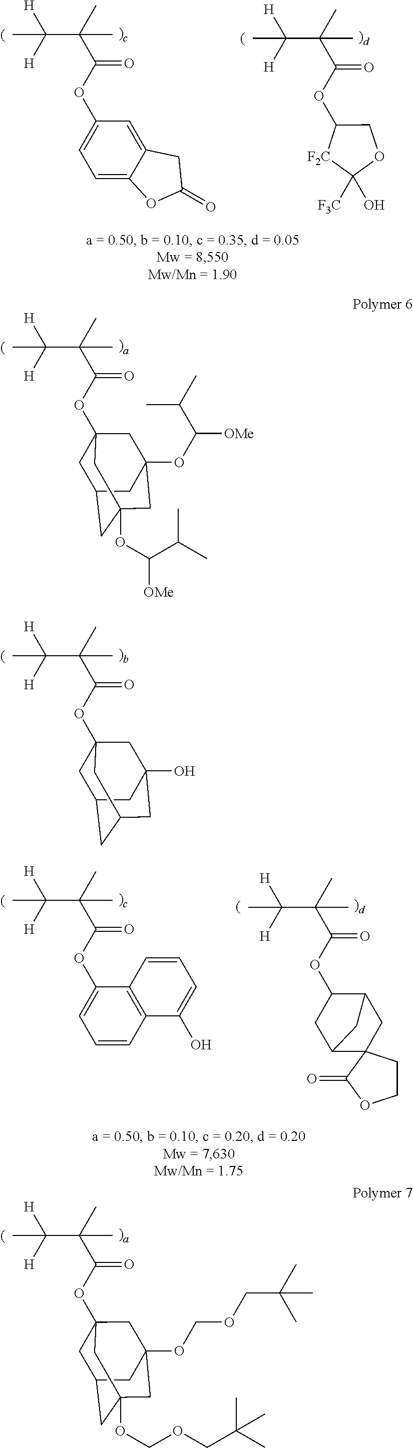

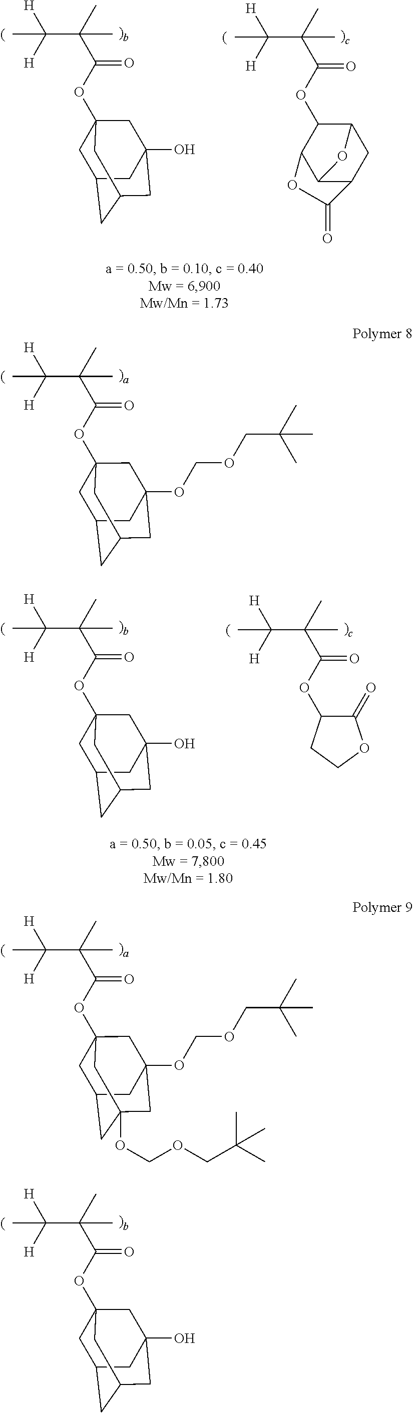

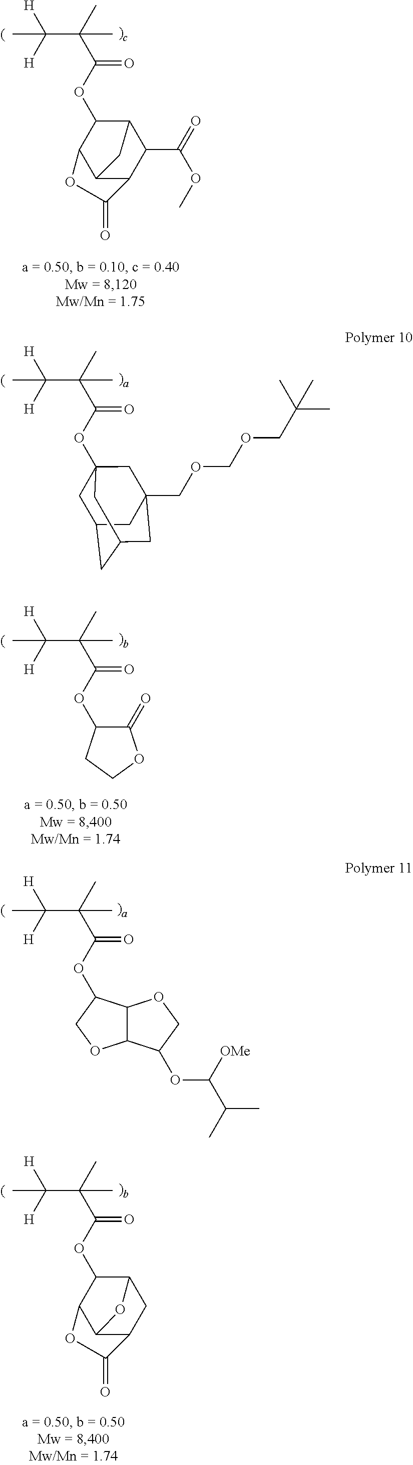

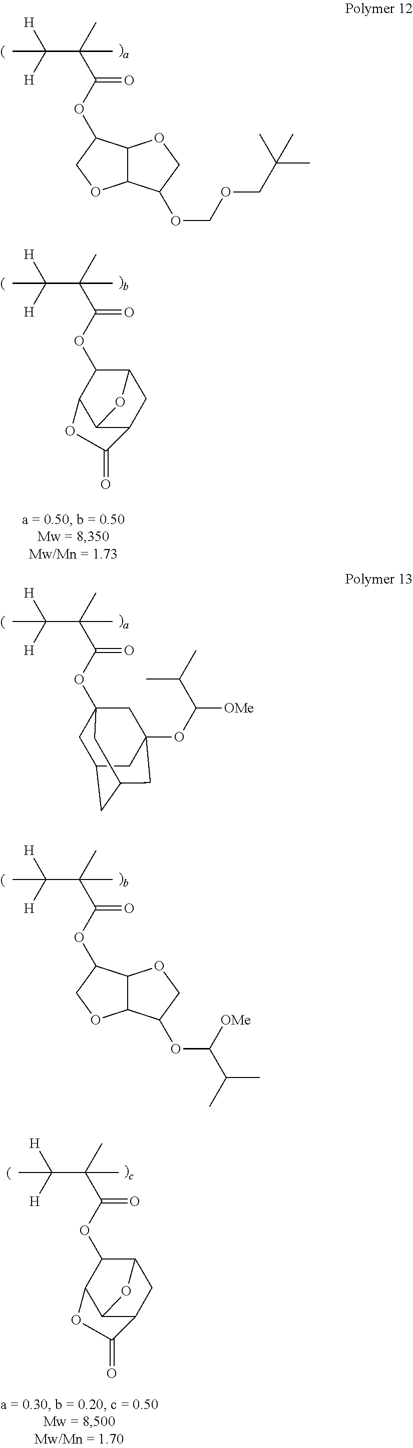

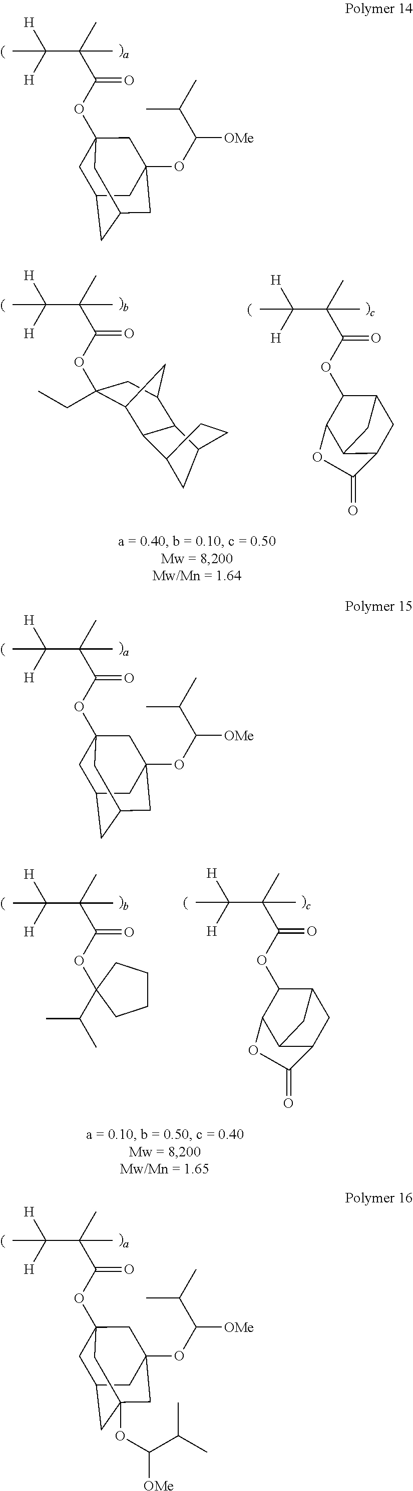

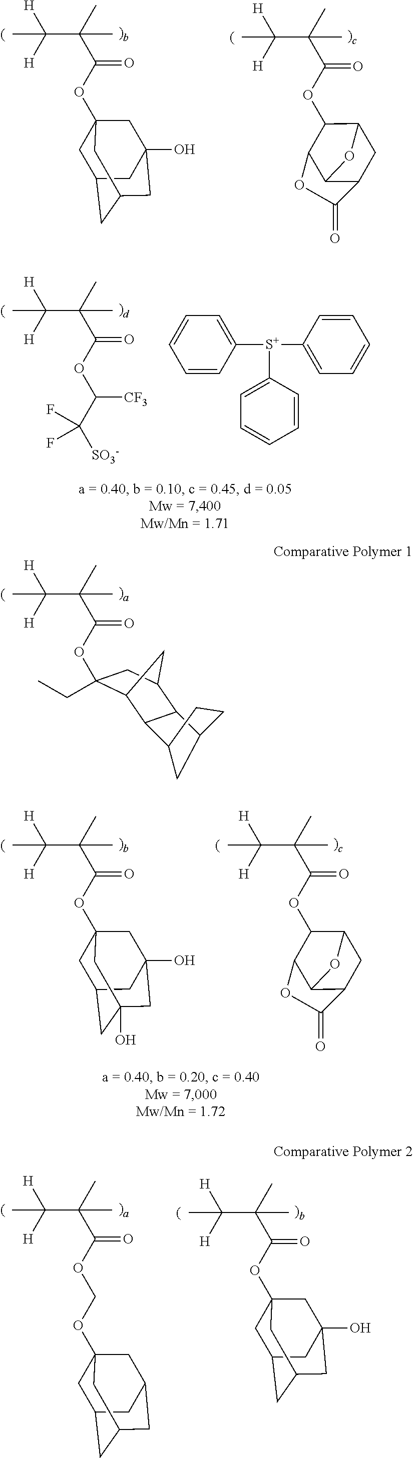

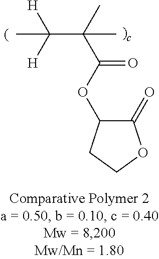

### Preparation of Resist Composition and Protective Film-Forming Composition

A resist composition in solution form was prepared by dissolving a polymer (Polymers 1 to 16, Comparative Polymers 1 and 2) and components in solvents in accordance with the formulation of Tables 1 and 2. A protective film-forming composition in solution form was prepared by dissolving a polymer (TC Polymer) and additive in solvents in accordance with the formulation of Table 3. The solutions were filtered through a Teflon® filter with a pore size of 0.2 μm.

The components are identified below.

Acid generator B: PAG-1 to PAG-10 of the Following Structural Formulae

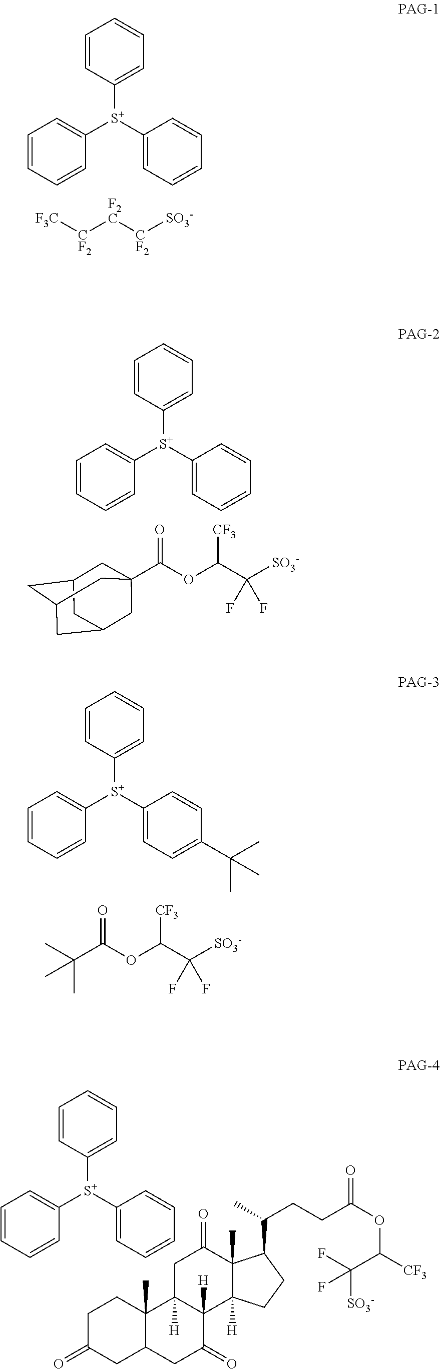

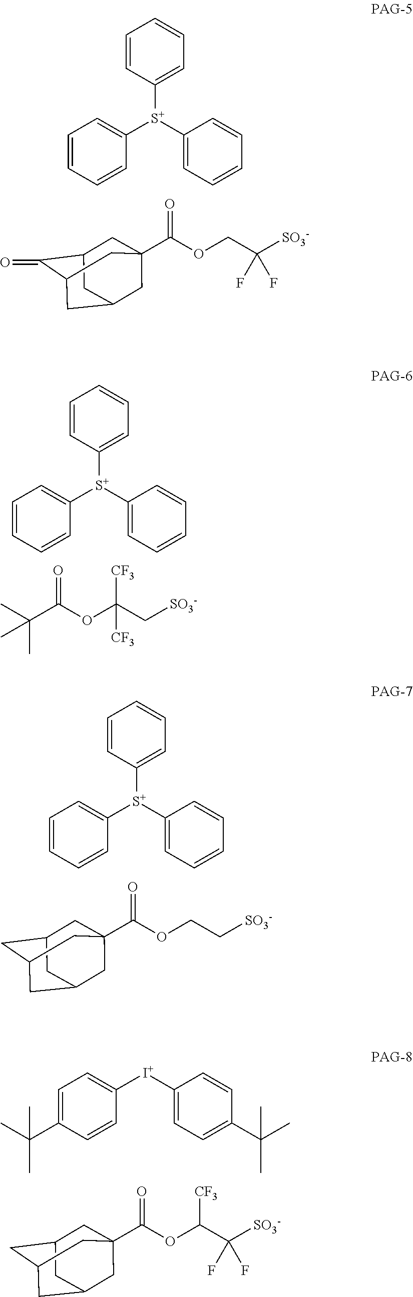

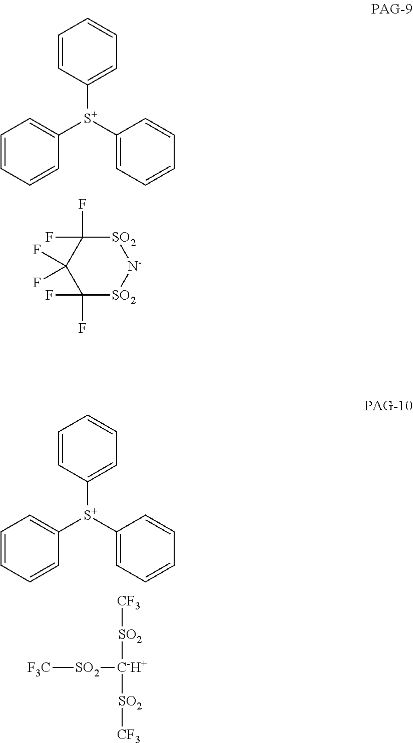

Onium salt C: Salt-1 to Salt-6 of the Following Structural Formulae

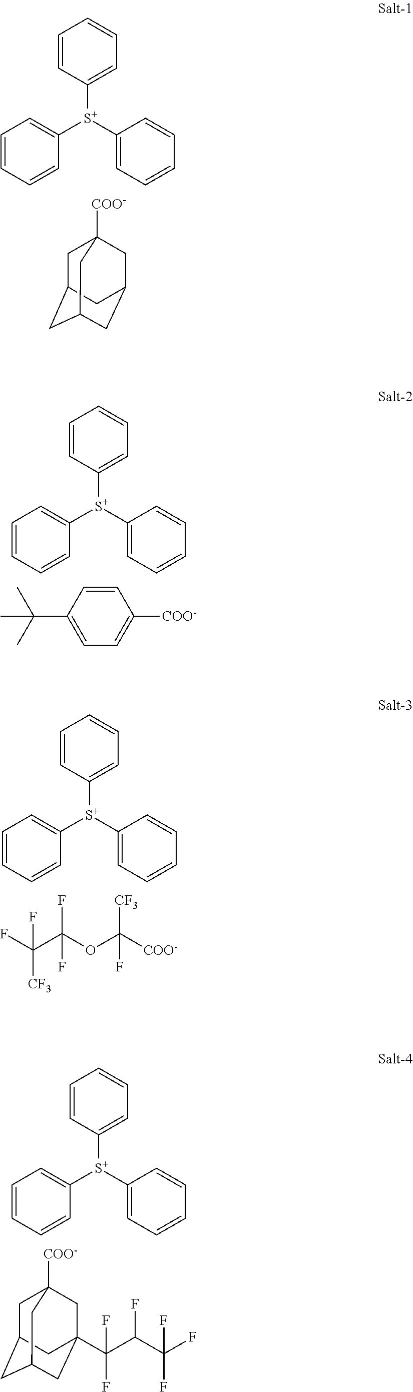

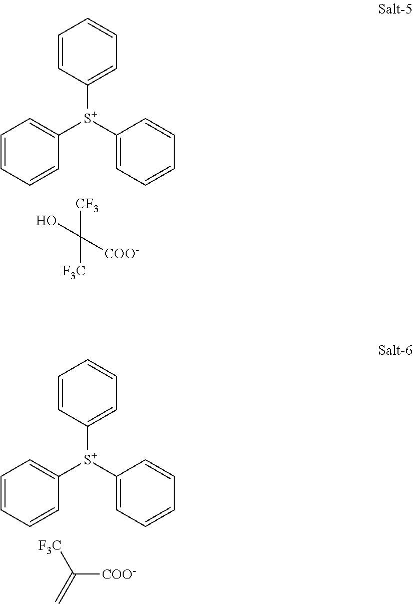

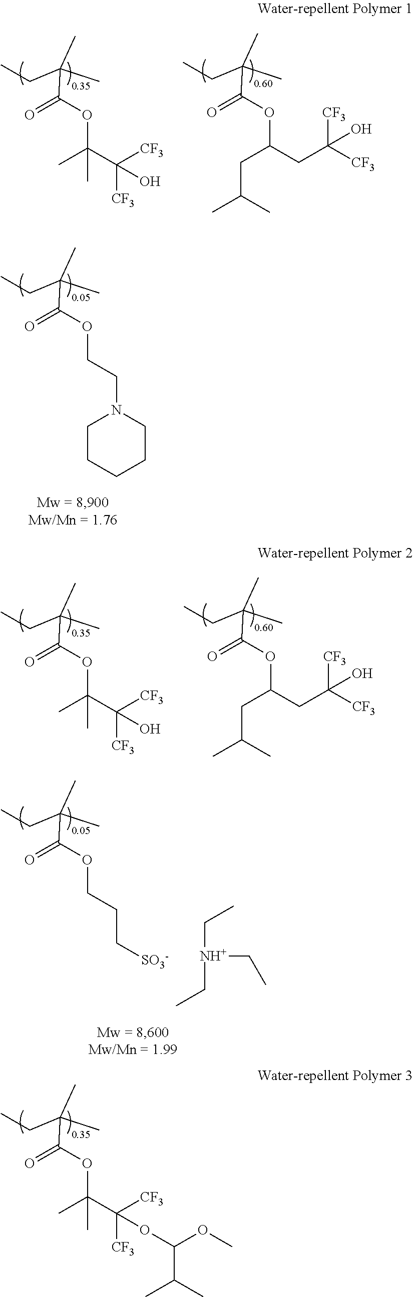

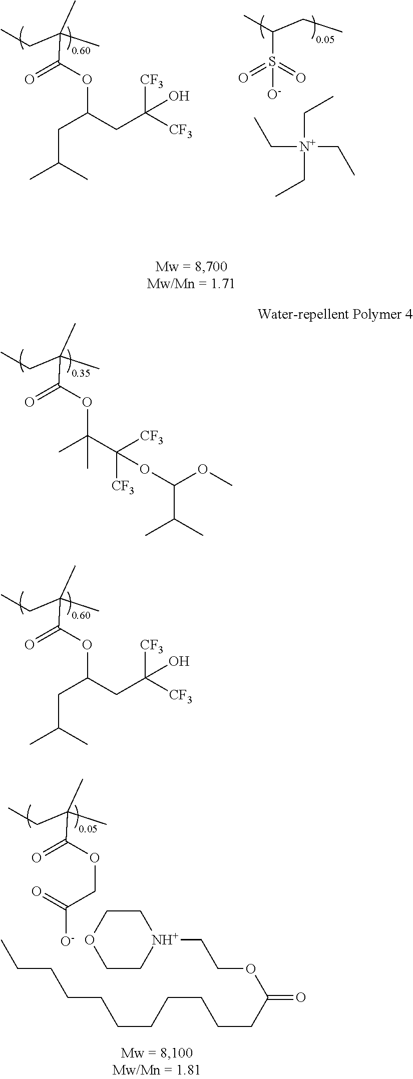

### Basic Compound: Quencher-1 of the Following Structural Formula

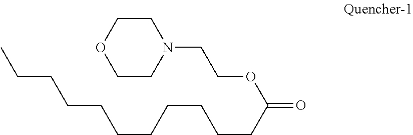

### Organic Solvent:

PGMEA (propylene glycol monomethyl ether acetate)

γBL (γ-butyrolactone)

TC polymers 1 to 6 used in the protective film-forming compositions in Table 3 are identified below.

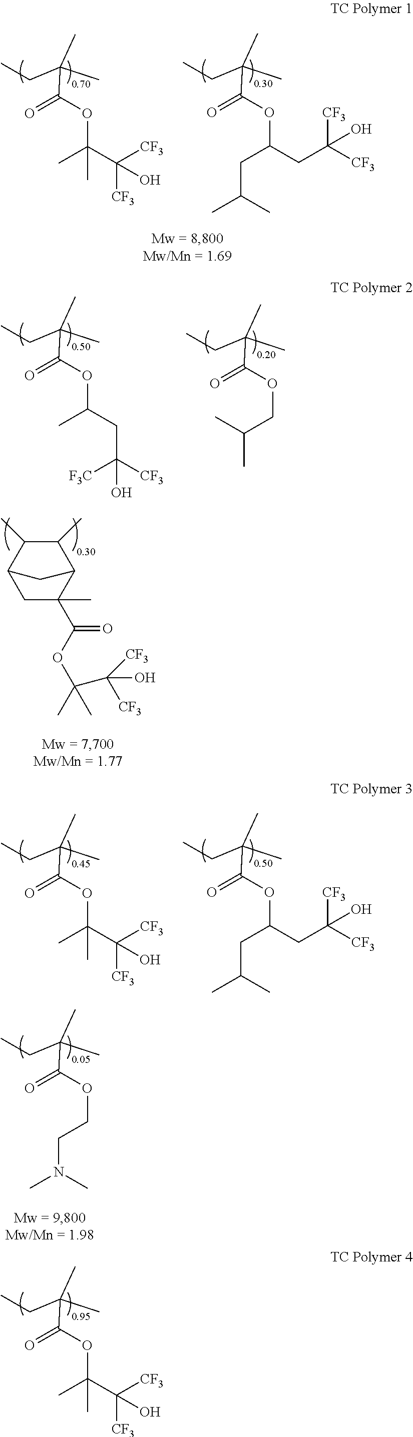

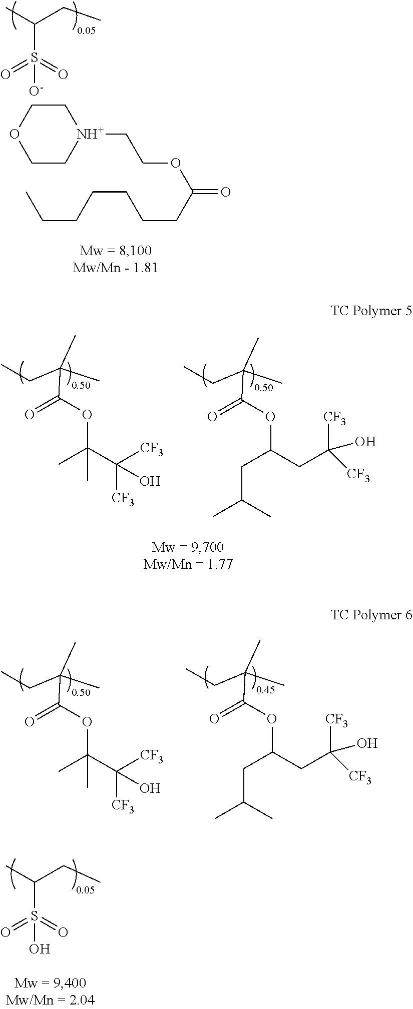

### Example 1-1 & Comparative Examples 1-1, 1-2

### ArF Lithography Patterning Test 1

On a substrate (silicon wafer) having an antireflective coating (Nissan Chemical Industries, Ltd.) of 80 nm thick, the resist composition in Table 1 was spin coated and baked on a hot plate at 100° C. for 60 seconds to form a resist film of 100 nm thick.

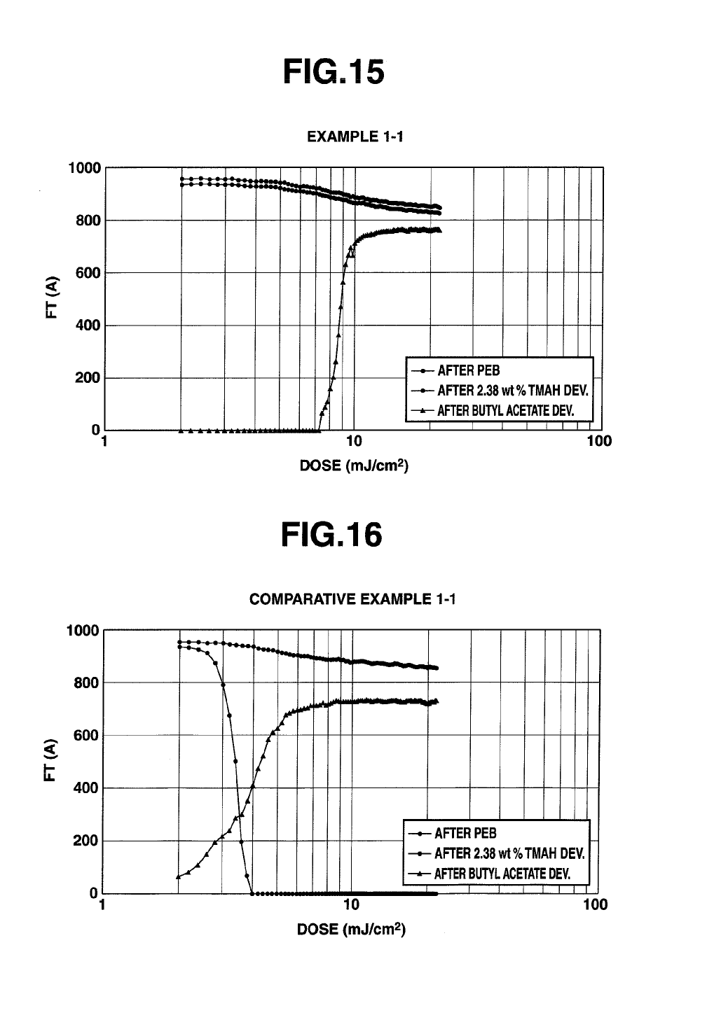

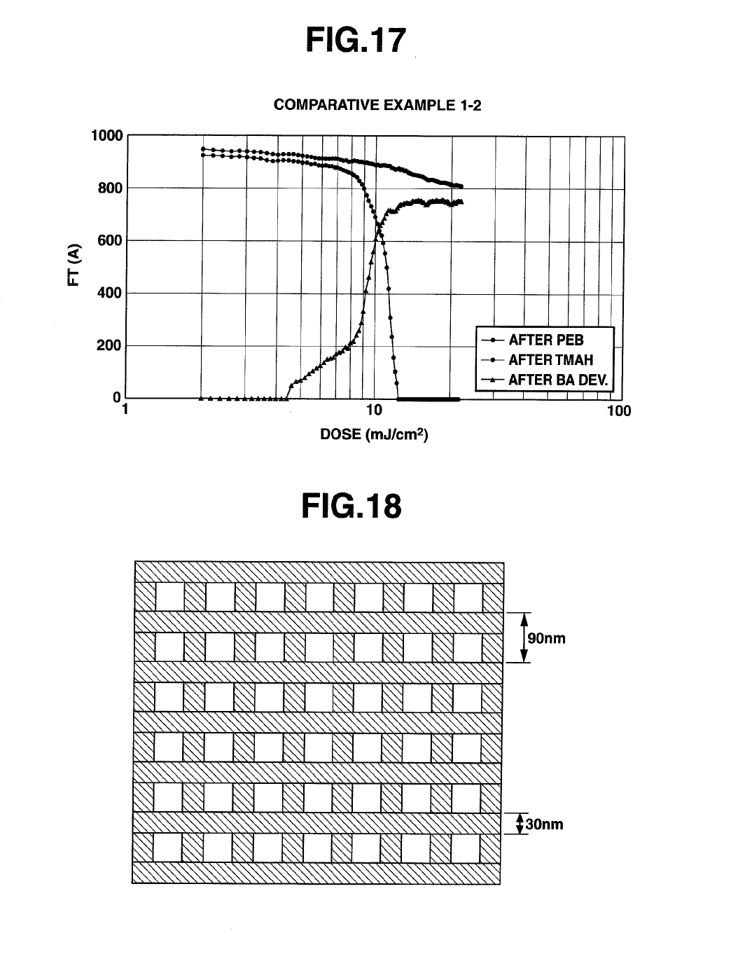

Using an ArF excimer laser scanner NSR-307E (Nikon Corp., NA 0.85, σ 0.73), the resist film was open-frame exposed in a dose which varied stepwise by 0.2 mJ/cm². The exposed resist film was baked (PEB) at 100° C. for 60 seconds and puddle developed for 60 seconds in an organic solvent developer as shown in Table 1. The wafer was rinsed at 500 rpm with a rinse liquid (organic solvent) as shown in Table 1, spin dried at 2,000 rpm, and baked at 100° C. for 60 seconds to evaporate off the rinse liquid. Separately, the same process was repeated until the PEB, and followed by development in a 2.38 wt % tetramethylammonium hydroxide (TMAH) aqueous solution. The film thickness after PEB, the film thickness after organic solvent development (butyl acetate), and the film thickness after TMAH aqueous solution development were measured. A contrast curve was determined by plotting the film thickness versus the exposure dose. The results are shown in FIGS. 15 to 17.

TABLE 1

| | | | | Onium | Basic | Organic | | |
|---|---|---|---|---|---|---|---|---|
| | | Polymer A | PAG B | salt C | compound | solvent | | Rinse |
| | | (pbw) | (pbw) | (pbw) | (pbw) | (pbw) | Developer | liquid |
| Example 1-1 | Resist 1-1 | Polymer 1 | PAG-1 | Salt-1 | — | PGMEA | butyl | 4-methyl- |
| | | (100) | (5.5) | (4.5) | | (800) | acetate | 2-pentanol |
| | | | | | | γBL | | |
| | | | | | | (400) | | |
| Comparative | Comparative | Comparative | PAG-1 | — | Quencher-1 | PGMEA | butyl | 4-methyl- |
| Example 1-1 | Resist 1-1 | Polymer 1 | (12) | | (2) | (800) | acetate | 2-pentanol |
| | | (100) | | | | γBL | | |
| | | | | | | (400) | | |
| Comparative | Comparative | Comparative | PAG-1 | Salt-1 | — | PGMEA | butyl | 4-methyl- |
| Example 1-2 | Resist 1-2 | Polymer 2 | (5.5) | (4.5) | | (800) | acetate | 2-pentanol |
| | | (100) | | | | γBL | | |
| | | | | | | (400) | | |

### Examples 2-1 to 2-29 & Comparative Examples 2-1 to 2-6

### ArF Lithography Patterning Test 2

On a substrate (silicon wafer), a spin-on carbon film ODL-101 (Shin-Etsu Chemical Co., Ltd.) having a carbon content of 80 wt % was deposited to a thickness of 180 nm and a silicon-containing spin-on hard mask SHB-A940 having a silicon content of 43 wt % was deposited thereon to a thickness of 35 nm. On this substrate for trilayer process, the resist composition in Table 2 was spin coated, then baked on a hot plate at 100° C. for 60 seconds to form a resist film of 100 nm thick. The protective film-forming composition TC-1 in Table 3 was spin coated on the resist film and baked at 90° C. for 60 seconds to form a protective film (or topcoat) of 50 nm thick. In Examples 2-25 to 2-29 and Comparative Examples 2-2 to 2-4, the protective film was omitted.

Using an ArF excimer laser immersion lithography scanner NSR-610C (Nikon Corp., NA 1.30, σ 0.98/0.78, cross-pole opening 20 deg., azimuthally polarized illumination), exposure was performed in a varying dose through a 6% halftone phase shift mask bearing a lattice-like pattern with a pitch of 90 nm and a line width of 30 nm (on-wafer size) whose layout is shown in FIG. 18. After the exposure, the wafer was baked (PEB) at the temperature shown in Table 4 for 60 seconds and developed. Specifically, butyl acetate was injected from a development nozzle while the wafer was spun at 30 rpm for 3 seconds, which was followed by stationary puddle development for 17 seconds. The wafer was rinsed with 4-methyl-2-pentanol, spin dried, and baked at 100° C. for 20 seconds to evaporate off the rinse liquid.

A hole pattern resulted from image reversal by solvent development. By observation under TDSEM S-9380, the size of 50 holes was measured, from which a size variation 3σ was determined. The results are shown in Table 4.

TABLE 2

| | | | Onium | Basic | | Organic |
|---|---|---|---|---|---|---|
| | Polymer A | PAG B | salt C | compound | Additive | solvent |
| | (pbw) | (pbw) | (pbw) | (pbw) | (pbw) | (pbw) |
| Resist 2-1 | Polymer 1 | PAG-2 | Salt-1 | — | — | PGMEA(800) |
| | (100) | (4.0) | (4.0) | | | γBL(400) |
| Resist 2-2 | Polymer 1 | PAG-5 | Salt-1 | — | — | PGMEA(800) |
| | (100) | (4.0) | (4.0) | | | γBL(400) |
| Resist 2-3 | Polymer 1 | PAG-6 | Salt-1 | — | — | PGMEA(800) |
| | (100) | (4.0) | (4.0) | | | γBL(400) |
| Resist 2-4 | Polymer 1 | PAG-7 | Salt-1 | — | — | PGMEA(800) |
| | (100) | (4.0) | (4.0) | | | γBL(400) |
| Resist 2-5 | Polymer 1 | PAG-8 | Salt-2 | — | — | PGMEA(800) |
| | (100) | (4.0) | (4.0) | | | γBL(400) |
| Resist 2-6 | Polymer 1 | PAG-9 | Salt-3 | — | — | PGMEA(800) |
| | (100) | (4.0) | (4.0) | | | γBL(400) |
| Resist 2-7 | Polymer 1 | PAG-10 | Salt-5 | — | — | PGMEA(800) |
| | (100) | (4.0) | (4.0) | | | γBL(400) |
| Resist 2-8 | Polymer 2 | PAG-2 | Salt-1 | — | — | PGMEA(800) |
| | (100) | (4.0) | (4.0) | | | γBL(400) |
| Resist 2-9 | Polymer 3 | PAG-3 | Salt-1 | — | — | PGMEA(800) |
| | (100) | (4.0) | (4.0) | | | γBL(400) |
| Resist 2-10 | Polymer 4 | PAG-2 | Salt-1 | — | — | PGMEA(800) |
| | (100) | (4.0) | (4.0) | | | γBL(400) |
| Resist 2-11 | Polymer 5 | PAG-2 | Salt-1 | — | — | PGMEA(800) |
| | (100) | (5.5) | (4.0) | | | γBL(400) |
| Resist 2-12 | Polymer 6 | PAG-4 | Salt-1 | — | — | PGMEA(800) |
| | (100) | (4.0) | (4.0) | | | γBL(400) |
| Resist 2-13 | Polymer 7 | PAG-2 | Salt-1 | — | — | PGMEA(800) |
| | (100) | (4.0) | (4.0) | | | γBL(400) |
| Resist 2-14 | Polymer 8 | PAG-2 | Salt-3 | — | — | PGMEA(800) |
| | (100) | (4.0) | (4.0) | | | γBL(400) |
| Resist 2-15 | Polymer 9 | PAG-2 | Salt-3 | — | — | PGMEA(800) |
| | (100) | (4.0) | (4.0) | | | γBL(400) |
| Resist 2-16 | Polymer 10 | PAG-2 | Salt-3 | — | — | PGMEA(800) |
| | (100) | (4.0) | (4.0) | | | γBL(400) |
| Resist 2-17 | Polymer 11 | PAG-2 | Salt-4 | — | — | PGMEA(800) |
| | (100) | (4.0) | (4.0) | | | γBL(400) |
| Resist 2-18 | Polymer 12 | PAG-2 | Salt-5 | — | — | PGMEA(800) |
| | (100) | (4.0) | (4.0) | | | γBL(400) |
| Resist 2-19 | Polymer 13 | PAG-2 | Salt-6 | — | — | PGMEA(800) |
| | (100) | (4.0) | (4.0) | | | γBL(400) |
| Resist 2-20 | Polymer 14 | PAG-2 | Salt-4 | — | — | PGMEA(800) |
| | (100) | (4.0) | (4.0) | | | γBL(400) |
| Resist 2-21 | Polymer 15 | PAG-2 | Salt-5 | — | — | PGMEA(800) |
| | (100) | (4.0) | (4.0) | | | γBL(400) |
| Resist 2-22 | Polymer 16 | — | Salt-1 | — | — | PGMEA(800) |
| | (100) | | (4.0) | | | γBL(400) |
| Resist 2-23 | Polymer 13 | PAG-2 | Salt-4 | — | — | PGMEA(800) |
| | (100) | (2.0) | (4.0) | | | γBL(400) |
| | | PAG-3 | | | | |
| | | (2.0) | | | | |
| Resist 2-24 | Polymer 13 | PAG-2 | Salt-4 | Quencher-1 | — | PGMEA(800) |
| | (100) | (2.0) | (3.0) | (2) | | γBL(400) |
| | | PAG-3 | | | | |
| | | (2.0) | | | | |
| Resist 2-25 | Polymer 4 | PAG-2 | Salt-1 | — | Water repellent polymer 1 | PGMEA(800) |
| | (100) | (4.0) | (4.0) | | (6) | γBL(400) |
| Resist 2-26 | Polymer 4 | PAG-2 | Salt-1 | — | Water repellent polymer 2 | PGMEA(800) |
| | (100) | (4.0) | (4.0) | | (6) | γBL(400) |
| Resist 2-27 | Polymer 4 | PAG-2 | Salt-1 | — | Water repellent polymer 3 | PGMEA(800) |
| | (100) | (4.0) | (4.0) | | (6) | γBL(400) |
| Resist 2-28 | Polymer 4 | PAG-2 | Salt-1 | — | Water repellent polymer 4 | PGMEA(800) |
| | (100) | (4.0) | (4.0) | | (6) | γBL(400) |
| Resist 2-29 | Polymer 15 | PAG-2 | Salt-5 | — | Water repellent polymer 1 | PGMEA(800) |
| | (100) | (4.0) | (4.0) | | (6) | γBL(400) |
| Comparative | Polymer 1 | PAG-2 | — | Quencher-1 | — | PGMEA(800) |
| Resist 2-1 | (100) | (10.0) | | (2) | | γBL(400) |
| Comparative | Comparative Polymer 1 | PAG-2 | Salt-1 | — | — | PGMEA(800) |
| Resist 2-2 | (100) | (4.0) | (4.0) | | | γBL(400) |
| Comparative | Comparative Polymer 2 | PAG-2 | Salt-1 | — | — | PGMEA(800) |
| Resist 2-3 | (100) | (4.0) | (4.0) | | | γBL(400) |
| Comparative | Comparative Polymer 1 | PAG-2 | Salt-1 | — | Water repellent polymer 4 | PGMEA(800) |
| Resist 2-4 | (100) | (4.0) | (4.0) | | (6) | γBL(400) |

TABLE 3

| | Polymer A | Additive | Organic solvent |
|---|---|---|---|
| | (pbw) | (pbw) | (pbw) |
| TC-1 | TC polymer 1 (100) | tri-n-octyl- | diisoamyl ether (2,700) |
| | | amine (0.5) | 2-methyl-1-butanol (270) |
| TC-2 | TC polymer 2 (100) | tri-n-octyl- | diisoamyl ether (2,700) |
| | | amine (0.5) | 2-methyl-1-butanol (270) |
| TC-3 | TC polymer 3 (100) | — | diisoamyl ether (2,700) |
| | | | 2-methyl-1-butanol (270) |
| TC-4 | TC polymer 2 (80) | — | diisoamyl ether (2,700) |
| | TC polymer 4 (20) | | 2-methyl-1-butanol (270) |
| TC-5 | TC polymer 5 (80) | — | diisoamyl ether (2,700) |
| | TC polymer 4 (20) | | 2-methyl-1-butanol (270) |
| Compara- | TC polymer 1 (100) | — | diisoamyl ether (2,700) |
| tive TC-1 | | | 2-methyl-1-butanol (270) |
| Compara- | TC polymer 6 (100) | — | diisoamyl ether (2,700) |
| tive TC-2 | | | 2-methyl-1-butanol (270) |

TABLE 4

| | | | PEB | | Hole size |
|---|---|---|---|---|---|
| | | Protec- | temp. | Dose | variation |
| | Resist | tive film | (° C.) | (mJ/cm²) | 3σ (nm) |
| Example 2-1 | Resist 2-1 | TC-1 | 105 | 38 | 1.7 |
| Example 2-2 | Resist 2-2 | TC-1 | 95 | 51 | 1.8 |
| Example 2-3 | Resist 2-3 | TC-1 | 90 | 49 | 2.0 |
| Example 2-4 | Resist 2-4 | TC-1 | 95 | 47 | 2.1 |
| Example 2-5 | Resist 2-5 | TC-1 | 95 | 42 | 1.7 |
| Example 2-6 | Resist 2-6 | TC-1 | 100 | 48 | 2.2 |
| Example 2-7 | Resist 2-7 | TC-1 | 105 | 38 | 2.3 |
| Example 2-8 | Resist 2-8 | TC-1 | 110 | 42 | 1.9 |
| Example 2-9 | Resist 2-9 | TC-2 | 100 | 53 | 2.0 |
| Example 2-10 | Resist 2-10 | TC-3 | 105 | 42 | 2.1 |
| Example 2-11 | Resist 2-11 | TC-4 | 105 | 45 | 1.8 |
| Example 2-12 | Resist 2-12 | TC-5 | 100 | 39 | 1.9 |
| Example 2-13 | Resist 2-13 | TC-1 | 95 | 41 | 2.3 |
| Example 2-14 | Resist 2-14 | TC-1 | 100 | 32 | 2.1 |
| Example 2-15 | Resist 2-15 | TC-1 | 95 | 41 | 2.3 |
| Example 2-16 | Resist 2-16 | TC-1 | 110 | 54 | 2.1 |
| Example 2-17 | Resist 2-17 | TC-1 | 85 | 54 | 2.1 |
| Example 2-18 | Resist 2-18 | TC-1 | 100 | 42 | 1.8 |
| Example 2-19 | Resist 2-19 | TC-1 | 90 | 32 | 1.9 |
| Example 2-20 | Resist 2-20 | TC-1 | 90 | 54 | 1.8 |
| Example 2-21 | Resist 2-21 | TC-1 | 100 | 43 | 2.1 |
| Example 2-22 | Resist 2-22 | TC-1 | 80 | 45 | 2.2 |
| Example 2-23 | Resist 2-23 | TC-1 | 100 | 33 | 2.0 |
| Example 2-24 | Resist 2-24 | TC-1 | 100 | 43 | 2.0 |
| Example 2-25 | Resist 2-25 | — | 100 | 45 | 1.8 |
| Example 2-26 | Resist 2-26 | — | 100 | 39 | 1.9 |
| Example 2-27 | Resist 2-27 | — | 100 | 47 | 1.9 |
| Example 2-28 | Resist 2-28 | — | 100 | 46 | 1.7 |
| Example 2-29 | Resist 2-29 | — | 100 | 35 | 1.6 |
| Comparative | Comparative | TC-1 | 100 | 42 | 2.9 |
| Example 2-1 | Resist 2-1 | | | | |
| Comparative | Comparative | — | 100 | 48 | 3.0 |
| Example 2-2 | Resist 2-2 | | | | |
| Comparative | Comparative | — | 100 | 53 | 3.4 |
| Example 2-3 | Resist 2-3 | | | | |
| Comparative | Comparative | — | 100 | 49 | 3.5 |
| Example 2-4 | Resist 2-4 | | | | |
| Comparative | Resist 2-3 | Compara- | 90 | 54 | 2.9 |
| Example 2-5 | | tive TC-1 | | | |
| Comparative | Resist 2-3 | Compara- | 90 | 50 | 3.0 |
| Example 2-6 | | tive TC-2 | | | |

### Examples 3-1, 3-2 & Comparative Example 3-1

### ArF Lithography Patterning Test 3

On a substrate (silicon wafer), a spin-on carbon film ODL-50 (Shin-Etsu Chemical Co., Ltd.) having a carbon content of 80 wt % was deposited to a thickness of 200 nm and a silicon-containing spin-on hard mask SHB-A940 having a silicon content of 43 wt % was deposited thereon to a thickness of 35 nm. On this substrate for trilayer process, the resist composition (Resist 2-15, 2-16, or Comparative Resist 2-4) in Table 2 was spin coated, then baked on a hot plate at 100° C. for 60 seconds to form a resist film of 100 nm thick. The protective film-forming composition TC-1 in Table 3 was spin coated on the resist film and baked at 90° C. for 60 seconds to form a protective film (or topcoat) of 50 nm thick.

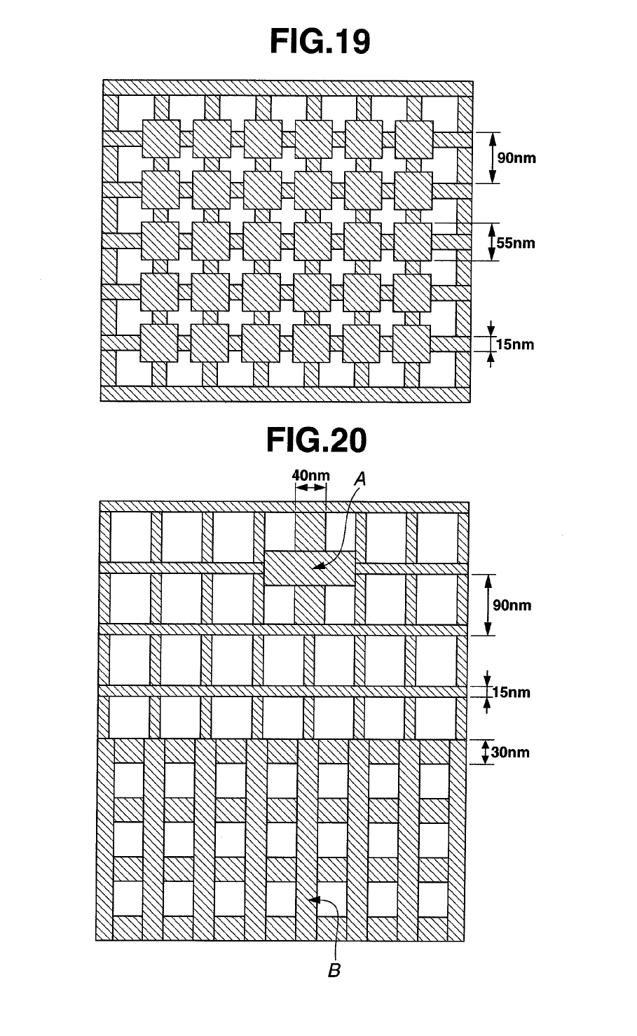

Using an ArF excimer laser immersion lithography scanner NSR-610C (Nikon Corp., NA 1.30, a 0.98/0.78, cross-pole opening 20 deg., azimuthally polarized illumination), exposure was performed through a 6% halftone phase shift mask bearing a lattice-like pattern with a pitch of 90 nm and a line width of 15 nm (on-wafer size) having dots disposed at intersections, whose layout is shown in FIG. 19, while the dose and focus were varied. After the exposure, the wafer was baked (PEB) at the temperature shown in Table 5 for 60 seconds and developed. Specifically, butyl acetate was injected from a development nozzle while the wafer was spun at 30 rpm for 3 seconds, which was followed by stationary puddle development for 27 seconds. The wafer was rinsed with diisoamyl ether, spin dried, and baked at 100° C. for 20 seconds to evaporate off the rinse liquid.

A hole pattern resulted from image reversal by solvent development. By observation under TDSEM S-9380, the size of 50 holes was measured, from which a size variation 3σ was determined. The results are shown in Table 5.

TABLE 5

| | | PEB | | Hole size |
|---|---|---|---|---|
| | | temp. | Dose | variation |
| | Resist | (° C.) | (mJ/cm²) | 3σ (nm) |
| Example 3-1 | Resist 2-15 | 105 | 18 | 3.2 |
| Example 3-2 | Resist 2-16 | 95 | 19 | 2.9 |
| Comparative | Comparative | 100 | 24 | 4.1 |
| Example 3-1 | Resist 2-4 | | | |

### Examples 4-1, 4-2 & Comparative Example 4-1

### ArF Lithography Patterning Test 4

On a substrate (silicon wafer), a spin-on carbon film ODL-101 (Shin-Etsu Chemical Co., Ltd.) having a carbon content of 80 wt % was deposited to a thickness of 180 nm and a silicon-containing spin-on hard mask SHB-A940 having a silicon content of 43 wt % was deposited thereon to a thickness of 35 nm. On this substrate for trilayer process, the resist composition (Resist 2-15, 2-16, or Comparative Resist 2-4) in Table 2 was spin coated, then baked on a hot plate at 100° C. for 60 seconds to form a resist film of 100 nm thick.

Using an ArF excimer laser immersion lithography scanner NSR-610C (Nikon Corp., NA 1.30, σ 0.98/0.78, cross-pole opening 20 deg., azimuthally polarized illumination), exposure was performed through a 6% halftone phase shift mask bearing a lattice-like pattern with a pitch of 90 nm (on-wafer size) having thick gratings disposed at intersections whose layout is shown in FIG. 20, while the dose was varied. After the exposure, the wafer was baked (PEB) at the temperature shown in Table 6 for 60 seconds and developed. Specifically, butyl acetate was injected from a development nozzle while the wafer was spun at 30 rpm for 3 seconds, which was followed by stationary puddle development for 27 seconds. The wafer was rinsed with diisoamyl ether, spin dried, and baked at 100° C. for 20 seconds to evaporate off the rinse liquid.

A hole pattern resulted from image reversal by solvent development. By observation under TDSEM S-9380, the size of holes at positions A and B on the mask (FIG. 20) was measured. The results are shown in Table 6.

TABLE 6

| | | | | Hole | Hole |
|---|---|---|---|---|---|
| | | PEB | | size | size |
| | | temp. | Dose | at A | at B |
| | Resist | (° C.) | (mJ/cm²) | (nm) | (nm) |
| Example 4-1 | Resist 2-15 | 105 | 32 | 40 | 39 |
| Example 4-2 | Resist 2-16 | 95 | 35 | 41 | 42 |
| Comparative | Comparative | 100 | 43 | 24 | 53 |
| Example 4-1 | Resist 2-4 | | | | |

While the invention has been described with reference to a preferred embodiment, it will be understood by those skilled in the art that various changes may be made and equivalents may be substituted for elements thereof without departing from the scope of the invention. Therefore, it is intended that the invention not be limited to the particular embodiment disclosed as the best mode contemplated for carrying out this invention, but that the invention will include all embodiments falling within the scope of the appended claims.

Japanese Patent Application Nos. 2011-106011 and 2011-203162 are incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A resist composition comprising
(A) a polymer comprising recurring units (a) having a hydroxyl group substituted with an acid labile group, represented by the general formula (1),
(B) at least one photoacid generator selected from an onium salt type photoacid generator capable of generating a sulfonic acid of the general formula (2), an onium salt type photoacid generator capable of generating an imide acid of the general formula (3), and an onium salt type photoacid generator capable of generating a methide acid of the general formula (4), and
(C) an onium salt type photoacid generator capable of generating a carboxylic acid of the general formula (5),
wherein the cations of the onium salts of (B) and (C) each are a sulfonium cation having the general formula (6) or an iodonium cation having the general formula (7), 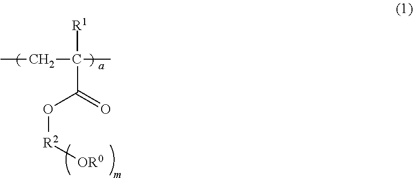
wherein R¹ is hydrogen or methyl, R² is a C₁-C₁₆ straight, branched or cyclic aliphatic hydrocarbon group having a valence of 2 to 5 which may contain an ether or ester radical, R⁰ is an acid labile group, “a” is a number in the range: 0<a≦1.0, and m is an integer of 1 to 4, 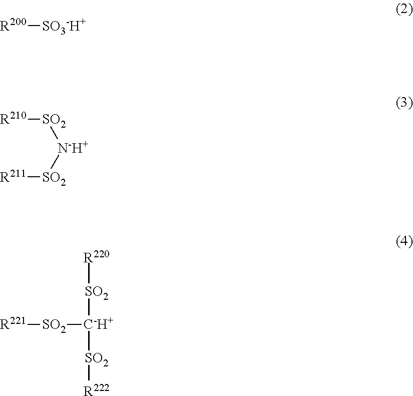
wherein R²⁰⁰ is a C₁-C₂₈ straight, branched or cyclic alkyl group, C₆-C₂₈ aryl group or C₇-C₂₈ aralkyl group, in which a methylene moiety may be substituted by an ether, ester, carbonyl, amide, carbonate or carbamate radical, and in which some or all hydrogen atoms may be substituted by at least one radical selected from the group consisting of halogen, hydroxyl, carboxyl, amino, cyano, nitro, and sulfonic acid ester;
R²¹⁰ and R²¹¹ each are an optionally substituted C₁-C₈ straight or branched fluoroalkyl group, or R²¹⁰ and R²¹¹ may bond together to form a ring, wherein R²¹⁰ and R²¹¹ each are a C₁-C₈ fluoroalkylene group;
R²²⁰, R²²¹ and R²²² each are an optionally substituted C₁-C₈ straight or branched fluoroalkyl group, or R²²⁰ and R²²¹ may bond together to form a ring, wherein R²²⁰ and R²²¹ each are a C₁-C₈ fluoroalkylene group,
R³⁰⁰—COO⁻H⁺ (5)
wherein R³⁰⁰ is a C₁-C₂₅ straight, branched or cyclic alkyl group, C₂-C₂₅ alkenyl group, C₆-C₂₅ aryl group or C₇-C₂₅ aralkyl group, in which a methylene moiety may be substituted by an ether, ester or carbonyl radical, and in which some or all hydrogen atoms may be substituted by at least one radical selected from the group consisting of halogen, hydroxyl, carboxyl, amino, cyano, nitro, and sulfonic acid ester, 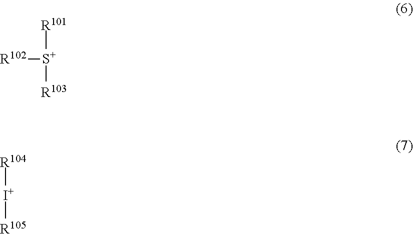
wherein R¹⁰¹, R¹⁰² and R¹⁰³ are each independently a C₁-C₂₀ straight or cyclic alkyl group, C₂-C₂₀ alkenyl group, C₆-C₂₀ aryl group or C₇-C₂₀ aralkyl group, in which a methylene moiety may be substituted by an ether, ester or carbonyl radical, and in which some or all hydrogen atoms may be substituted by at least one radical selected from the group consisting of halogen, hydroxyl, carboxyl, amino, and cyano, or two of R¹⁰¹, R¹⁰² and R¹⁰³ may bond together to form a ring with the sulfur atom,
R¹⁰⁴ and R¹⁰⁵ are each independently a C₁-C₂₀ straight or cyclic alkyl group, C₂-C₂₀ alkenyl group, C₆-C₂₀ aryl group or C₇-C₂₀ aralkyl group, in which a methylene moiety may be substituted by an ether, ester or carbonyl radical, and in which some or all hydrogen atoms may be substituted by at least one radical selected from the group consisting of halogen, hydroxyl, carboxyl, amino, and cyano.

2. The resist composition of claim 1 wherein (A) the polymer comprising recurring units (a) having a hydroxyl group substituted with an acid labile group comprises recurring units (a1) or (a2) having a hydroxyl group protected with an acetal protective group, represented by the general formula (1-1) or (1-2): 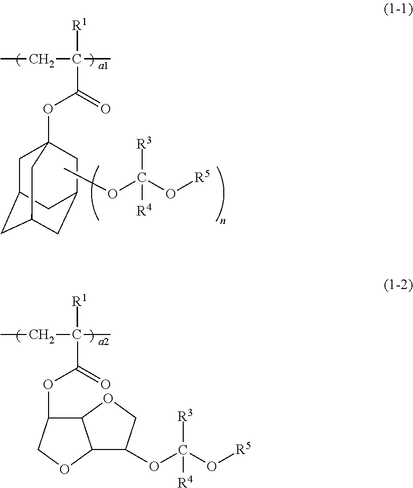
wherein R¹ is hydrogen or methyl, R³ and R⁴ are each independently hydrogen or a C₁-C₁₀ straight, branched or cyclic monovalent hydrocarbon group, R⁵ is a C₁-C₁₆ straight, branched or cyclic monovalent hydrocarbon group which may contain a heteroatom, a1 and a2 are numbers in the range: 0<a1≦1.0, 0<a2≦1.0, and 0<a1+a2≦1.0, and n is an integer of 1 to 3.

3. The resist composition of claim 1 wherein the photoacid generator (B) generates a sulfonic acid of the general formula (8): 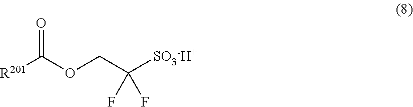
wherein R²⁰¹ is a C₁-C₂₃ straight, branched or cyclic alkyl group, C₆-C₂₃ aryl group or C₇-C₂₃ aralkyl group, in which methylene moiety may be substituted by an ether, ester or carbonyl radical, and in which some or all hydrogen atoms may be substituted by at least one radical selected from the group consisting of halogen, hydroxyl, carboxyl, amino, cyano, nitro, and sulfonic acid ester, with the proviso that R²⁰¹ is not perfluoroalkyl.

4. The resist composition of claim 1 wherein the photoacid generator (B) generates a sulfonic acid of the general formula (9): 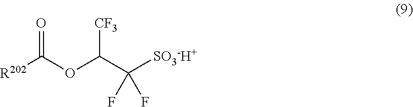
wherein R²⁰² is a C₁-C₂₃ straight, branched or cyclic alkyl group, C₆-C₂₃ aryl group or C₇-C₂₃ aralkyl group, in which a methylene moiety may be substituted by an ether, ester or carbonyl radical, and in which some or all hydrogen atoms may be substituted by at least one radical selected from the group consisting of halogen, hydroxyl, carboxyl, amino, and cyano, with the proviso that R²⁰² is not perfluoroalkyl.

5. The resist composition of claim 1 wherein the photoacid generator (B) generates a sulfonic acid of the general formula (10): 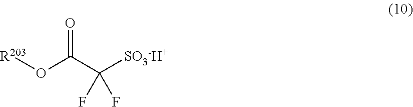
wherein R²⁰³ is an optionally substituted C₁-C₂₀ straight, branched or cyclic alkyl group or optionally substituted C₆-C₁₄ aryl group, with the proviso that R²⁰³ is not perfluoroalkyl.

6. The resist composition of claim 1 wherein the photoacid generator (B) generates a sulfonic acid of the general formula (11): 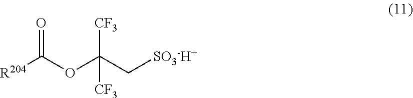
wherein R²⁰⁴ is a C₁-C₂₃ straight, branched or cyclic alkyl group, C₆-C₂₃ aryl group or C₇-C₂₃ aralkyl group, in which a methylene moiety may be substituted by an ether, ester or carbonyl radical, and in which some or all hydrogen atoms may be substituted by at least one radical selected from the group consisting of halogen, hydroxyl, carboxyl, amino, and cyano, with the proviso that R²⁰⁴ is not perfluoroalkyl.

7. The resist composition of claim 1 wherein the photoacid generator (B) generates a sulfonic acid of the general formula (12): 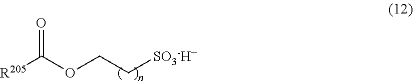
wherein R²⁰⁵ is an optionally substituted C₁-C₂₀ straight, branched or cyclic alkyl group or optionally substituted C₆-C₁₄ aryl group, and n is an integer of 1 to 3, with the proviso that R²⁰⁵ is not perfluoroalkyl.

8. The resist composition of claim 1 wherein the polymer (A) further comprises recurring units (b) having a carboxyl group substituted with an acid labile group, represented by the general formula (14) and/or recurring units (c) having an adhesive group selected from the group consisting of hydroxyl, cyano, carbonyl, ester, ether, lactone ring, carboxyl, and carboxylic anhydride, 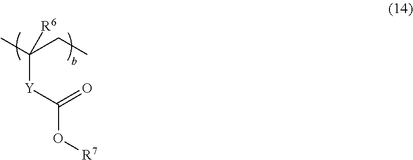
wherein R⁶ is hydrogen or methyl, R⁷ is an acid labile group, Y is a single bond or —C(═O)—O—R⁸—, R⁸ is a C₁-C₁₀ straight, branched or cyclic alkylene group which may contain an ether or ester radical, or a naphthylene group, and b is a number in the range: 0<b<1.0.

9. The resist composition of claim 1 herein the polymer (A) comprising recurring units (a) having a hydroxyl group substituted with an acid labile group, represented by the general formula (1) further comprises recurring units of at least one type selected from units of sulfonium salt having the general formulae (d1) to (d3), and
the onium salt type photoacid generator (C) capable of generating a carboxylic acid of the general formula (5) is present, 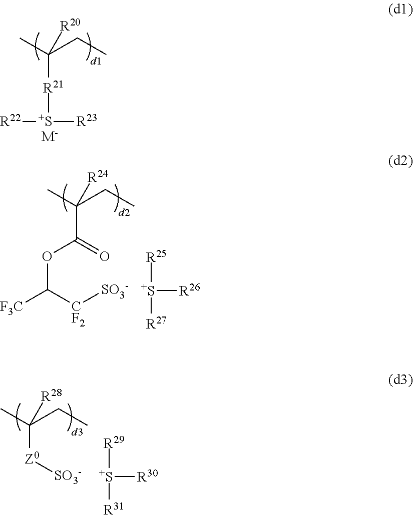
wherein R²⁰, R²⁴, and R²⁸ each are hydrogen or methyl, R²¹ is a single bond, phenylene, —O—R³³—, or —C(═O)—Y—R³³—, Y is oxygen or NH, R³³ is a straight, branched or cyclic C₁-C₆ alkylene group, alkenylene or phenylene group, which may contain a carbonyl (—CO—), ester (—COO—), ether (—O—) or hydroxyl radical, R²², R²³, R²⁵, R²⁶, R²⁷, R²⁹, R³⁰, and R³¹ are each independently a straight, branched or cyclic C₁-C₁₂ alkyl group which may contain a carbonyl, ester or ether radical, or a C₆-C₁₂ aryl, C₇-C₂₀ aralkyl, or thiophenyl group, Z⁰ is a single bond, methylene, ethylene, phenylene, fluorophenylene, —O—R³²—, or —C(═O)—Z¹—R³²—, Z¹ is oxygen or NH, R³² is a straight, branched or cyclic C₁-C₆ alkylene group, alkenylene or phenylene group, which may contain a carbonyl, ester, ether or hydroxyl radical, M⁻ is a non-nucleophilic counter ion, d1, d2 and d3 are numbers in the range: 0≦d1≦0.3, 0≦d2≦0.3, 0≦d3≦0.3, and 0<d1+d2+d3≦0.3.

10. A pattern forming process comprising the steps of applying the resist composition of claim 1 onto a substrate to form a resist film, exposing the resist film to high-energy radiation, baking, and developing the exposed film in an organic solvent-based developer to form a negative pattern wherein the unexposed region of film is dissolved away and the exposed region of film is not dissolved.

11. The process of claim 10 wherein the developer comprises at least one organic solvent selected from the group consisting of 2-octanone, 2-nonanone, 2-heptanone, 3-heptanone, 4-heptanone, 2-hexanone, 3-hexanone, diisobutyl ketone, 2-methylcyclohexanone, 3-methylcyclohexanone, 4-methylcyclohexanone, acetophenone, 2′-methylacetophenone, 4′-methylacetophenone, propyl acetate, butyl acetate, isobutyl acetate, amyl acetate, isoamyl acetate, butenyl acetate, phenyl acetate, propyl formate, butyl formate, isobutyl formate, amyl formate, isoamyl formate, methyl valerate, methyl pentenoate, methyl crotonate, ethyl crotonate, methyl lactate, ethyl lactate, propyl lactate, butyl lactate, isobutyl lactate, amyl lactate, isoamyl lactate, methyl 2-hydroxyisobutyrate, ethyl 2-hydroxyisobutyrate, methyl benzoate, ethyl benzoate, benzyl acetate, methyl phenylacetate, benzyl formate, phenylethyl formate, methyl 3-phenylpropionate, benzyl propionate, ethyl phenylacetate, and 2-phenylethyl acetate.

12. The process of claim 10 wherein the step of exposing the resist film to high-energy radiation includes ArF excimer laser immersion lithography of 193 nm wavelength, EUV lithography of 13.5 nm wavelength or EB lithography.

13. The process of claim 12 wherein the ArF immersion lithography of 193 nm wavelength uses a halftone phase shift mask bearing a dot pattern, whereby a pattern of holes is formed at the dots after development.

14. The process of claim 10 wherein the exposing step includes two exposures through a halftone phase shift mask having intersecting lines, whereby a pattern of holes is formed at the intersections of lines after development.

15. The process of claim 10 wherein the exposing step uses a halftone phase shift mask bearing lattice-like shifter gratings, whereby a pattern of holes is formed at the intersections of gratings after development.

16. The process of claim 13, wherein the halftone phase shift mask has a transmittance of 3 to 15%.

17. The process of claim 15 wherein the phase shift mask used is a phase shift mask including a lattice-like first shifter having a line width equal to or less than a half pitch and a second shifter arrayed on the first shifter and consisting of lines whose on-wafer size is 2 to 30 nm thicker than the line width of the first shifter, whereby a pattern of holes is formed only where the thick shifter is arrayed.

18. The process of claim 15 wherein the phase shift mask used is a phase shift mask including a lattice-like first shifter having a line width equal to or less than a half pitch and a second shifter arrayed on the first shifter and consisting of dots whose on-wafer size is 2 to 100 nm thicker than the line width of the first shifter, whereby a pattern of holes is formed only where the thick shifter is arrayed.

19. A pattern forming process comprising the steps of applying the resist composition of claim 1 onto a substrate to form a resist film, forming a protective film thereon, film thereon, exposing the resist film to high-energy radiation, baking, and applying an organic solvent-based developer to dissolve the protective film and the unexposed region of resist film and form a negative pattern wherein the exposed region of resist film is not dissolved.

20. The process of claim 19 wherein the protective film is formed of a composition comprising a polymer comprising recurring units having a 1,1,1,3,3,3-hexafluoro-2-propanol residue and an amine compound or amine salt, or a composition comprising a polymer comprising recurring units having a 1,1,1,3,3,3-hexafluoro-2-propanol residue and recurring units having an amino group or amine salt copolymerized, the composition further comprising an alcohol solvent of at least 4 carbon atoms, an ether solvent of 8 to 12 carbon atoms, or a mixture thereof.
